(19) United States
(12) Patent Application Publication
(10) Pub. No.: US 2009/0112564 A1
(43) Pub. Date: Apr. 30, 2009

(54) Circuits for simulating dynamical systems

(76) Inventor: Robert William Schmieder, Walnut Creek, CA (US)

Correspondence Address: Robert William Schmieder, 4295 Walnut Blvd, Wlanut Creek, CA, 94596, US

(21) Appl. No.: 12/284,640

(22) Filed: Sep. 24, 2008

Related U.S. Application Data
(60) Provisional application No. 60/994,965, filed on Sep. 25, 2007.

(51) Int. Cl. G06G 7/62

(52) U.S. Cl. 703/21

(57) ABSTRACT

The present invention provides a set of analog circuit modules and a procedure for assembling them into a complete circuit that can be used for simulating dynamical systems, especially periodic, complex, or chaotic systems. The circuit is an electronic analogue of an idealized geometric model of a topological structure (called the attractor) commonly used for representing dynamical systems. Each circuit module consists of one or more electrical paths, each carrying a voltage or current representing one of the dynamical variables of the attractor such as the independent physical variable of the dynamical system, the density of trajectories at every point on the attractor, and the time. Different modules allow for electronic transformations that are the analogues of pieces of the model attractor: extensions, expansions, shifts, bends, twists, turns, splits, and merges. By imposing certain constraints on the modules, they can be connected together to form a complete circuit with the same topology as the model system attractor. For instance, linear systems are simulated by linear chains of modules, and quasi-periodic systems are represented by joining the ends of linear chains to make rings. The complete circuit is operated by controlling some of the electrical variables and observing others; the relationship between the controlled variables and the observed variables constitutes simulation of the dynamical system. The preferred embodiment of the circuits described herein is analog nanoelectronics, in which the individual and compound modules can be fabricated as monolithic structures with VLSI technology using individual nanoscale devices with complex transfer functions. The most appropriate use of these circuits will be simulation of systems whose behavior is extremely complicated but deterministic. The circuits achieve considerable advantage over software-controlled digital computers by casting a significant part of the algorithm into analog hardware, and therefore they can be expected to successfully attack computational problems currently considered effectively intractable.

### CROSS REFERENCE TO RELATED APPLICATION

This application claims priority of U.S. Provisional Patent Application No. 60/994/965, filed 25 Sep. 2007, the entire contents of which is hereby incorporated by reference.

### FEDERALLY SPONSORED RESEARCH OR DEVELOPMENT

Not applicable SEQUENCE LISTING, A TABLE, OR A COMPUTER PROGRAM

Not applicable

### LISTING COMPACT DISC APPENDIX

Not applicable

### BACKGROUND

1. Field of the Invention

This invention relates to circuits used for simulation, and more specifically to circuits for simulating systems that have dynamic behavior that is periodic, complex, or chaotic.

2. Prior Art

One of the most extensive uses of computers is simulation: the representation of the behavior of a system by a simpler or more convenient system. Electronic computers have special value for simulation because of their low cost and flexibility. Unfortunately, there is a large class of simulations that cannot be done with available computers; these problems are part of a larger group of mathematical problems referred to as intractable.

Computers can fail to solve problems for a variety of intrinsic and practical reasons, including overly restrictive boundary conditions, excessive numbers of boundaries (e.g., multi-dimensional grids), combinatorial explosion (e.g., unrestricted branching), accumulation of unacceptable error, discontinuous variables, unknown dynamics, data that are ambiguous, vague, incomplete, dirty, fuzzy, etc., excessive unused precision, excessive signal propagation times, large numbers of sensors/actuators, stringent limitations on size, weight, power, speed, etc.

Many of these reasons for failure can be traced to the use of numbers to represent the behavior of the system. Numbers are used because they are system-independent and they enable arbitrary precision. However, a general principle in simulation is that the more closely the simulator resembles the structure and function of the system, the more efficient (=fast) it will be. Unfortunately, digital computers, which use circuits with a restricted set of stable states to represent numbers, have no similarity to the systems they are simulating, hence are highly inefficient. Indeed, in a digital computer almost all the time almost all the data is doing nothing at all (it is merely stored). Thus, a digital computer, while being convenient, is an extremely poor simulator.

It should be noted that there are no numbers in Nature; natural processes, which are often what we wish to simulate, proceed without any numbers. A physical system that does not use numbers is called an analog simulator. Analog simulators are common, although they are not always called computers. Any system that has structure and function similar to the system of interest but does not use numbers can be considered an analog simulator, and the more similar it is to the system of interest, the faster it will be. Thus, a cup of tea is a very good (and very fast) simulator of a cup of coffee, while a jar of sand is poorer as a simulator, and a bag of marbles would be terrible. However, for some processes (e.g., pouring, conforming to the container, etc.), even a poor simulator is faster than a numerical one.

Analog simulators include electronic analog computers. The original electronic analog computers, developed during the mid-20^{th} Century, were large, fixed-architecture, single-purpose circuits used for tasks such as trajectory calculations [N. R. Scott, Analog and Digital Computer Technology, McGraw-Hill, 1960]. Modern analog computers are integrated circuits, often with modular architecture that enables considerable programmable re-configurability and adaptive capability. They are therefore far more powerful than the original analog computers, and in fact have the potential for successfully attacking problems conventionally considered intractable on digital computers.

In the past decade, considerable progress has been made on designing and fabricating analog arrays: integrated circuits containing a set of functional modules, accessible to outside connections, and capable of being configured by using internal switches. For example, Hasler and colleagues at the Georgia Institute of Technology [U.S. Pat. App. Nos. 20070040712, 20070007999, 20060261846] have developed Field Programmable Analog Arrays (FPAA) containing 42 configurable analog blocks (CAB); chips containing as many as 1000 CABs are quite feasible. Such chips would enable development of application-specific analog array computers, which are projected to have computational capability up to 100,000 times equivalent digital computers.

In simulation, an important aspect is precision. Digital computers have precision fixed by hardware connectivity (e.g., 64-bit words), although through software this precision can be extended arbitrarily, with concomitant increase of computation management overhead. A difficult but important goal is adaptive precision, in which the hardware imposed-precision is adaptable. Analog computers offer a distinct advantage in this regard: adjusting the precision of an analog signal can be done by adjusting a filter using analog circuits, which is not only intrinsically faster than software and can be implemented in parallel within a large computer but also can be locally adjustable within the machine.

Among the important classes of simulation problems that are often intractable are dynamical systems exhibiting nonlinear, complex, and chaotic behavior [E. Ott, Chaos in Dynamical Systems, Cambridge, 2002; L. E. Reichel, The Transition to Chaos, Springer, 1992; V. G. Ivancevic and T. T. Ivancevic, High-Dimensional Chaotic and Attractor Systems, Springer, 2007; M. C. Gutzwiller, Chaos in Classical and Quantum Mechanics, Springer, 1990.]. The goal in studying such systems generally is not to describe the exact behavior of a particular system in time, but rather to understand the behavior of a set of similar systems, starting from similar initial conditions and subject to similar influences. This is essentially a topological concept: we seek the behavior of neighborhoods of points (i.e., SETs) as functions of control points (other SETs). Indeed, the current trend in complex dynamics is to classify behavior using topological analysis [R. Gilmore and M. Lefranc, The Topology of Chaos, Wiley, 2002; R. Gilmore and C. Letellier, The Symmetry of Chaos, Oxford, 2007]. Thus, rather than a detailed, high-precision simulation of a specific system, we seek a lower-precision qualitative simulation of the general system behavior.

A central requirement on any practical computer system is that it be scalable—it can be built up to arbitrary size by combining smaller parts into larger parts. Fortunately, many if not most systems of interest can be analyzed into connected component pieces, and the number of different pieces is rather small. This suggests that we should seek a simulator that can be built from standard modules by connecting them in the same way (or more accurately, a similar way) as the system.

The implied need for large numbers of modules suggests that limitations will be encountered with microelectronic VLSI technology. Nanoelectronics offers a substantial advantage here: smaller device size, lower power, and monolithic compound devices with complex transfer functions [M. Dragoman and D. Dragoman, Nanoelectronics, Artech, 2006; G. Timp, Nanotechnology, Springer, 1999]. Using complex devices as the basic logic element offers increase in logic density, logic throughput, reductions of the number of devices, and simplifications in design. In addition, the general aspect of nanoelectronic analog signal processing as the fundamental computational process is consistent with reduced (or adaptable) precision appropriate for simulation.

Thus, the general goal of practical electronic computers for simulation of dynamical systems is consistent with VLSI analog array technology [S. Liu, J. Kramer, G. Indiveri, T. Delbruck, and R. Douglas, Analog VLSI: Circuits and Principles, MIT, 2002; R. L. Geiger, P. E. Allen, and N. R. Strader, VLSI. Design Techniques for Analog and Digital Circuits, McGraw-Hill, 1990; S. L. Hurst, VLSI Custom Microelectronics: Digital, Analog, and Mixed-Signal, Marcel-Dekker, 1999]. Implementation of such computers with nanoelectronics will provide significantly increased advantages in design and performance.

What is needed to realize these goals is a set of basic standard modules that can be connected together, and a procedure for assembling a circuit that is similar to the system to be simulated. It is this need to which this invention is directed, and for which this invention provides one practical approach.

### BRIEF SUMMARY OF THE INVENTION

This invention comprises a set of simple, standard circuit modules that are electronic analogues of basic processes that occur in dynamical systems, and a procedure for connecting them together to form complete circuits that are the analogues of topological structures that describe dynamical systems, particularly complex, nonlinear, or chaotic systems.

The modules are electronic analogues of simple component pieces of topological structures called branched manifolds. A branched manifold is an idealization of a topological structure called an attractor, which is used for classifying and describing chaotic dynamical systems. The instantaneous state of the system is represented by a point that moves around the attractor. If the system is periodic, the state point will return to a previous point on the attractor. If the system is chaotic, the state point will return to the vicinity of its initial position, but it will never return to an initial point. The overlap of trajectories from many cycles fills out the structure called the attractor. The branched manifold is an approximation to the attractor for large times; it is in the form of a multi-connected ribbon of finite width and zero thickness. The local longitudinal path on the ribbon corresponds to the time.

The first step in this invention is to replace the branched manifold, which is a topological structure, with a geometrical structure, namely an idealized model branched manifold, in which all bends, turns, and twists are at 90°, splits and merges are planar, and in which no pieces intersect. This enables dissecting the model branched manifold into a small number of standard geometrical pieces.

The second step is to associate with each standard piece a simple 3-wire electronic circuit that provides an electronic analogue of the geometrical transformation represented by the piece. For instance, the circuit analogue for a bend would involve the interchange of two of the wires and the inversion of one of them, because in the geometrical bend two axes are rotated around the third axis. Other examples include circuits that are the analogues of one branch splitting into two branches, and of two branches merging into one.

The third step is to assemble the circuit modules into a complete circuit with the same topology as the branched manifold. For example, if the branched manifold has a bend followed by an extension followed by a split, we would connect the module for extension to the module for the bend to the module for the split. The compound circuit is then the analogue of the three connected pieces of the model branched manifold. Such compound circuits will still have 3 input wires and 3 output wires, hence they can serve as modules for further assembly of the complete circuit.

The final step is to vary some parameters of the complete circuit while observing others. The output behavior will also depend on the values of the circuit device parameters (resistances, capacitances, etc.). Because the circuit is an electronic analogue of the dynamical system, its behavior will mimic (=simulate) the dynamical system.

Small perturbations in the input parameters and variables will cause small changes in the output voltages and currents, but will not alter the circuit topology, which is consistent with perturbation of dynamical systems. Larger changes in the input parameters could cause large, sudden changes in the dynamics, and such changes can be implemented in circuits that use the dynamical variables to adaptively change the circuit topology.

A general principle in simulation is that the more closely the simulator resembles the structure and function of the system, the more efficient (=fast) it will be, and we adopt this as our approach: the circuit modules enable assembly of a global circuit that has the essential structure and function of a chaotic dynamical system. Thus, the present invention offers a path to extremely high efficiency (=speed) in simulation of complex, possibly chaotic dynamical systems.

In summary, this invention provides a set of standard, simple, analog circuit modules and a procedure for assembling them to form a complete circuit that is the topological analogue of the system of interest, hence a complete circuit that can simulate that system.

These and other objects, features, and advantages of the present invention will become more apparent upon reading the following specification in conjunction with the accompanying drawings.

### BRIEF DESCRIPTION OF THE FIGURES

FIGS. 1A-1L, collectively designated FIG. 1, is a graphical summary of this invention, in which the principal steps of its implementation are displayed.

FIGS. 2A-2C, collectively designated FIG. 2, show examples of chaotic system behavior, as described by a phase-space attractor and its idealization as a branched manifold.

FIGS. 3A-3D, collectively designated FIG. 3, show a fragment of a branched manifold and examples of the Poincare density, which describes local the density of orbits.

FIGS. 4A-4B, collectively designated FIG. 4, show a simple branched manifold, and its idealization to a model branched manifold, the first procedural step in this invention.

FIGS. 5A-5B, collectively designated FIG. 5, show simple, standardized pieces which can be used to assemble a model branched manifold.

FIGS. 6A-6C, collectively designated FIG. 6, show how pieces can be assembled to form model branched manifolds.

FIGS. 7A-7D, collectively designated FIG. 7, show an example of a physical system, its branched manifold, and the assembly of a model branched manifold using simple standard pieces.

FIG. 8 shows the assignments of axes to the local model branched manifold, which enables associating voltages (or currents) on 3-wire circuits with these axes.

FIGS. 9A-9C, collectively designated FIG. 9, show different orientations of pieces of the model branched manifold.

FIG. 10 defines the graphical notation to be used in describing this invention.

FIGS. 11A-11D, collectively designated FIG. 11, show basic definitions for 3-wire circuits to be used as analogues of pieces of model branched manifolds.

FIGS. 12A-12C, collectively designated FIG. 12, show extensional pieces of the model branched manifold and their 3-wire circuit analogues.

FIGS. 13A-13C, collectively designated FIG. 13, show rotational pieces of the model branched manifold and their 3-wire circuit analogues.

FIGS. 14A-14B, collectively designated FIG. 14, show inversional pieces of the model branched manifold and their 3-wire circuit analogues.

FIGS. 15A-15D, collectively designated FIG. 15, show the split piece of the model branched manifold and 3-wire circuit analogues.

FIGS. 16A-16D, collectively designated FIG. 16, show the merge piece of the model branched manifold and 3-wire circuit analogues.

FIG. 17 shows a summary of all basic pieces defined in FIGS. 12-16 for model branched manifolds and their circuit analogues.

FIGS. 18A-18B, collectively designated FIG. 18, show how the individual pieces of the model branched manifold can be combined into compound pieces that can be used to build larger compound structures.

FIGS. 19A-19C, collectively designated FIG. 19, show two examples of very simple chaotic dynamical systems, namely the LORENZ and RÖSSLER systems, and the procedure for obtaining circuit analogues of the associated attractors, and for assembling these circuits into computing architectures.

FIGS. 20A-20D, collectively designated FIG. 20, show a more detailed example of a flat ribbon model branched manifold and the procedure for determining its 1-wire circuit analogue, and its correspondence with linear maps.

FIGS. 21A-21B, collectively designated FIG. 21, show an example of the close correspondence between a model branched manifold and its 3-wire circuit analogue.

FIG. 22 shows a piece of a model branched manifold that implements an arbitrary piecewise mapping.

FIGS. 23A-23C, collectively designated FIG. 23, show an example of a model branched manifold that implements an arbitrary 4-segment piecewise mapping, and its 1-wire circuit analogue.

FIGS. 24A-24C, collectively designated FIG. 24, show two examples of piecewise discontinuous linear maps with opposite local and global behavior, and their generic 1-wire circuit analogue.

FIGS. 25A-25D, collectively designated FIG. 25, defines flowgraphs.

FIG. 26A-26B, collectively designated FIG. 26, shows an example of a model branched manifold and its associated flowgraph.

FIGS. 27A-27E, collectively designated FIG. 27, show an example of model branched manifold and its associated flowgraph, showing how paths are defined and how the flowgraph can be replaced by a fully-parallel equivalent for the independent paths.

FIGS. 28A-28F, collectively designated FIG. 28, show an example of a 4-segment linear map and its corresponding flowgraphs.

FIGS. 29A-29D, collectively designated FIG. 29, defines notation used to represent flowgraphs and their properties.

FIG. 30 shows examples of flowgraphs and some of their statistical properties.

FIGS. 31A-31B, collectively designated FIG. 31, show numbers of paths through selected flowgraphs.

FIGS. 32A-32E, collectively designated FIG. 32, show examples of branched manifolds that have multiple variables, and their circuit analogues.

FIGS. 33A-33D, collectively designated FIG. 33, show nonplanar flowgraphs, including examples of model branched manifolds containing knots.

FIGS. 34A-34C, collectively designated FIG. 34, show the process of unrolling an attractor to form a linear model branched manifold, and the paths of signals through them.

FIGS. 35A-35B, collectively designated FIG. 35, show three similar flowgraphs, and signal paths through them.

FIGS. 36A-36C, collectively designated FIG. 36, show a linear chain circuit manifold and its role in setting the system precision.

FIGS. 37A-37E, collectively designated FIG. 37, show an 11-node ring circuit manifold and an example of the data it generates when used as a computer.

FIGS. 38A-38D, collectively designated FIG. 38, defines analog iteration and shows an example.

FIGS. 39A-39F, collectively designated FIG. 39, show a 7-node ring circuit manifold and typical data it generates when used as a computer.

FIGS. 40A-40D, collectively designated FIG. 40, show a tree branched circuit manifold and typical data it generates when used as a computer.

FIGS. 41A-41E, collectively designated FIG. 41, show examples of data generated by linear circuit manifolds that are the analogues of periodicity, period tripling, intermittency, transience, and chaos.

FIGS. 42A-42D, collectively designated FIG. 42, show examples of how the topology of circuit manifolds can be adaptively altered.

FIG. 43 shows a generic system layout for computers based on the aggregation/evaluation paradigm.

FIGS. 44A-44C, collectively designated FIG. 44, show examples of computing architectures using circuit manifolds in which data and control are mixed and interchangeable.

FIGS. 45A-45C, collectively designated FIG. 45, show examples of computing architectures using circuit manifolds to build ladder and 2D arrays.

FIGS. 46A-46B, collectively designated FIG. 46, show examples of computing architectures using circuit manifolds to build arrays with peripheral or embedded sensors.

### DETAILED DESCRIPTION OF THE INVENTION

### Preliminary Overview of the Steps in this Invention

We provide here a very brief overview of the steps used in this invention.

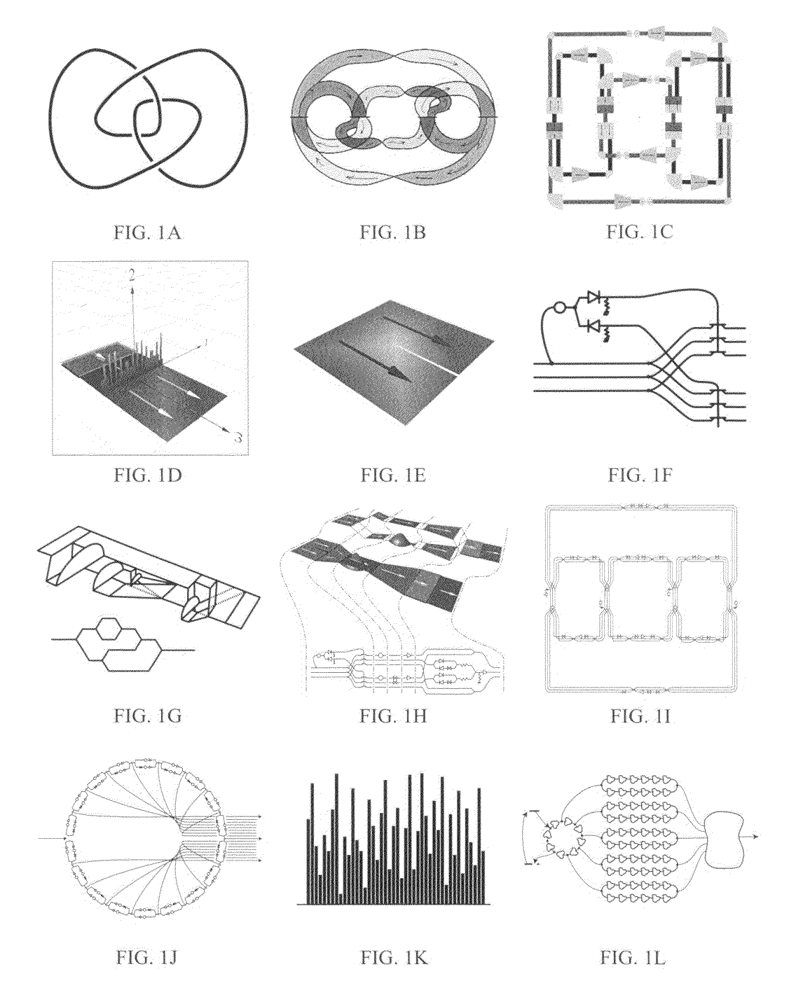

FIG. 1 shows the main steps in implementing this invention.

FIG. 1A represents a physical system, in this case a closed wire loop carrying an electric current. The task is to describe the magnetic field produced by the loop.

FIG. 1B shows the topological attractor associated with the current loop. The attractor is a multiply-connected ribbon, called a branched manifold, with flow directions which indicate the polarity of the magnetic field lines. In oscillatory and chaotic dynamical systems, these ribbons are pathways traversed by the point in phase space representing the state of the system.

FIG. 1C shows the first step in this invention, in which the branched manifold is replaced with a model that has the same topology as the branched manifold, but has simple local geometry (90-degree bends, etc.). This structure is assembled by connecting copies of a small set of standard pieces, such as bends, splits, and merges.

FIG. 1D indicates that a local piece of the model manifold has 3 axes, corresponding to (1) the dynamical variable of the physical system; (2) the density of orbits as the system passes repeatedly past a particular position; and (3) the time.

FIG. 1E shows a typical standard piece of the model manifold, in this case the split piece, which separates the ribbon into two narrower ribbons, each of which connects and evolves independently.

FIG. 1F shows how a 3-wire circuit fragment is associated with the standard model manifold pieces: each wire carries a voltage or current that corresponds to the location of the state point on the model manifold. In this particular case, one line generates a Boolean signal that switches the 3 lines to either of two independent 3-line outputs. This circuit implements the split piece.

FIG. 1G shows the correspondence between a model branched manifold and its topologically equivalent flowgraph.

FIG. 1H indicates how circuits can be built up from fragments by joining them in the same topology as the model manifold.

FIG. 1I shows the completed circuit for the model manifold of FIG. 1C. It consists of multiply-connected 3-wire circuits.

FIG. 1J shows how such complete circuits are used to perform analog computations. In this 18-module circuit, one node voltage is set, which automatically sets all 17 other node voltages. This circuit implements a simulation of a period-18 system.

FIG. 1K shows representative data obtained from a circuit similar to FIG. 1J, with 44 modules. Although the data vs. node number appear chaotic, they actually described period-44 motion.

FIG. 1L indicates the general freedom to combine circuit modules into useful adaptive computing architectures, in this case, compound analog iteration.

Each of these steps is described in detail in the full description below.

### Topological Description of Dynamics

### Nonlinear, Complex, and Chaotic Behavior

Dynamics refers generally to the variation of systems in time and more specifically to their asymptotic behavior at large time. A central issue in dynamics is recurrence, of which periodicity is the simplest form. Some systems pass through a transient and settle into a stable state. Others settle into periodic or quasi-periodic motion. When the operating conditions become more extreme, regular periodic motion usually becomes multiperiodic and eventually chaotic, by which we mean the state of the system varies quasi-periodically, but never actually repeats any part of its motion. Chaotic motion is characterized by great complexity and sensitivity to initial conditions.

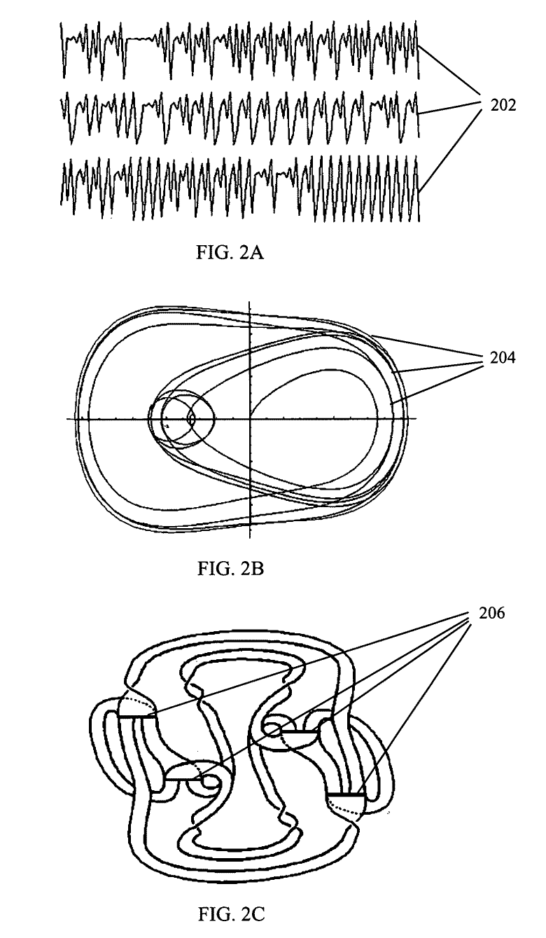

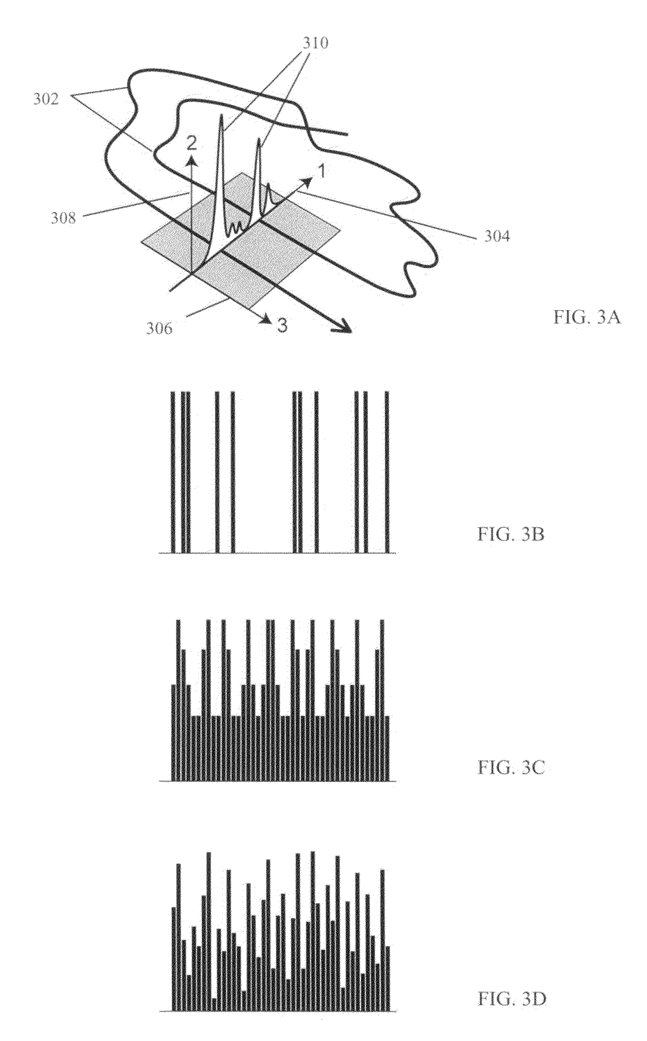

FIG. 2 shows exemplary behavior of a chaotic system.

FIG. 2A shows the behavior of a 3-dimensional chaotic system in time. There are three signals 202, corresponding to the 3 degrees of freedom. While there are segments in these signals that are highly regular and nearly periodic, inevitably such regularity gives way to a qualitative change, making the global behavior of the system unpredictable (chaotic). Over the past decade, considerable effort has been made to understand and organize such complex behavior; topological analysis has so far proved the most powerful.

### Attractors

The behavior of a dynamical system is visualized as the movement of a point (the state) along trajectories in the multi-dimensional parameter (phase) space. Over long times, the trajectories trace a structure called the attractor. The geometry of the attractor can be very complex, or even fractal (in which case the attractor is called strange). Generally, orbits of small finite period are embedded in the attractor alongside orbits of very long or infinite periods. Some orbits are changed when system parameters are changed, but attractors can remain globally stable even when the system parameters are varied (by reasonably small amounts). When system parameters are changed by large amounts, the global attractor structure is changed. One of the goals of dynamic systems analysis is to describe the attractor and the effects of changes in system parameters on its shape and connectivity.

FIG. 2B shows the projection in the plane of a few orbits 204 of a nonlinear system. If the attractor were confined to a simple curve it would be periodic; the fact that it is confined only to relatively wide bands in which it never exactly repeats means it is chaotic. Changing the parameters that define this attractor will distort it; sufficiently large changes will “break” it, causing branches to form or coalesce.

### Branched Manifolds

The attractor is typically a multiply-branched structure in the space of the dynamical variables and control parameters. The branches are composed of fibers that represent individual orbits of the state point in time. Gilmore and others have developed a topological approach to describing and classifying such attractors. They emphasize the usefulness of reducing the dimensionality of complex systems to three, and indeed, this is very often quite reasonable, since in most systems only a few variables (say, 3!) dominate the behavior.

Given a 3D attractor, the Birman-Williams theorem guarantees that at large times the attractor collapses to a multiply-connected flat ribbon called the branched manifold. The branched manifold is a 2D surface embedded in a 3D space. Gilmore and others have shown and analyzed branched manifolds for many well-known systems, and they have developed a standard form and matrix algebra for any branched manifold.

FIG. 2C shows an exemplary branched manifold. Gilmore emphasizes that the splits and merges 206 are the only parts that are important to the topology of the global manifold. In developing our circuits, we will find that it is essential to have a third piece, one that scales the branched manifold transversely (changes the ribbon width). We will base our circuit analogue of the branched manifold on local properties, retaining the global structure defined by the split and merge pieces.

### The Poincare Density

Reducing the system to a branched manifold provides us with a powerful advantage: all the trajectories lie on flat ribbons, so a cut through such a ribbon is a line or set of line segments (the Poincare section, nominally normalized to [0,1]). All trajectories (locally) cross that line. We can imagine waiting at the line (segments) for the state point to pass, marking the interval [a,b] on the line through which it passes, and accumulating a histogram showing the number of passes for each interval. Taking the intervals to be infinitesimally small, we can define a density ρ(x) (the Poincare density) such that the integral of ρ(x) over an interval [a,b] along the line is the fraction of trajectories in the interval [a,b]. The function ρ(x) contains fundamental behavioral information about the system. Although this function passes through a transient as the system initially evolves, eventually it stabilizes on a constant function, called the natural invariant density.

FIG. 3A shows a generic Poincare density. The trajectories 302 are distributed on the 1-axis 304 in the interval [0,1]. They advance along the 3-axis 306 and pass normally through the Poincare section (the 1-axis). The Poincare density ρ(x) 310 is plotted on the 2-axis 308.

The next three figures show three possible forms of the Poincare density.

FIG. 3B results from periodic (period-5) motion.

FIG. 3C results from periodic (period-40) motion.

FIG. 3D results from chaotic motion. The function ρ(x) depends on the control parameters of the system. We take ρ(x) to be a significant representation of the behavior of the system, and we will develop circuits that generate local values of <x, ρ, t> and display their dependence on the control parameters. By building the branched manifold from local pieces, we will obtain a complete circuit that is the analogue of the global manifold.

### Model Branched Manifolds

The branched manifold is a 2D surface embedded in a 3D space. It consists of various ribbon-like pieces connected in various loops, with various twists, splits, and merges.

Our approach to developing a circuit that simulates the branched manifold is to imagine constructing the manifold from real physical pieces, simplify the geometry of the pieces, and associate a simple circuit modules with each simplified piece. This enables us to assemble a complete circuit that has the same global topography and local behavior as the attractor, hence will be a valid simulator of the attractor.

### Modeling the Branched Manifold

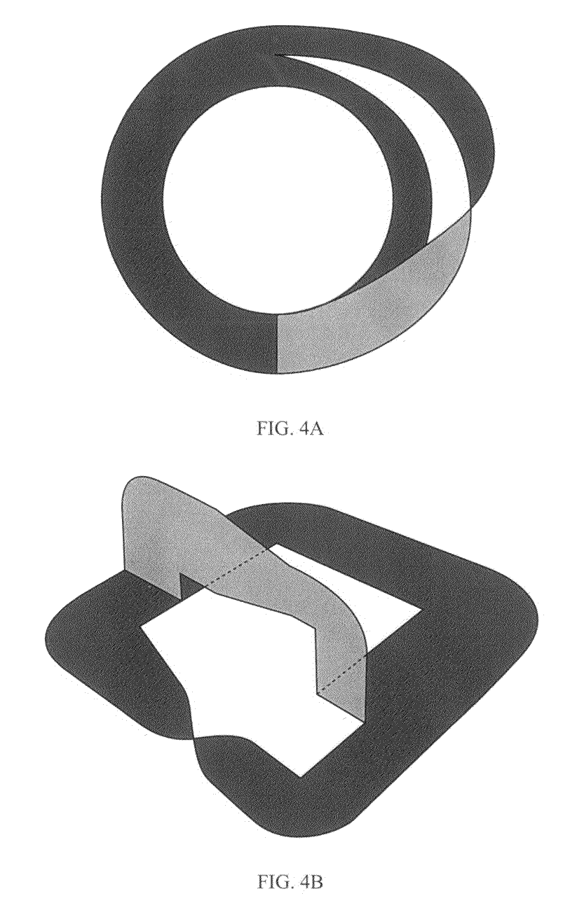

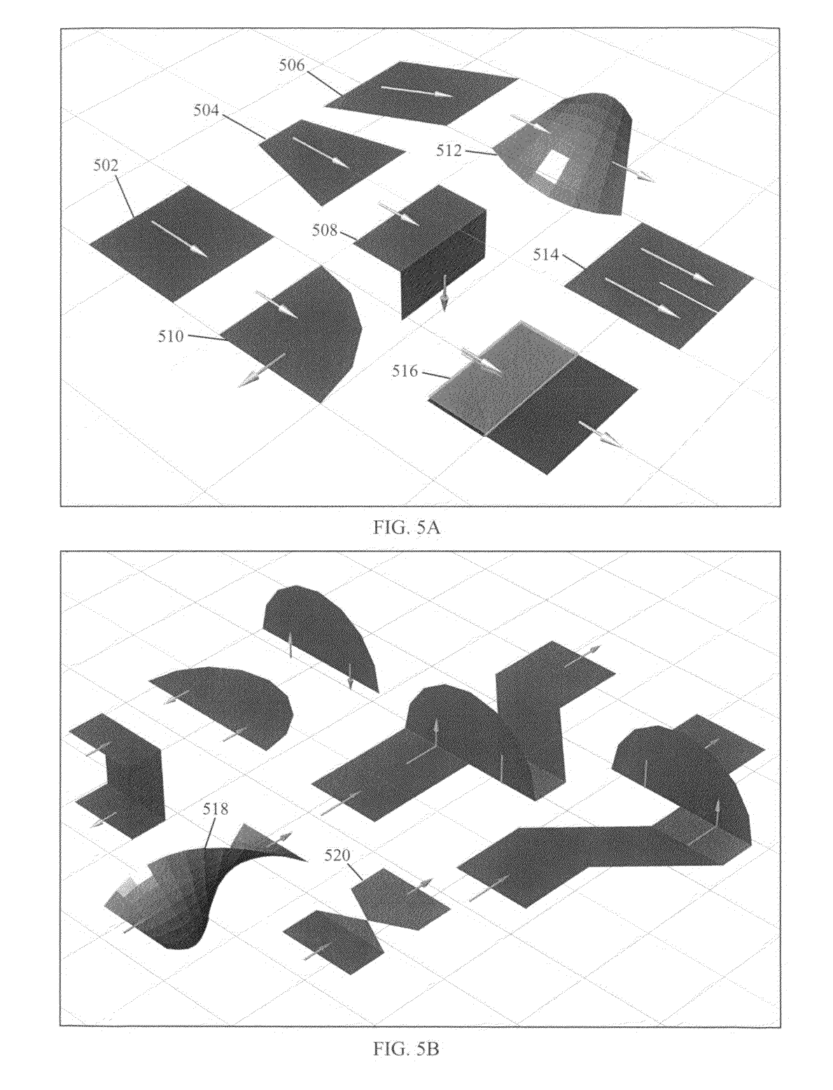

FIG. 4 illustrates the step of converting a topological branched manifold into a geometrical model branched manifold, which is necessary to implement the circuit analogues of the system attractor.

FIG. 4A shows one of the simplest branched manifolds, the Smale horseshoe. Branched manifolds of arbitrary complexity can be constructed to correspond to dynamical systems of arbitrary complexity. Any non-tearing distortion of a branched manifold is the same branched manifold.

We idealize the branched manifold by converting it from a topological structure to a geometric one, using the following rules:

(1) Very short local sections are represented by (oriented) flat laminae;

(2) Bends, turns, and twists are only made in 90° increments;

(3) Splits are represented by flat laminae with one input and two output branches;

(4) Merges are represented by flat laminae with two input and one output branches.

FIG. 4B shows a model branched manifold for the Smale branched manifold. The model branched manifold, like the branched manifold, is locally 2D but globally 3D. Topologically, the model manifold is equivalent to the branched manifold. Constraining the pieces to have only 90° changes of directions will considerably simplify the circuits to be associated with these model manifolds.

### Model Pieces

Model branched manifolds can be constructed from a small set of canonical pieces. The pieces have a “flow” direction that corresponds to increasing time.

FIG. 5 shows pieces from which any model branched manifold can be assembled.

FIG. 5A shows a minimal set of canonical pieces that can be used to assemble any non-pathological model branched manifold. The three pieces on the left implement connecting pieces of the branched manifold: the extension piece 502, the scale piece 504, and the shift piece 506. The three center pieces implement 90° bends: the bend piece 508, the turn piece 510, and the twist piece 512. The two rightmost pieces implement the split piece 514 and the merge piece 516. These basic pieces can be combined to form compound pieces that are convenient for assembly of more complicated model manifolds. Such combinations must follow certain rules (listed in the next section).

FIG. 5B shows various ways to implement 180° bends. These include the twoist piece 518 and the inversion piece 520.

### Assembling the Model Manifold

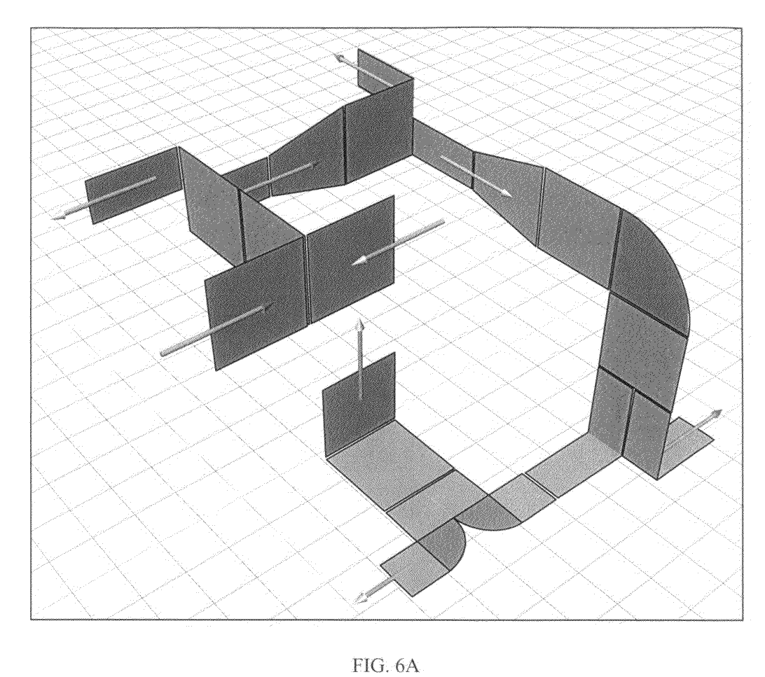

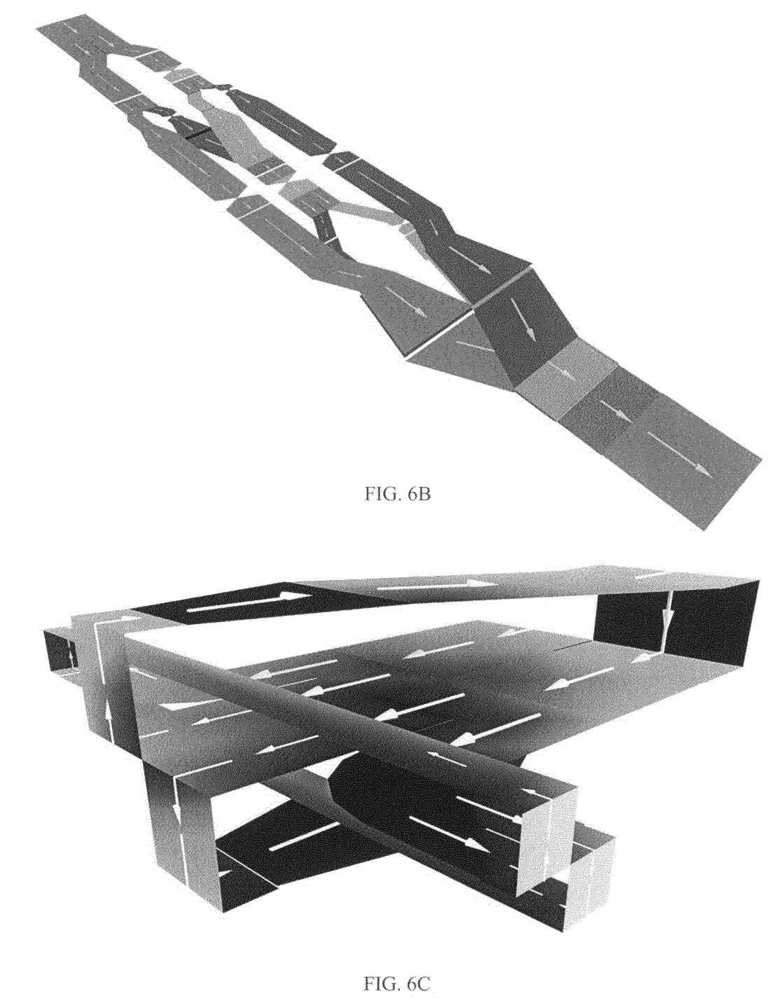

FIG. 6 shows the principle of using simple pieces to build a more complex model branched manifold.

FIG. 6A illustrates the rules for building the model manifold from the individual pieces. They include:

(1) The pieces must join in their common plane;

(2) There must be no overlaps;

(3) The edges must match;

(4) The angle of all bends, turns, and twists must be 90°;

(5) The flow (indicated by the arrows) must be coherent;

(6) The manifold must be closed, i.e., there must be no “dead-ends.”

Note how we have shown the coordinate axes <1,2,3>. These axes will remain fixed “in the lab,” that is, regardless of how the model BM turns, rotates, twists, etc., these axes do not change. We will reiterate several times that this means that the “time” axis (the direction of the arrows) will sometimes be in the plus-1-direction, sometimes in the minus-3-direction, etc.

### 2D Model Manifolds

Manifolds assembled by connecting modules end-to-end into long linear chains remain 2-dimensional, in spite of the need for the third dimension to effect twists. We will refer to such manifolds as chain manifolds. Even if the ribbon is joined at its ends into a ring or at multiple points, it is still 2D.

FIG. 6B shows a typical model chain manifold. Circuits representing such manifolds will be different from those representing intrinsically 3D manifolds. We will use this particular example later to implement a period-11 ring.

If we limit the available pieces to connectors, inversion, split, and merge, we can assemble linear model manifolds with arbitrary complexity. This will have the structure of a ribbon that is repeatedly slit longitudinally, separated into strands, perhaps inverting some strands by double twists, perhaps stretching the strands transversely to change their widths, perhaps overlapping them to merge into single strands, and finally rejoining the strands to form a single ribbon. For such manifolds, the time direction is the same everywhere, and we can represent it with one voltage, say V₃, in an analogue circuit. In fact, it is unnecessary to even track this voltage, since it merely varies uniformly from the start to the end.

Structures such as these exhibit the property called anastomosis: a multiply-connected, multi-path braid-like structure that supports a uni-directional flow. Anastomosis is found in branching streams, blood vessels, nerve plexuses, and similar systems.

The transverse dimension (the widths of the ribbon and its strands) represents the selected independent dynamical variable. It is also always in the same direction (the 1-axis), so we can represent it with one voltage V₁. As a function of V₃, the value of V₁ changes; the function V₁(V₃) constitutes the desired data. Note that there is no analogue value of V₂; the model branched manifold is 2D and a point on it is represented by <V₁,V₃>. This statement is true no matter how complex is the braiding or multiplicity of the model branched manifold.

Note that only one branch of the model branched manifold can have a signal—all other branches are isolated from the active branch. However, changing the voltage anywhere along the length may cause switching the branch that is active. These points are elaborated below.

We will generally arrange the model manifold to have a single inflow and a single outflow. We assume that the ends are joined by a flat branch that returns from the outflow to the inflow. As emphasized by Gilmore et al., all the splitting, linking, twisting, and merging occurs in this section. This is the part described by the differential equation model. The Poincare section is represented by the transverse cuts a the two ends.

### 3D Model Manifolds

We can use the pieces described above to assemble nearly arbitrary 3D model manifolds, subject to the condition that bends, turns, and twists are limited to 900 and multiples thereof.

FIG. 6C shows an example of a 3D model branched manifold. Any point on this manifold represents the state of the system; the state point moves around the manifold on endless multi-branched loops (the arrows indicate the direction of increasing time, or “flow”). Near the center of this spaceship-like model manifold we can make a transverse cut that will intercept the entire flow. In principle, the cut can be put anywhere, but it should be placed to intercept all parts of the flow (or at least those parts that are of interest), and this was done here. The density of orbits along the cut line is the Poincare density. The model branched manifold is locally 2D but globally 3D. In that 3D space, any point on this manifold can be located with three coordinates <x,ρ,φ>. Therefore, in principle we can represent any point on the model manifold with three circuit voltages <V₁,V₂,V₃>, or any other circuit variables such as current, charge, etc. But as we move around the manifold, the direction of the time (i.e., φ) changes: sometimes is it along the +V₁ axis, sometimes along the V₂ axis, sometimes along the—V₃ axis, etc. The other two variables x,μ similarly change directions. We therefore must face the question: How should we associate the voltages with the branched manifold coordinates?

The straightforward answer to this question is that we must consider the model manifold to be comprised of multiple pieces, each of which is locally a 2D manifold piece (described in the previous section). After all, the 3D branched manifold was assembled from pieces in the first place! The three circuit voltages will then take on different associations as we progress around the branched manifold. In order to advance the state point around the branched manifold, we will increase whichever voltage represents the local time axis. When a bend, turn, or twist is encountered, the roles of the 3 voltages will be changed, and we will increase whichever voltage now locally represents the time axis.

### EXAMPLE

### The Figure-8 Model Branched Manifold

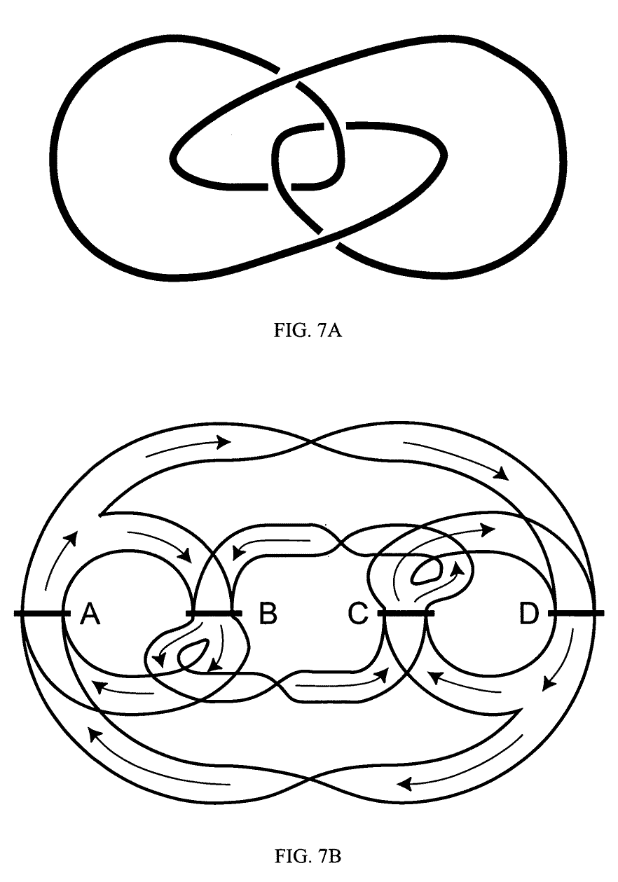

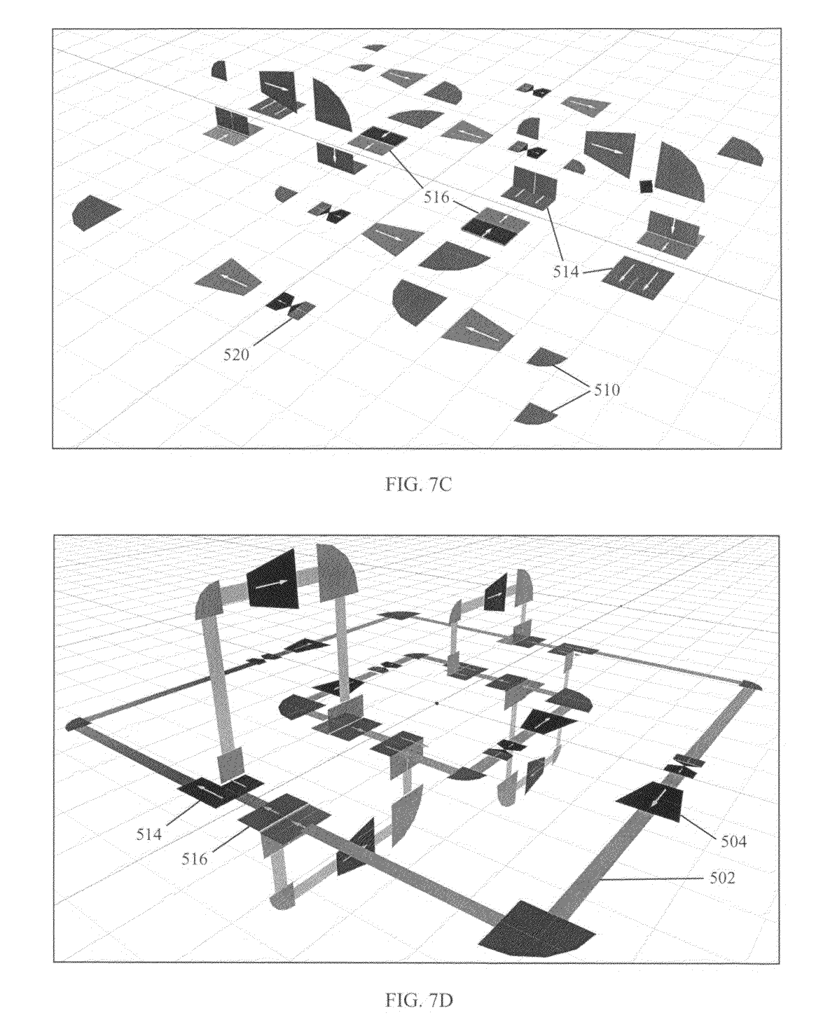

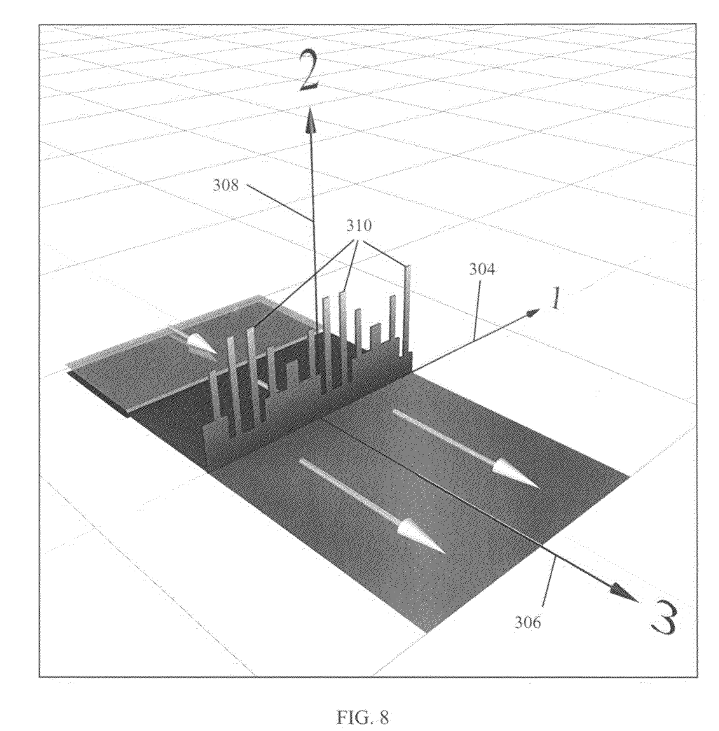

FIG. 7 refers to a well-known branched manifold, taken from the book by Gilmore and Lefranc (who reproduce the work of Birman and Williams).

FIG. 7A shows the original physical system, which is a closed wire loop carrying a current which produces a magnetic field.

FIG. 7B is the topological branched manifold for the magnetic field lines, including their flow directions (arrows).

FIG. 7C shows the standard turn 510, split 514, merge 516, and inversion 520 pieces being assembled to form the model manifold with the same topology as the branched manifold.

FIG. 7D shows the completed model branched manifold. While it can be pictured in its 2D projection, the manifold is really a 2D object embedded in 3D space. For clarity we show the connections between the pieces as narrow paths, although each path is actually the full width of the pieces they connect. Straight connections can be made with the extension piece 502, which can have any length. All other pieces, such as the expansion piece 504 can be thought of as having zero extension, because their functions occur at specific points (in time).

Like most manifolds of this type, this one contains singularities at each of its split 514 and merge 516 pieces. At these singularities, the flow lines have discontinuities. As described by Gilmore, the singularity associated with the split is a point, while the singularity associated with the merge is a line.

### Poincare Density on the Model Manifold

FIG. 8 shows a local piece of a model branched manifold, indicating the flow direction 306 and a histogram representing the Poincare density 310 in the 1-2 plane 304, 308. The Poincare density represents the number of times the dynamical variable of the system passes within a narrow interval. If the motion is exactly periodic, the density will be a set of isolated points, which might be binned into a histogram. If there are many points (high-order periodicity or chaos), we can define a continuous density function. We take the Poincare density as a fundamental global representation of the dynamics of the system.

The Poincare density is determined at an arbitrary transverse cut in the branched manifold. The central requirement is that all orbits must pass through the cut. For complicated branched manifolds, it will be necessary to make several cuts; the Poincare section is then the union of the individual sections.

### CIRCUIT MANIFOLDS

### Definitions

### Model Circuit Variables

We now discuss the task of associating circuit variables with the Poincare section. Referring to FIG. 8, we define the axes <1,2,3> to be fixed in the lab. We will associate circuit variables with these axes, and thereby with the model branched manifold. We assume that we have an electronic circuit with a variety of dynamical variables (voltages or currents). We are free to assemble any circuit, using any number of any kind of devices, so long as we generate three physically independent circuit variables. In this circuit we can identify any three voltages or currents as the dynamic variables; all the other voltages and currents may be considered control parameters. For simplicity, we adopt a set of three voltages <V₁,V₂,V₃>, although any combination of voltages and currents will be just as acceptable.

### Independent Variable

First, we associate one of the circuit variables (say V₁) with the independent dynamic variable x of the physical system. This variable is plotted on the model manifold along the 1-axis 802. Thus, the circuit variable V₁ is the electronic analogue of the system dynamical variable x. The value of V₁ thus locates the orbit on the Poincare section.

### Poincare Density

Second, we associate another circuit variable (say V₂) with the density of orbits, i.e., the Poincare density ρ(x). This variable is plotted on the model manifold along the 2-axis 804. Thus, the function V₂(V₁) is the electronic analogue of the Poincare density ρ(x). The value of V₂ thus is a measure of the density of orbits along the Poincare cut.

### Time

Third, we associate the remaining circuit variable (V₃) with the time t for the physical system. If the system is quasi-periodic or chaotic, the branched manifold is folded; it is confined to a finite region of phase space. Therefore, it can be represented by a variable φ that remains finite. This variable is represented on the model manifold along the 3-axis 806. Thus, the voltage V₃ is the electronic analogue of the time variable φ, and the function V₂(V₁,V₃) is the electronic analogue of ρ(x,φ).

Thus, we have the following (incoherent) analogue between the model branched manifold and circuit variables:

| Branched manifold | [symbol] | Circuit manifold |
|---|---|---|
| <x, ρ, φ> | [symbol] | <V₁ , V₂, V₃> |

A complete circuit that is the electronic analogue of a model branched manifold will be referred to as a circuit manifold.

### Variable Assignments and Transformations

The associations x [symbol] V₁, ρ [symbol] V₂, φ [symbol] V₃ are valid only for the orientation shown in FIG. 8. When the model branched manifold is oriented differently on the <1,2,3> axes, the associations will be different. We discuss this in detail now.

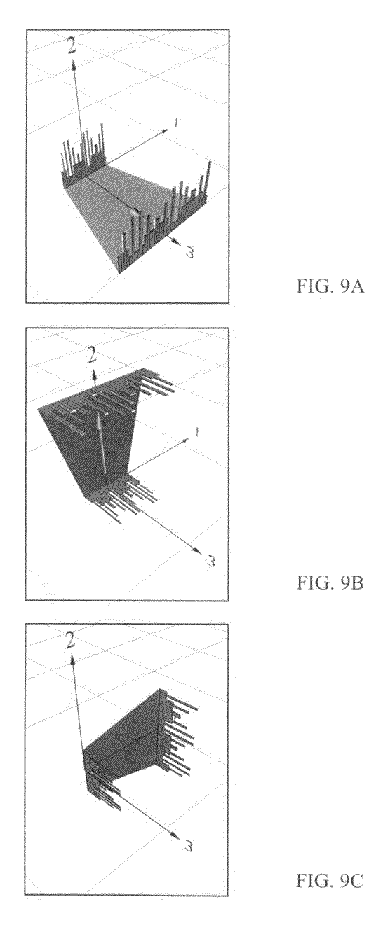

FIG. 9 shows three orientations of the scaling piece. This piece changes the width of the local model branched manifold to enable joining with other pieces with different widths. This piece is not necessary in the topological branched manifold, but became necessary when we converted it to the geometrical model branched manifold. We will use this piece to discuss manifold analogues.

### Progress in the 3-Direction.

FIG. 9A shows the scaling piece oriented in the 1-3 plane. This is the original definition of this piece (FIG. 8). The finite time variable φ increases along the 3-axis. The Poincare section x is along the 1-axis, and the Poincare density ρ is plotted on the 2-axis, so the function ρ(x) lies in the (1,2)-plane at φ=0. Thus, we make the associations <x [symbol] V₁, ρ [symbol] V₂, φ [symbol] V₃>.

As we traverse this piece from V₃=0 to V₃=p, the Poincare function slides forward, so the function ρ(x) appears in the (1,2)-plane, at V₃=p. In addition, ρ(x) is stretched uniformly in the 1-direction by a factor c. We stipulate that the value of ρ(x) (on the 2-axis) remains unchanged in this displacement. The transformations on the model branched manifold variables and the corresponding changes in the circuit manifold variables are:

| Branched manifold | Variable associations | Circuit manifold |
|---|---|---|
| x → c x | x [symbol] V₁ | V₁ → c V₁ |
| ρ → ρ | ρ [symbol] V₂ | V₂ → V₂ |
| φ → φ + p | φ [symbol] V₃ | V₃ → V₃ + p |

### Progress in the 2-Direction.

FIG. 9B shows the same piece oriented in the 1-2 plane, with the time variable along the 2-axis. This orientation might be encountered at some other place in the model branched manifold. By the same analysis as above, we can make the associations <x [symbol] V₁, ρ [symbol] V₃, φ [symbol] V₂>. The transformations on the model branched manifold variables and the corresponding changes in the circuit manifold variables are now:

| Branched manifold | Variable associations | Circuit manifold |
|---|---|---|
| x → c x | x [symbol] V₁ | V₁ → c V₁ |
| ρ → ρ | ρ [symbol] V₃ | V₃ → V₃ |
| φ → φ + p | φ [symbol] V₂ | V₂ → V₂ + p |

### Progress in the 1-Direction.

FIG. 9C shows the same piece oriented in the 1-2 plane, with the time variable along the 1-axis. By the same analysis, we can make the associations <x [symbol] V₂, ρ [symbol] V₃, φ [symbol] V₁>. The transformations on the model branched manifold variables and the corresponding changes in the circuit manifold variables are now:

| Branched manifold | Variable associations | Circuit manifold |
|---|---|---|
| x → c x | x [symbol] V₂ | V₂ → c V₂ |
| ρ → ρ | ρ [symbol] V₃ | V₃ → V₃ |
| φ → φ + p | φ [symbol] V₁ | V₁ → V₁ + p |

To reiterate, at any point on the manifold, we have three model branched manifold variables <x,ρ,φ> and three circuit manifold voltages <V₁,V₂,V₃>. Each voltage represents one of the branched manifold variables, but which voltage represents which variable is determined by the local orientation of the branched manifold.

### Traversing the Manifold

The procedure for moving around the model branched manifold is:

(1) Associate <V₁,V₂,V₃> with <x,ρ,φ> according to the local orientation of the piece;

(2) Increase the voltage corresponding to φ, forcing the consequential changes in the voltages corresponding to x and p;

(3) Exchange and/or invert two of the voltages in accordance with a bend, turn, twist, etc. (The third voltage is not changed).

An obvious question is: Can find an algorithm for traversing the model branched manifold globally? That is, could we set up functions for <x,ρ,φ> for which φ has finite intervals on each branch. This would require φ “knowing” which branch it is on, i.e., a branch index k. We could therefore infer that the variables for the model branched manifold would be the set {<x,ρ,φ,k>|kεN}, and the variables for the circuit manifold would be {<V₁,V₂,V₃,k>|kεN}. It is possible to use analog switches as we did for the split piece to separate the various branches of the model manifold, thereby keeping the entire circuit analog.

In summary, traversing a model branched manifold requires traversing it in local pieces. For each piece we assign the three circuit voltages according to the orientation of the piece. This can be done with analog switches in order to keep the entire circuit in analog mode. As each piece is encountered, the variable assignments are changed.

### Variable Mixing in 3D Manifolds

Clearly, bends, turns, and twists have the effect of mixing the variables. We now clarify this rather mysterious effect.

While we normally think of the time coordinate t as being special, and increasing to large values, here we find it being exchanged with, say, the independent variable or the Poincare density (the “data”). At first encounter, mixing the time and the data may seem like nonsense, but in fact it is a direct consequence of folding the linear-time 2D manifold into a closed, finite 3D manifold. This folding maps the infinite time axis into something finite. This something is a mixture of the 3 variables <x,ρ,φ>.

To reiterate: Folding the 2D infinite-time ribbon-like manifold <x,t> into the 3D finite closed manifold <x,ρ,φ> means that the axes in the latter do not globally correspond directly to the 3 variables. However, locally the axes do correspond to these variables, which means that we can make transformations of arbitrary complexity. When the 3D manifold bends, turns, or twists, the correspondences between <x,ρ,φ> and {<V₁,V₂,V₃> are no longer true. While we cannot escape reassigning correspondences at such places, if we make the bends, turns, and twists at 90°, it enables us to associate very simple circuits with these pieces. Circuit notation.

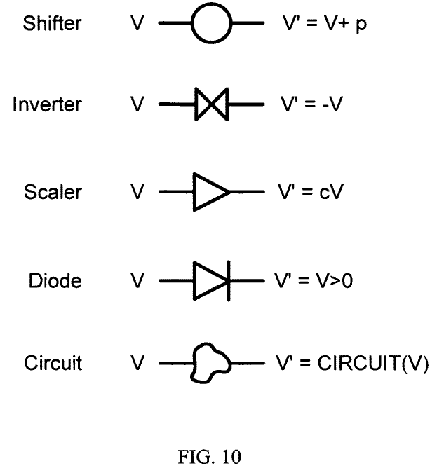

FIG. 10 shows the notation we shall use in this invention to represent some basic circuit devices, including shifter, inverter, scaler, diode, and an arbitrary circuit. We view the devices as transforming an input voltage V (or current) into an output voltage V′ (or current).

### Circuit Analogues of Manifold Pieces

In following sections we define and describe 3-wire circuit analogues of the model manifold pieces. We have organized the pieces into groups, as shown in the following table:

| Model | |
|---|---|
| Manifold Pieces | Use |
| General | Defining 3-wire circuits. |
| Connecting | Shifting and scaling the independent variable. |
| | Expanding the BM for visualization. |
| Rotation | Implementing the global BM topology. Keeping the |
| | manifold finite. |
| Inversion | Introducing twists into the model manifold. |
| Split | Separating the independent variable into disjoint |
| | intervals for separate functions. |
| Merge | Accumulating the Poincare density. Identifying |
| | periodic motion. |

It is emphasized again that the variable assignments depend on the orientation of the piece and the defined axes.

### Circuit Analogues of Transformations

Having defined circuit analogues V=<V₁,V₂,V₃> of the three physical variables <x,ρ,φ> of the branched manifold, we can physically realize the circuit manifold, no matter how complex is the branched manifold, with a few simple circuit fragments, each having three wires.

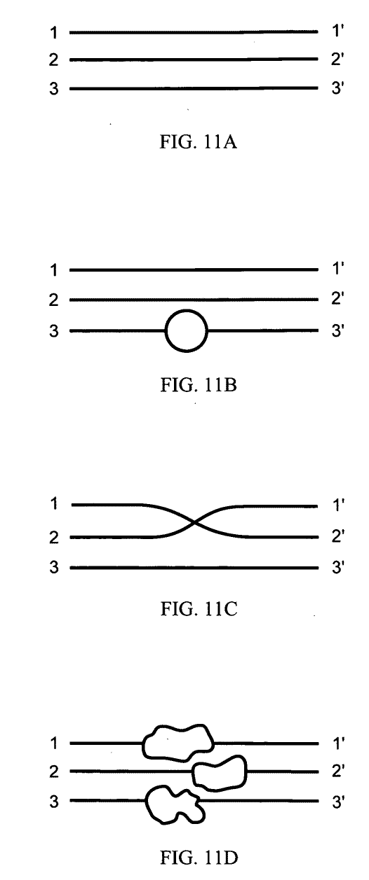

FIG. 11 shows some basic forms of 3-wire circuit fragments that are the analogues of pieces of the model branched manifold.

FIG. 11A shows the simplest 3-wire circuit. The voltages are physical analogues of the three variables <x,ρ,φ> of the model branched manifold. The map for this piece is <V₁,V₂,V₃>→<V₁,V₂,V₃>.

FIG. 11B shows a circuit that can represent the analogue of a shift in the time axis. For a piece in which the time axis is line 3, a voltage shift of p represents a time shift proportional to p. The map for this piece is <V₁,V₂,V₃>→<V₁,V₂,V₃+p>.

FIG. 11C shows a circuit that is the analogue of an inversion of the 1 and 2 axes of the branched manifold. The map for this piece is <V₁,V₂,V₃>→<V₁,V₃,V₂>.

FIG. 11D shows a circuit that is the analogue of an arbitrary planar piece of the branched manifold. In this circuit the three voltages are independently changed according to three functions. The map for this piece is <V₁,V₂,V₃>→<F₁(V₁),F₂(V₂),F₃(V₃)>.

### Circuit Analogues of Connecting Pieces

Connecting pieces enable us to expand the model manifold for convenience in visualization and planning. The extension along the 3-axis is arbitrary, and can be set to any value p, consistent with assembling the complete global model manifold.

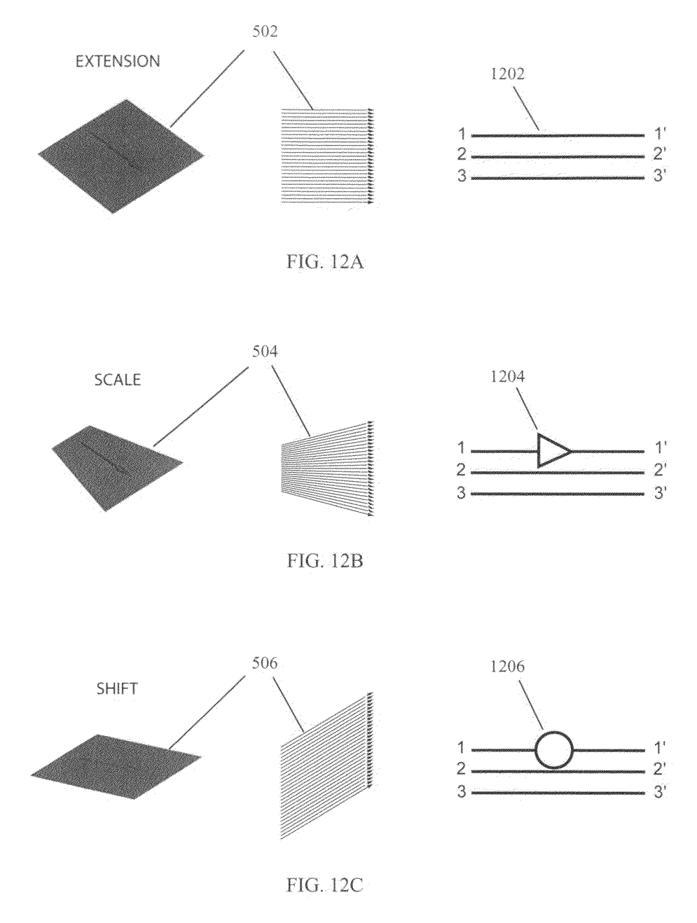

FIG. 12 shows three connecting pieces of the model branched manifold and their 3-wire circuit analogues.

FIG. 12A shows the extension piece 502, which joins two other pieces. It has the trivial mapping <V₁,V₂,V₃>→<V₁,V₂,V₃>, implemented by three wires 1202.

FIG. 12B shows the scale piece 504, which scales the independent variable V₁, leaving the others unchanged. This piece allows us to join two pieces that have different widths (the result of a previous split). Its mapping is <V₁,V₂,V₃>→<cV₁,V₂,V₃>, where c is an arbitrary scaling factor implemented by a scaler 1204.

FIG. 12C shows the shift piece 506, which shifts the independent variable V₁ without altering the other variables. Its mapping is <V₁,V₂,V₃>→<V₁+a,V₂,V₃>, where a is an arbitrary voltage shift implemented by a shifter 1206.

All of these pieces can be considered to be zero length. Indeed, the direct connection of line 3 implies zero length. However, we could insert a shift p on line 3 of these circuits, which could be helpful for visualizing the model branched manifold. The zero-length limit is obtained by letting p→0.

### Circuit Analogues of Rotation Pieces

Rotation pieces enable us to build the model manifold in 3D. These pieces implement rotation around the three axes <1,2,3>, and we limit such rotations to multiples of 90°. This trick enables us to represent the analogue circuits as simple exchanges among the 3 wires.

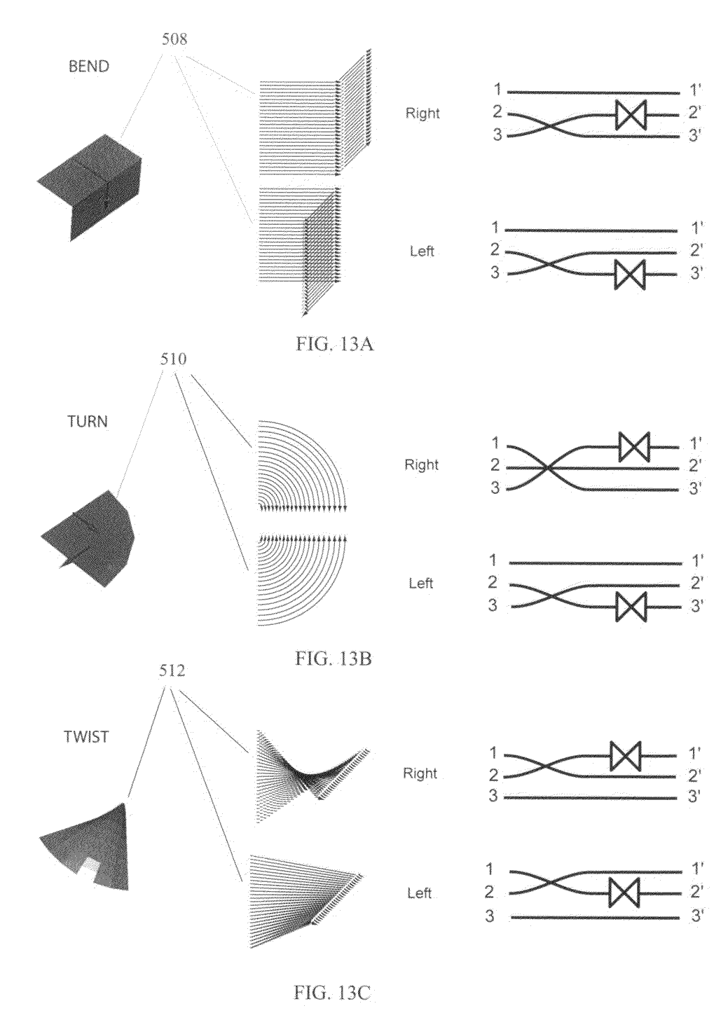

FIG. 13 shows three rotation pieces of the model branched manifold and their 3-wire circuit analogues.

FIG. 13A shows the bend piece 508, which produces a ±90° rotation around the V₁ axis. This piece is implemented by exchanging the V₂,V₃ wires, and inverting one of them. The right bend has the map <V₁,V₂,V₃>→<V₁,−V₃,V₂>. The left bend has the map <V₁,V₂,V₃>→<V₁,V₃,−V₂>.

FIG. 13B shows the turn piece 510, which produces a ±90° rotation around the V₂ axis. This piece is implemented by exchanging the V₁,V₃ wires, and inverting one of them. The right turn has the map <V₁,V₂,V₃>→<−V₃,V₂,V₁>. The left turn has the map <V₁,V₂,V₃>→<V₃,V₂,−V₁>.

FIG. 13C shows the twist piece 512, which produces a ±90° rotation around the V₃ axis. This piece is implemented by exchanging the V₁,V₂ wires, and inverting one of them. The right twist has the map <V₁,V₂,V₃>→<V₂,−V₁,V₃>. The left twist has the map <V₁,V₂,V₃>→<V₂,−V₁,V₃>.

As noted above, all these pieces should be regarded as having zero length. If it is desired to give them finite legs, we could insert a shift p on line 3, perhaps later taking it in the limit p→0.

### Circuit Analogues of Inversion Pieces

Inversion pieces enable us to put twists into the model manifold while staying in the same plane. Thus, they are useful for building linear 2D model manifolds involving arbitrary maps. These pieces implement rotation around the 3-axis by multiples of 180°.

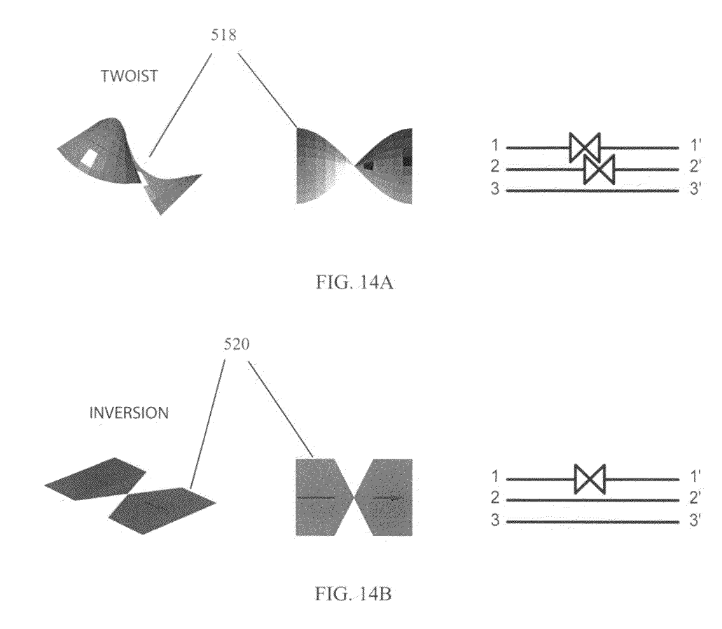

FIG. 14 shows two inversion pieces of the model branched manifold and their 3-wire circuit analogues.

FIG. 14A shows the twoist piece 518 (named because it is two twists connected in series), which produces a 180° twist around the 3-axis. This piece is implemented by inverting the V₁ and V₂ wires. Its map is <V₁,V₂,V₃>→<−V₁,−V₂,V₃>.

FIG. 14B shows the inversion piece 520, which produces an inversion of the 1-axis, normally centered at V₁=0. This piece is implemented by inverting the V₁ axis. It has the map <V₁,V₂,V₃>→<−V₁,V₂,V₃>. The twoist piece produces negative Poincare densities, ρ→−ρ, which is not valid for branched or model manifolds, hence we will not normally use it, preferring the inversion piece instead. This point will be elaborated subsequently.

As before, these pieces should be regarded as having zero length, with the proviso that they could be given an arbitrary finite length by adding a shift on line 3.

Inversion of the 3-axis, which would represent time-reversal, is an interesting idea, but in this invention we assume that signals propagate uni-directionally through the circuit manifold.

### Circuit Analogues of the Split Piece

The split piece enables us to divide a branch of the model manifold into two non-overlapping branches. This makes sense only if the orbits in the branch can be arranged into disjoint groups. If branches interact, they must be considered as a single branch.

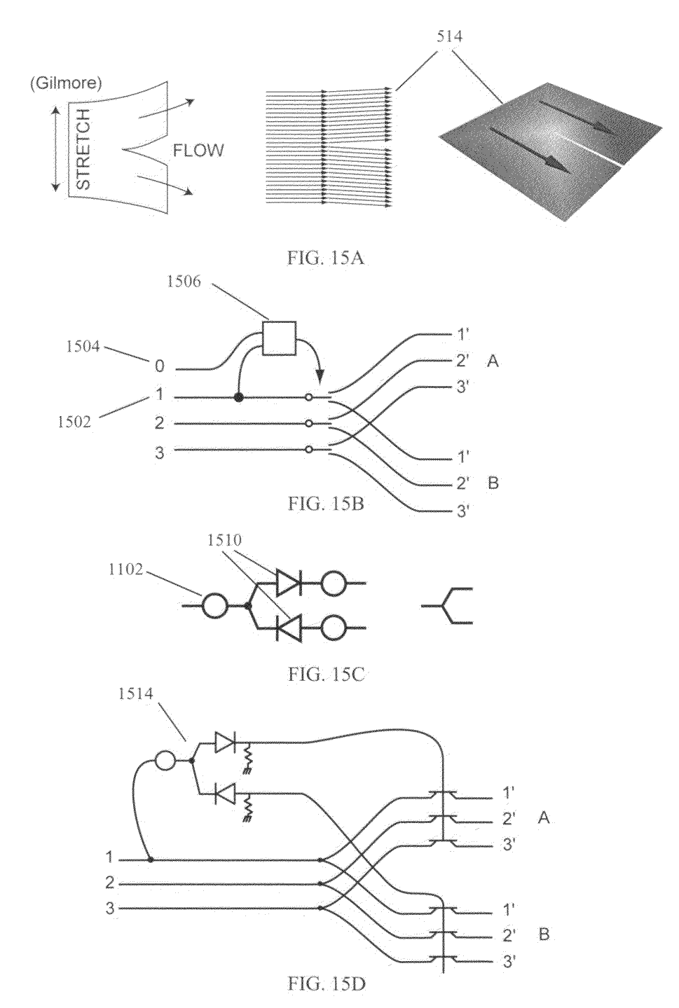

FIG. 15 shows the split piece 514, together with some variations for using it.

FIG. 15A shows three representations of the split piece. It could be visualized as a blade cutting a moving ribbon longitudinally, or wall in a river that divides the flow into two branches. The actual split function occurs at a single value of the time, hence the piece actually has zero length.

FIG. 15B shows one way to implement the circuit analogue of the split piece. Line 1 1502 is sampled and compared with a reference voltage V₀ 1504. The output from the comparator 1506 is a Boolean signal that controls the connection of this circuit to the next circuit: If the incoming V₁ value is greater/less than V₀, the 3-wire circuit is connected to branch A/B 1508 (the other branch is left unconnected). Lines 2 and 3 are connected directly to A or B. The split piece has the mapping <V₁,V₂,V₃>→{<V₁,V₂,V₃>_{A}|<V₁,V₂,V₃>_{B}} (where | means “or”).

FIG. 15C shows a fully analog way to implement this circuit. Let V₀=p. Because the split is done on V₁, we use a shift piece 1102 to move the value of V₁ by −p, then use a pair of opposing diodes 1510 to separate the two sub-branches. If V₁>p, the upper branch conducts, while the lower branch will be effectively isolated from the circuit. Conversely, if V₁<p, the lower branch will conduct and the upper branch will be isolated. We will sometimes use the a simplified diagram 1512.

FIG. 15D shows an implementation of the circuit analogue for the split piece using transistor switches 1514. For V₁<p, the analog switches on branch B conduct, while those on branch A are shut off. When V₁>p, branch A conducts and B is shut off.

### Circuit Analogues of the Merge Piece

The merge piece enables us to combine two overlapping branches into a single branch, which in turn enables us to keep the model branched manifold finite, to represent a finite attractor.

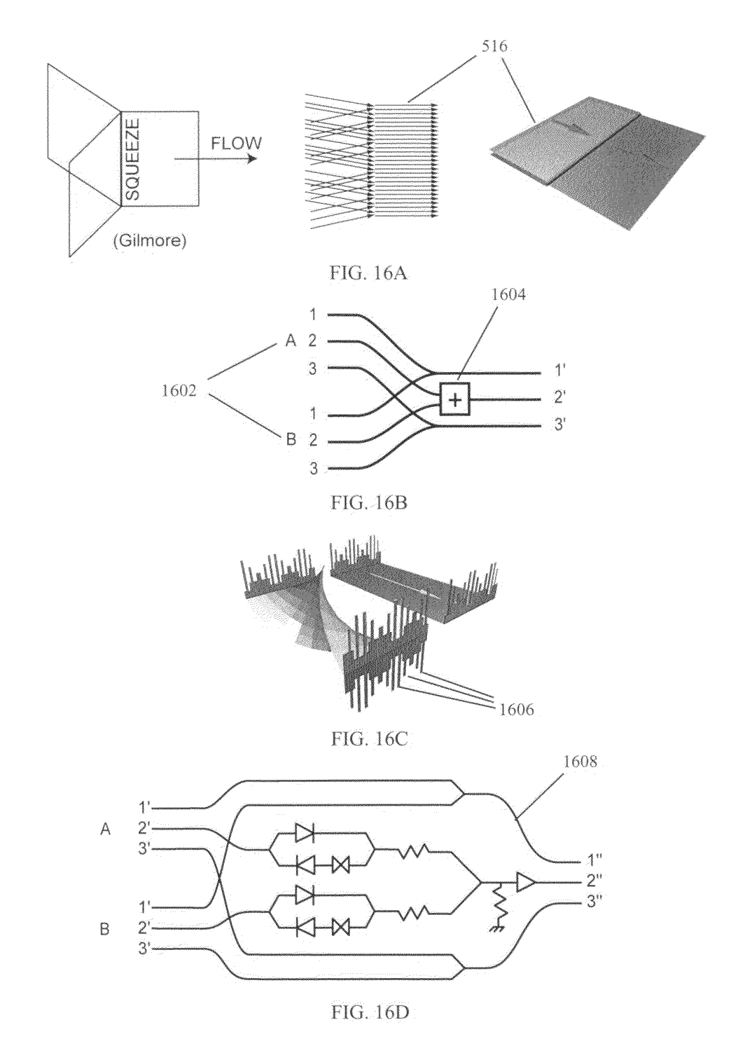

FIG. 16 shows the merge piece 516, including ways to handle the problem of negative Poincare densities associated with the twisted pieces of the model branched manifold.

FIG. 16A shows three representations of the merge piece. It could be visualized as a seam in piece of fabric joining two pieces to a third. The actual merge function occurs at a single value of the time, hence the piece actually has zero length.

FIG. 16B shows one way to implement the circuit analogue of the merge piece. Line 2 from circuits A and B 1602 are summed in an adder 1604 and provided to line 2 of the output. Lines 2 and 3 from A and B are connected directly to the output. The reasoning behind this circuit analogue is as follows: We idealize the merge to comprise two branches in [0,1] that are exactly overlapping in the <x,ρ,φ> space. The merge is then the combination in V₁: [0,1]+[0,1]→[0,1]. For every value of V₁, we have two values of V₂, namely V_{2A} and V_{2B}. Since V₂ represents the density of orbits along the Poincare section, the merge should be the sum of the densities of branches A and B. That is, ρ(x)=ρ₁(x)+ρ₂(x). The values of V₁ in branches A and B are the same, and of course the merge is done at a single value of V₃.

The merge piece has the map <V₁,V₂,V₃>→<V_{1A}|V_{1B},V_{2A}+V_{2B},V_{3A}|V_{3B}>

There is, however, a problem with this definition: The sum of the lines carry values of a Poincare density function (i.e., if both 2A and 2B are positive): if one of the branches leading into the merge had a previous twist, the Poincare density will be numerically negative. This is easy to see if you visualize the plot of the function ρ(x) being rotated by a 180° twist around the 3-axis, which leaves it “upside down.” The problem is, of course, that we cannot have negative densities—we are simply counting orbits, and orbits cannot be “cancelled.”

FIG. 16C shows the problem with negative Poincare densities 1606, and our proposed resolution of the problem. We propose to use the merge pieces as defined, except that we would take the absolute values of the Poincare densities before merging. To implement this in the circuit we need a rectifying circuit before the sum.

FIG. 16D shows a circuit analogue of the rectified model manifold merge piece 1608. The circuit works as follows: If either branch 2A or 2B is negative, it is rectified: V_{2A}→|V_{2A}| and V_{2B}→|V_{2B}|. The series resistors converted these voltages to currents I_{2A}=V_{2A}/R and V_{2B}/R. These currents are added by the summing node to get I₂=I_{2A}+I_{2B}, and the load resistor converts this current back to a voltage V₂=|V_{2B}|+|V_{2B}|. Since this is necessarily less than 1, we scale it with the in-line scaler to normalize it to [0,1]. Lines 1 and 3 are connected directly to the output, since they have the same values, by definition.

### Summary of the Basic Manifold Pieces and Circuit Analogues

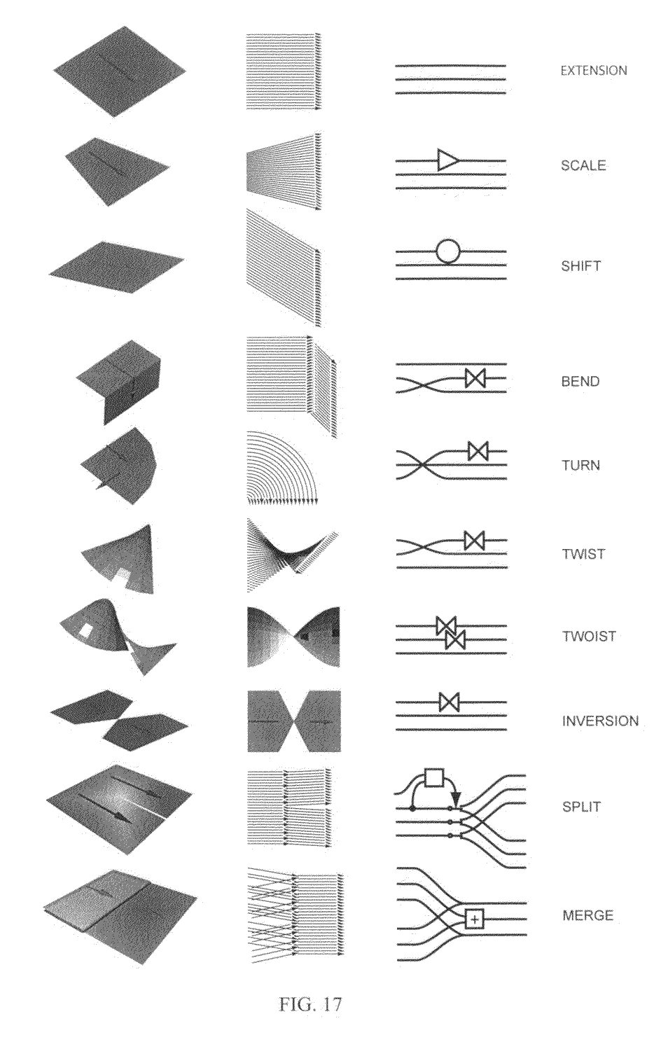

FIG. 17 shows all the basic model branched manifold pieces and their circuit analogues defined so far.

All pieces except the split and merge implement non-singular maps. The split piece has a point singularity and the merge piece has a line singularity.

All model manifolds can be constructed entirely from the set of planar, uniaxial pieces (extension, shift, scale, bend, turn, twoist, inversion, split), plus the nonplanar merge pieces (twist, merge).

In spite of the 3D character of the twist, it can be compensated with another twist piece, thus enabling a manifold to be effectively planar. Similarly, the twoist piece, while being 3D, is really a map of a line into the same line, hence is 2D. The inversion has the same property, hence is 2D.

The merge piece, however, is intrinsically 3D, because it is not single-valued. There is simply no way to escape the fact that the two incoming branches must originate from out of the plane, hence the model branched manifold must be 3D.

For all the pieces in this table, the extension in the 3-axis direction is actually immaterial; they can all be reduced to zero-length. Alternatively, they can be extended with an arbitrary shift in the local 3-axis.

### 3-Wire Vs 1-Wire Circuit Manifolds

The definition of circuit analogues of the 3D branched manifolds requires them to have 3 wires. For such circuit manifolds, the three dynamical variables <x,β,φ> must be tracked from segment to segment—the circuit voltage V₁ may be the analogue of x, α, or φ, and this may be different in different segments. We must carry along all three wires around the entire branched manifold, because the analogues shift among themselves from segment to segment.

However, if a finite number of cuts will permit unrolling the branched manifold into a single connected 2D flat ribbon structure, it will be advantageous to do so, since this will enable us to use 1-wire circuit manifolds. The reason for this is that V₁ is the analogue of the independent variable x, and V₃ is the analogue of the time variable φ, but there is no circuit variable V₂, since there is no Poincare density ρ. Thus, the function V₁(V₃) can be represented by a single wire with voltage V₁ which undergoes a series of point transformations, or maps. Here, time is not a dynamical variable, since the complete sequence of transformations corresponds to the transit of the state through one cycle on the attractor. The transformations therefore compute nested functions: traversal of a 9-segment linear branched manifold will generate V₁′=f₉(|f₈(f₇(f₆(f₅(f₄(f₃(f₂(f₁(V₁). The obvious question is: When do we need the 3-wire circuit manifold, and when willa 1-wire circuit manifold do? The answer is: If the model branched manifold has topological knots, the 3-wire circuit manifold is required; if not, the 1-wire circuit manifold is sufficient. This is because the (inevitable) finite width of the ribbon will prevent the branched manifold from collapsing into a point, which can occur in the absence of knots. The collapse is enabled because the transformations do not couple V₁ to V₂ or V₃. In fact, a model branched manifold without knots will automatically connect wires 2 and 3 into closed (and therefore trivial) loops.

### Compound Pieces

It is convenient to use the basic model manifold pieces to construct compound pieces of manifolds that occur often.

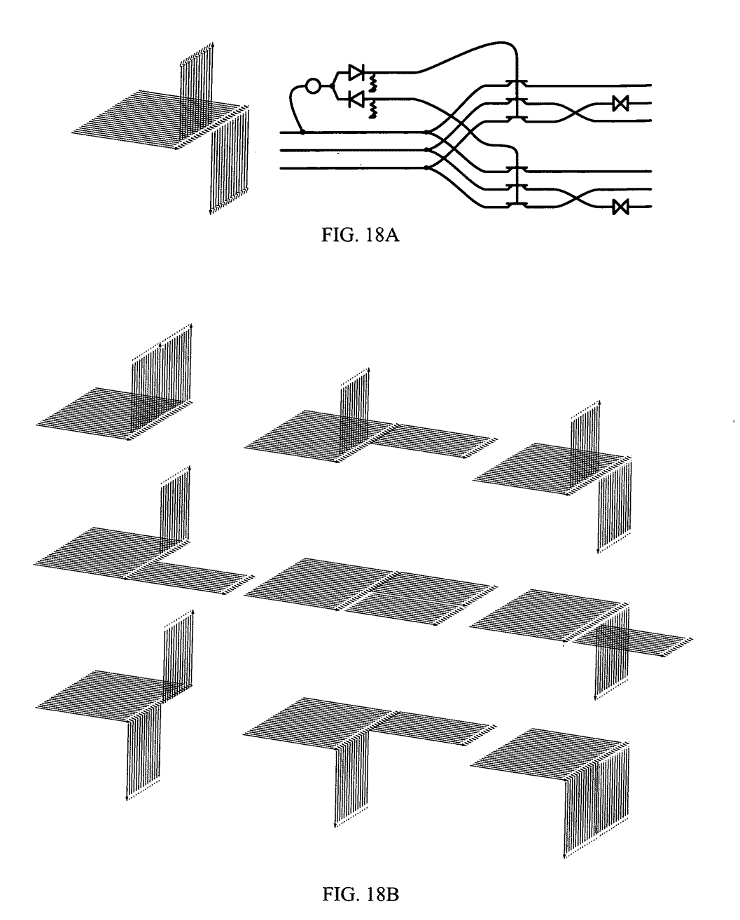

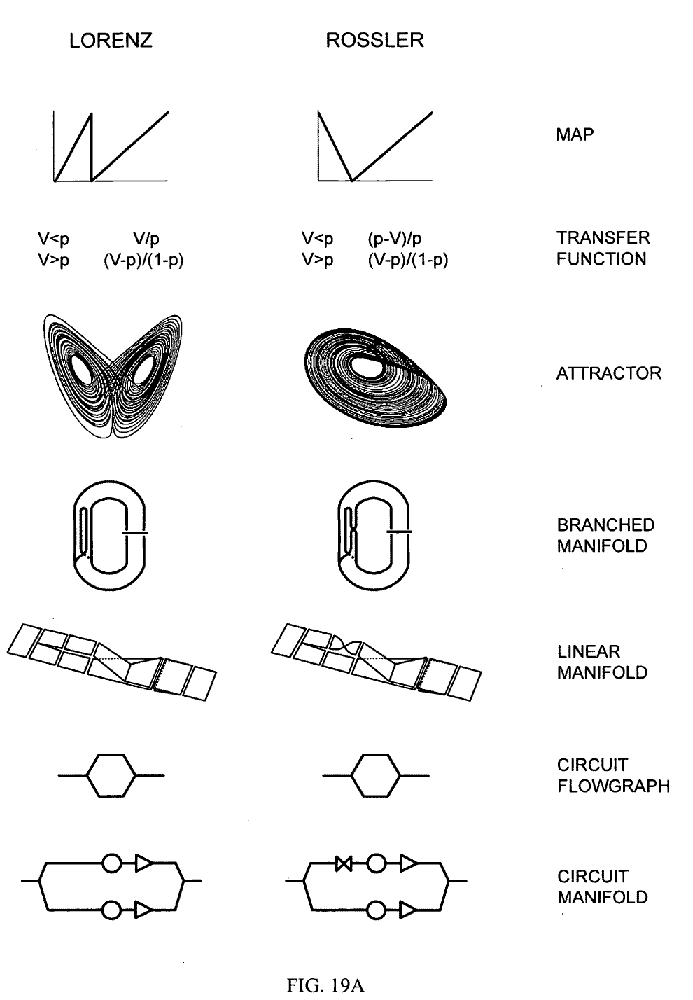

FIG. 18 shows examples of combining three pieces to make compound pieces.

FIG. 18A shows the combination of the split piece, followed by a bend piece in each of the two branches, together with its circuit analogue.

It is central to this invention that the combination of circuit analogues be done with the same topology as the combined pieces of the model branched manifold. Thus, the output of the split piece is two ribbon branches; each branch is then connected to a bend. In the analogue circuits, the bend pieces are implemented by exchanging wires, while the split piece is implemented with a discriminator.

FIG. 18B shows various ways to combine the split with bend pieces. The flexibility in such assemblies will make it rather easy to assemble the model branched manifold, and therefore its circuit analogue. It should be clear that the assembly of such pieces can be mechanized, taking advantage of the hierarchical nature of the assemblies.

### Simplifying the Modules

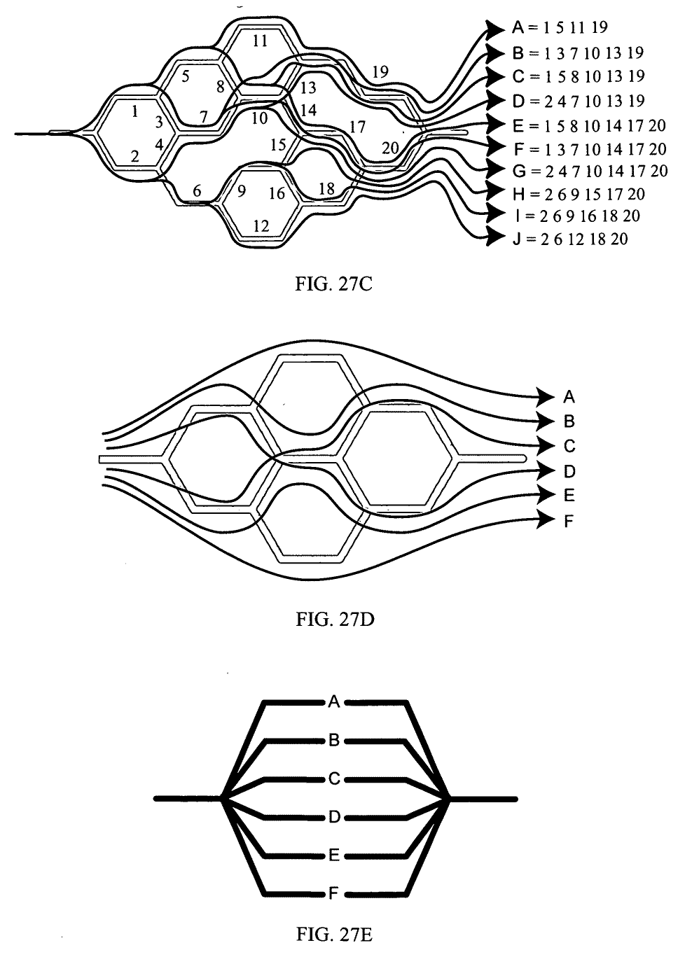

Certain combinations of basic modules occur repeatedly. It is relatively easy to replace such combinations with an equivalent device. For instance, the 3-device series combination (inverter, shifter, scaler) which generate the functions x→−x, x→x+p, and x→cx, can be replaced with the single function x→c(p−x). This could be shown pictorially by replacing a series of symbols by a single (new) symbol. Such replacements will be useful to convert networks to independent paths, which we will show below (cf. FIGS. 27D,E).

### CIRCUIT MANIFOLDS

### Examples

### Example: The Lorenz and Rössler Systems

We describe here two very simple and similar examples of branched manifolds, the Lorenz system and the Rössler systems. These systems generate trajectories in phase space that are cyclic but not periodic. The attractors can be quantified by the Poincare densities, but we will cut and unroll them to examine single trajectories. This procedure generates a flat 2D ribbon model branched manifold, which enables us to define a simple analogue circuit.

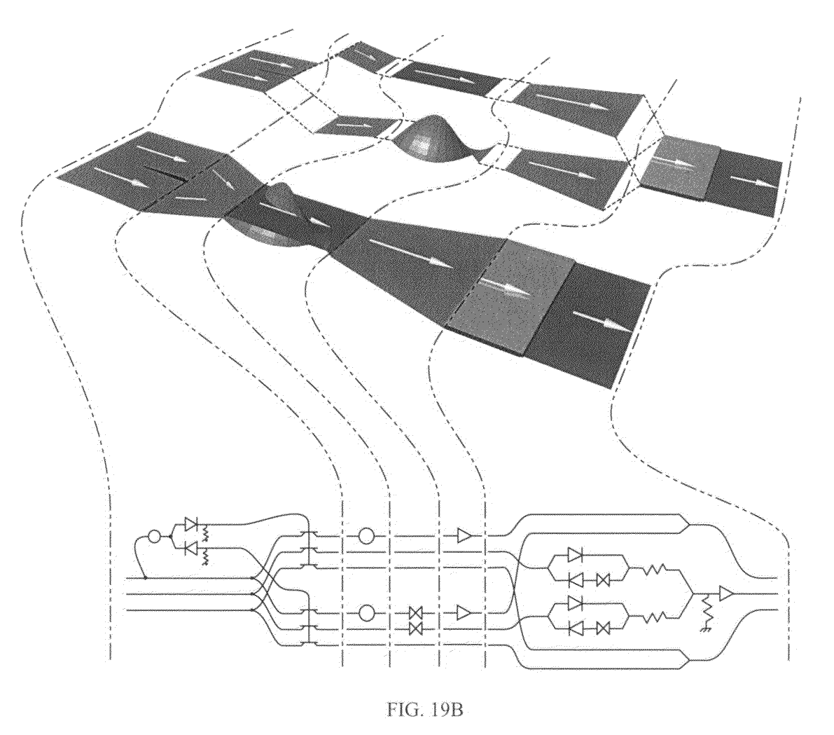

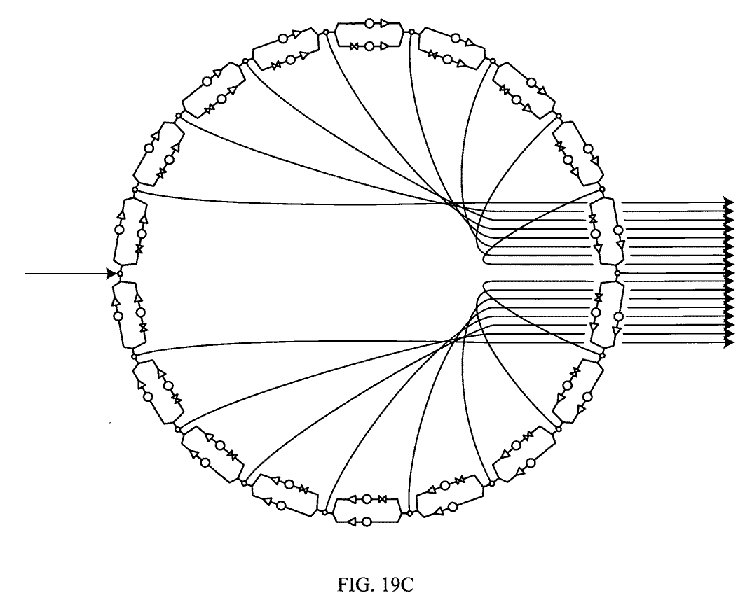

FIG. 19 demonstrates the general approach for designing circuit analogues of the Lorenz and Rössler systems.

FIG. 19A shows branched manifolds associated with the Lorenz attractor and the Rössler attractor. We discuss these two examples together.

The systems are defined using 2-segment linear MAPS: the Lorenz system has a sawtooth map, while the Rössler system has a tent map (inverted). These maps are familiar from chaos theory. The maps are defined by simple TRANSFER FUNCTIONS that can be used to generate the attractors by iteration.

In both systems, the ATTRACTORS are spiraling ovals that never close. The Lorenz attractor has two lobes; the trajectories switch chaotically from one lobe to the other. The Rössler attractor has a single folded lobe similar to a Möbius strip.

The BRANCHED MANIFOLDS associated with these attractors are in the form of single loops that are split and then merged together. In the Lorenz system, the split branches remain flat until they are merged. In the Rössler system, one split branch is twisted 180° before merging.

In order to reduce these 3D branched manifolds to 2D, we cut them transversely and unroll them to form flat ribbons. These LINEAR MANIFOLDS can be assembled using the simple, standard pieces (cf., FIG. 17). The model branched manifold constructed by assembling the pieces has the same local topology as the original system; performing the cut reduces the global topology from 3D to 2D but leaves the local topology unchanged. Note that the Rössler system retains the twist, which is in principle a 3D object but in fact can be implemented with the inversion piece as a 2D object.

Ignoring the twist (or inversion), both of these manifolds have the same topology, namely a single split followed by a single merge. We can therefore represent both of them with the same (simplified) diagram called a FLOWGRAPH. The flowgraph for these two systems is a single split/merge island. Flowgraphs will be described in detail below.

The circuit analogues for these two systems are obtained easily using the circuit analogues for the individual pieces (cf., FIG. 17). In analogy with the term branched manifolds, we refer to such circuit analogues as CIRCUIT MANIFOLDS.

### Example

### The Unrolled 3-Wire Rössler Manifold

FIG. 19B shows the details of the Rössler unrolled model branched manifold, and its 3-wire analogue circuit manifold. The Lorenz version differs only in not having the inversion in the lower central sub-branch.

### Example

### An 18-Module 1-Wire Circular Rössler Circuit Manifold

FIG. 19C shows a 1-wire circuit manifold constructed by assembling 18 Rössler modules into a ring. The nodes between modules constrain the voltages to exactly 18 values (which must be all different). In this figure, one node voltage is set, which determines the other 17 voltages.

This circuit manifold therefore implements a period-18 function, the analogue of a Rössler orbit that makes 18 cycles around the attractor and returns to its exact initial point. The 18 node voltages give the 18 values of the independent variable as the trajectory completes each cycle.

Circular linear circuits such as this have the very powerful property of determining (“computing”) periodic orbits in chaotic attractors. As emphasized by Gilmore and others, such orbits “organize” the chaotic behavior by separating the motions into bundles of unstable trajectories. We cannot over-emphasize the advantage of this circuit in performing such computations: here, the normally laborious task of numerically searching for periodic orbits is obviated by the (essentially instant) process of determining a set of node voltages.

Given a circular circuit manifold with N nodes, all orbits of period 1 . . . N can be determined by simply connecting two nodes. Because most of the significant behavior of the system is described with a finite set of low-N orbits, a circuit manifold of, say, 32 nodes could easily generate the entire set of periodic orbits for almost any reasonable chaotic system. This point will be elaborated with additional examples later.

### Example

### A 3-Branch 1-Wire Circuit Manifold

Here we examine an unrolled model branched manifold fragment, representing a single cycle of the presumed chaotic trajectories. The model manifold fragment has a single branch that splits into three sub-branches A, B, and C. These sub-branches then undergo various 180° twists before merging into a single branch.

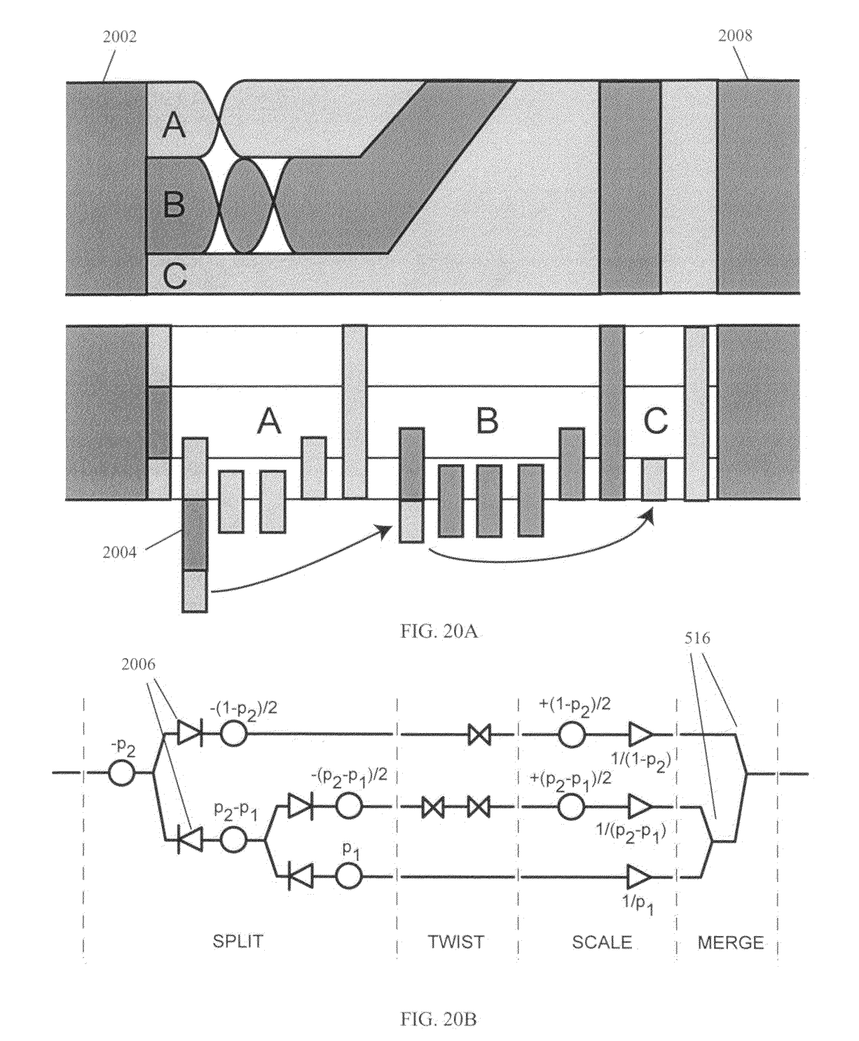

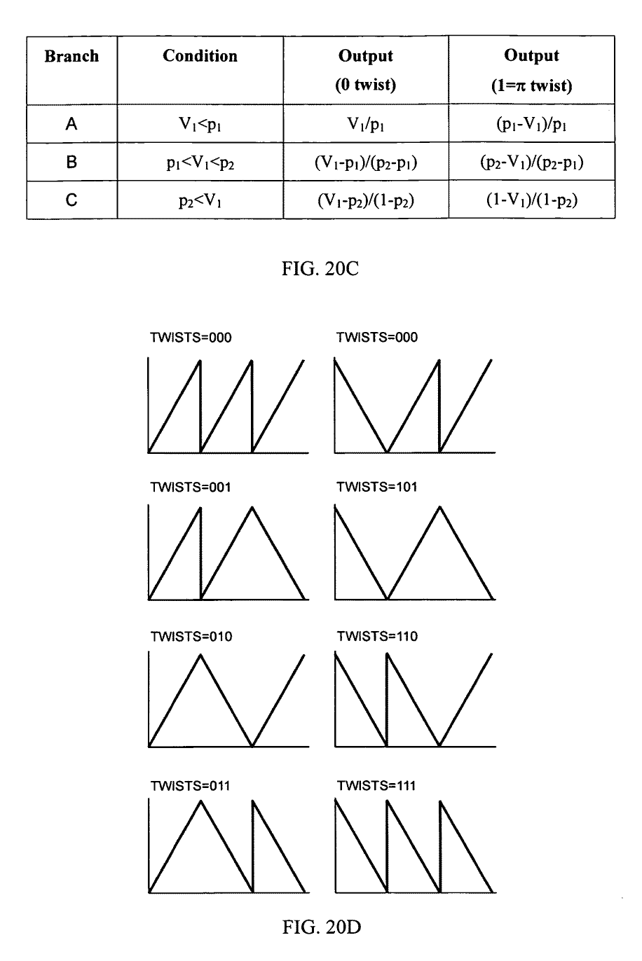

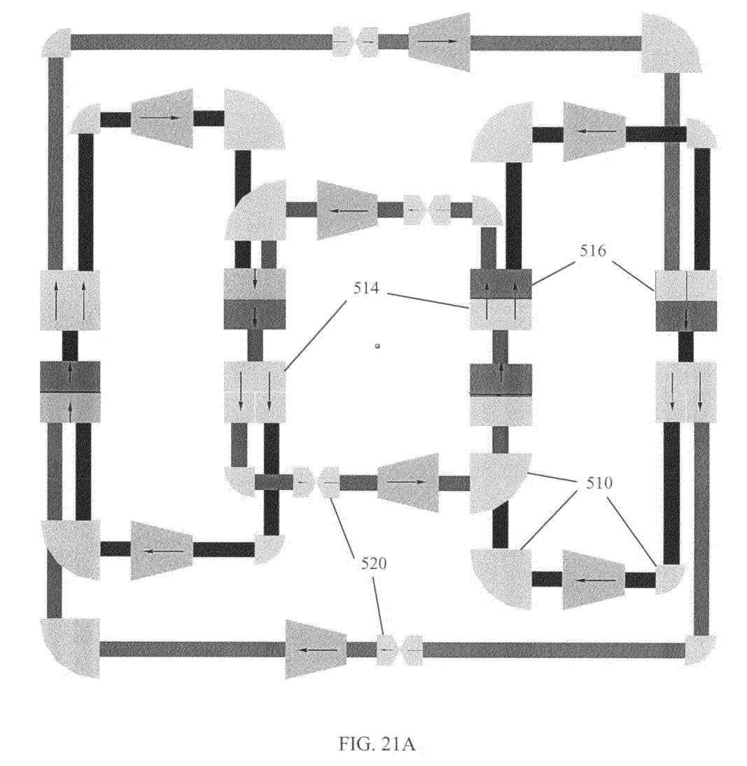

FIG. 20 shows a procedure for assembling the circuit analogue. The incoming branch 2002 occupies the interval V₁ε[0,1]. It is separated into the sub-branches: C=[0,p₁], B=[p₁,p₂], and A=[p₂,1]. The strategy is to use shifts, inversions, and scalings to isolate the individual sub-branches and map them to the full interval [0,1]. Each transformation corresponds to inserting one of the canonical circuit modules.

FIG. 20A shows the full sequence of transformations 2004. First, the value of V₁ is shifted by −p₂. The split analogue circuit uses a pair of diodes 2006 to separate positive signals from negative ones.

If V₁>p₂, V₁ is in branch A. We then apply a 180° twist in that branch (only). This is done by shifting the branch down by ½(1−p₂) to get V₁−½(1+p₂), inverting it to get −V₁+½(1+p₂), shifting it back up by ½(1−p₂) to get 1−V₁, and finally scaling it by 1/(1−p₂) to fill the full branch width [0,1]. The net map is (1−V₁)/(1−p₂).

If, instead, V₁<p₂ is negative, we shift it up by p₂−p₁ to get V₁-p₁ and test this value. If V₁>p₁, we know that V₁ is in the B branch. We therefore apply two 180° twists using the procedure described above.

Finally, we scale V₁ to fill the full interval [0,1]. If, however, V₁<p₁, we know that V₁ is in the C branch. We therefore shift it up by p₁ and scale it by 1/(1−p₁) to fill the interval [0,1].

The net result of these manipulations is to map all 3 sub-branches into the interval [0,1] 2008. They are then combined using the MERGE piece 516. The three branches can be combined with a single tie point because only one branch can have a signal at any time. We emphasize this point: although the circuit has three branches A, B, C, only one of them can have a signal (conduct positive current) at a time; the particular branch that conducts is determined by the value of V₁ at the input.

FIG. 20B shows the complete circuit analogue of this manifold fragment. The various pieces in this circuit correspond to the transformations, and the circuit has the same topology as the manifold.

It should be noted that the modules group naturally in the sequence SPLIT-TWIST-SCALE-MERGE. We will find this to be a common pattern, and it fact conforms to the branched manifold organization established by Gilmore and colleagues. We also note that the two successive 180° twists in branch B leaves the branch unchanged, hence they could be omitted by inspection. We can put an arbitrary combination of 180° twists in the three sub-branches A, B, and C. An odd number of twists will produce inversion in that sub-branch.

FIG. 20C shows the various possible combinations of twists in the three branches.

FIG. 20D shows the first-return maps for these 2³=8 cases, assuming the values p₁=⅓, p₂=⅔.

### Example

### The Figure-8 Wire Loop Circuit Manifold

We return now to apply these techniques to a more complicated case, namely the model branched manifold for the current-carrying wire loop, shown in FIG. 7.

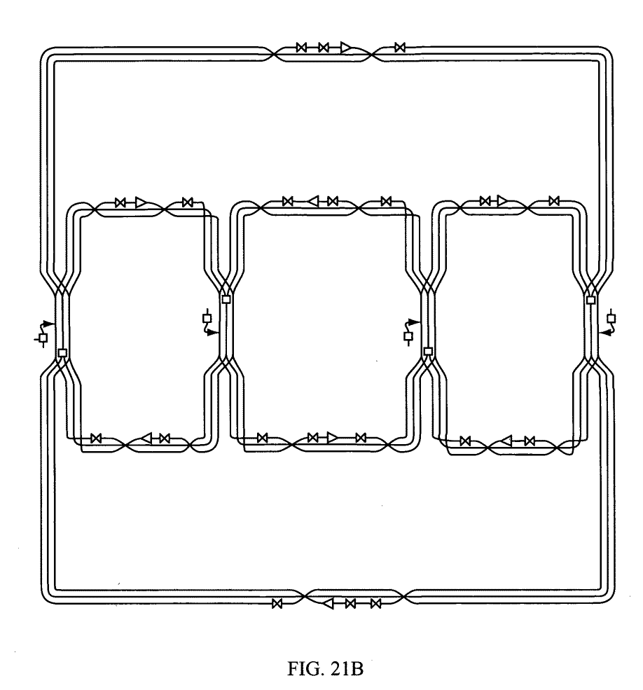

FIG. 21 shows the figure-8 model branched manifold and its circuit analogue.

FIG. 21A shows a projection of the complete model manifold. As before, the connections (extensions) are shown as narrow lines only for clarity; they represent the full-width ribbon manifold pieces that must join smoothly with adjacent pieces, with no hanging edges, dead-ends, intersections, etc. The complete manifold has 4 splits 514 and 4 merges 516, 16 turns 510, 8 scalers 504, and 4 inversions 520.

FIG. 21B shows the complete 3-wire circuit analogue for this model branched manifold. This circuit is obtained from the model branched manifold by direct substitution of the basic circuit modules (FIG. 17). The topological identity between the manifold and circuit is obvious.

### Arbitrary Maps

The model manifold can be arbitrarily complex, with nonlinear and discontinuous sorting of the orbits. The procedures already developed apply straightforwardly, as we now show.

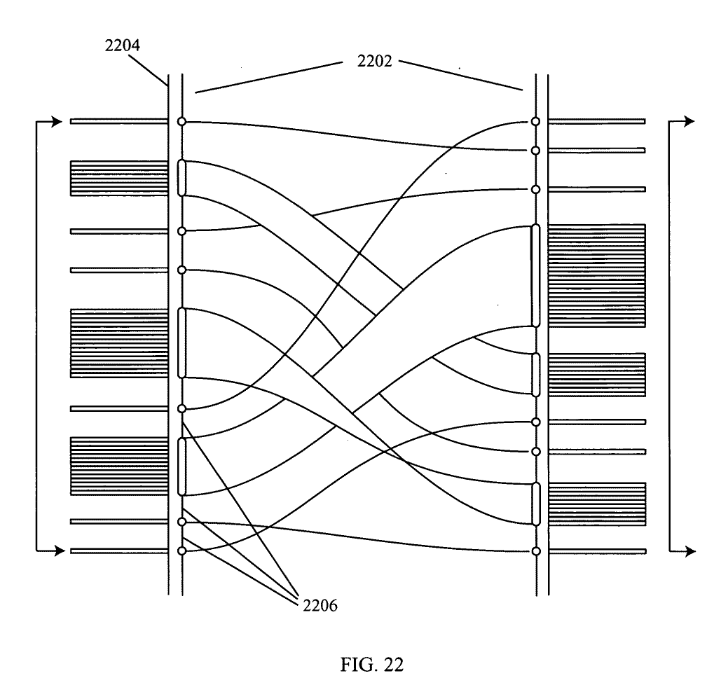

FIG. 22 shows a model manifold piece that implements an arbitrary, relatively complex transformation 2202 on the dynamical variable (the V₁ axis 2204). In order to help with visualization, we put spaces 2206 between the various branches; the system may or may not have such forbidden values. Taking the branches in sequence, the map could have the following algebraic representation (|=“or”):

x→{f₁(x)|f₂(x)|f₃(x)|f₄(x)|f₅(x)|f₆(x)|f₇(x)|f₈(x)|f₉(x)}.

Implementing such complex circuits presents alternatives. In principle, it is possible to synthesize an arbitrary function by breaking it into many sub-branches and applying simple linear transforms to each sub-branch. However, if we fabricate the circuits incorporating nanoelectronics, we can exploit intrinsic nonlinearity (and possible discontinuities) to generate very complex functions without sub-branching. The task will be not so much to fabricate such circuits, but to design the algorithms to make use of them in complex computations. The computational power of such complex maps will be very great.

### Reconfigurable Circuit Manifolds

Considerable advantage obtains if the circuit analogues of branched manifolds can be reconfigured at run time. Here we show that this is a straightforward task using analog circuits.

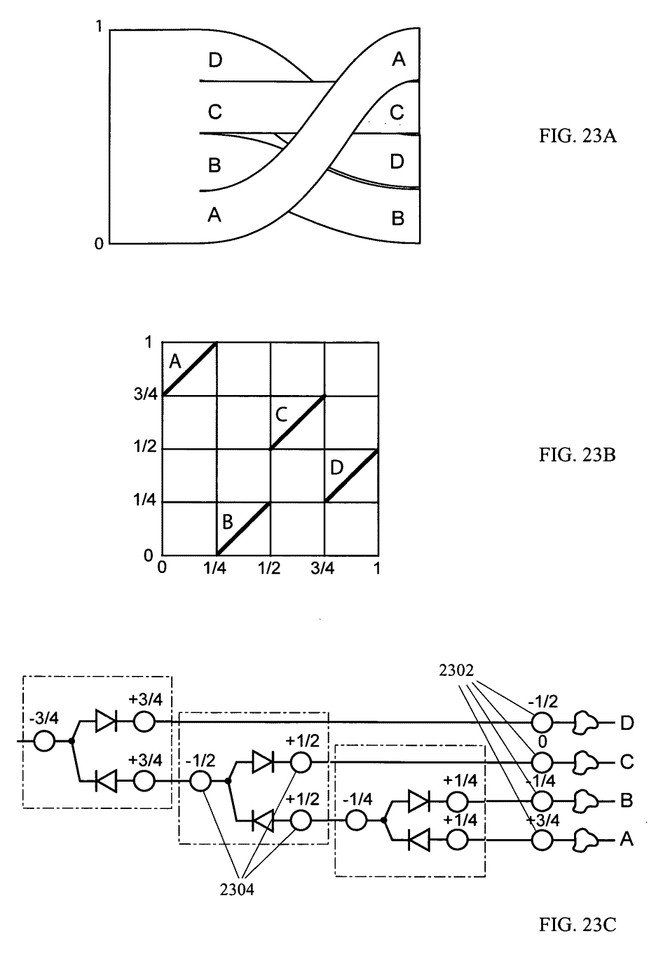

FIG. 23 shows how to reconfigure a 4-branch manifold fragment by reconfiguring its circuit analogue.

FIG. 23A shows one example of a 4-branch manifold fragment.

FIG. 23B shows the 4-segment piecewise linear map corresponding to the manifold. The segments can be arbitrarily positioned.

FIG. 23C shows the circuit analogue for the manifold, obtained by the procedure used in earlier examples. It is easy to see that the circuit uses three split pieces to separate the signal into the four branches; each branch is then transformed according to the 4-piece map.

Reconfiguration of the initial splitting of the branches is easy: they are determined by the shifters in the three split blocks (all of which have the same absolute value). The three blocks, indicated by the dashed rectangles, correspond to the splits A-B, B-C, and C-D. For instance, the +/−½ shifters 2304 define the B-C split.

Reconfiguration of the final branch positions is similarly easy: the final four shifters (−½,0,−¼,+¾) 2302 determine the final position of the branches (branch A is shifted up by +¾, branch B is shifted down by ¼, etc.). Simply altering these shifts will rearrange the final branch positions.

It is obvious that these circuits can be reconfigured during run-time, e.g., by using the results of a previous calculation to alter the branch splits. This facility provides the powerful opportunity for adaptive computing, optimization, model alteration, etc.

### Example

### Linear/Anti-Linear Maps

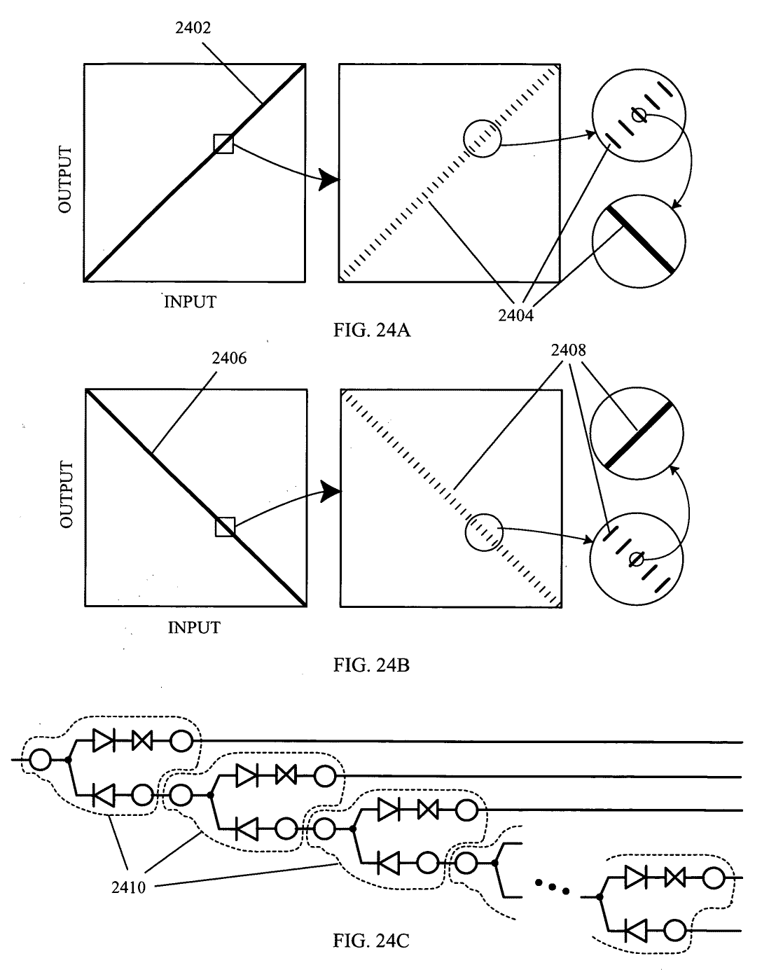

FIG. 24 shows two rather bizarre maps consisting of series of tiny linear ramps.

FIG. 24A shows a map that is globally linear but locally anti-linear. It is globally similar to the identity map 2402 but the individual segments 2404 make it locally similar to inversion. This map corresponds to a manifold fragment that is cut into many thin slices (branches), each of which is given a half-twist but no displacement.

FIG. 24B shows a map that is globally anti-linear but locally linear. It is globally similar to the inversion map 2406 but the individual segments 2408 make it locally similar to identity. This map corresponds to a manifold fragment that is cut into many thin slices (branches), which are then displaced symmetrically across the manifold midline (but without any twists).

FIG. 24C shows the circuit analogue corresponding to these maps. The circuit modules 2410 implement the splits and displacements. The diagram is meant to imply extension to as many stages as desired number of steps in the map.

These circuits will have the strange property of acting one way globally and the opposite way locally. Thus, they will respond differently to large and small signals. This aspect could be of value in dealing with computations with two very different scales.

### Flowgraphs

### DEFINITION

The examples in the previous section illustrate analog processing modules having the character of a multiply-branched network with a single input and single output. The branches are created by split units and terminated by merge units. In between, any link can have an arbitrary processing circuit that generates an arbitrary function.

The split units sense the input values and route them accordingly, and the merge units combine signals from all the routed inputs. These constraints suggest that a simplified version of the networks will be useful in classifying and developing circuit manifolds. We will refer to these objects as circuit flowgraphs, or just flowgraphs.

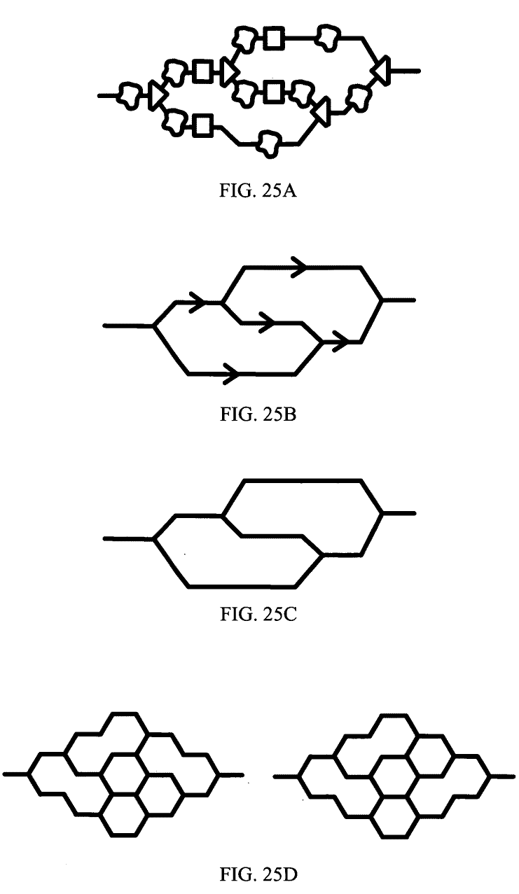

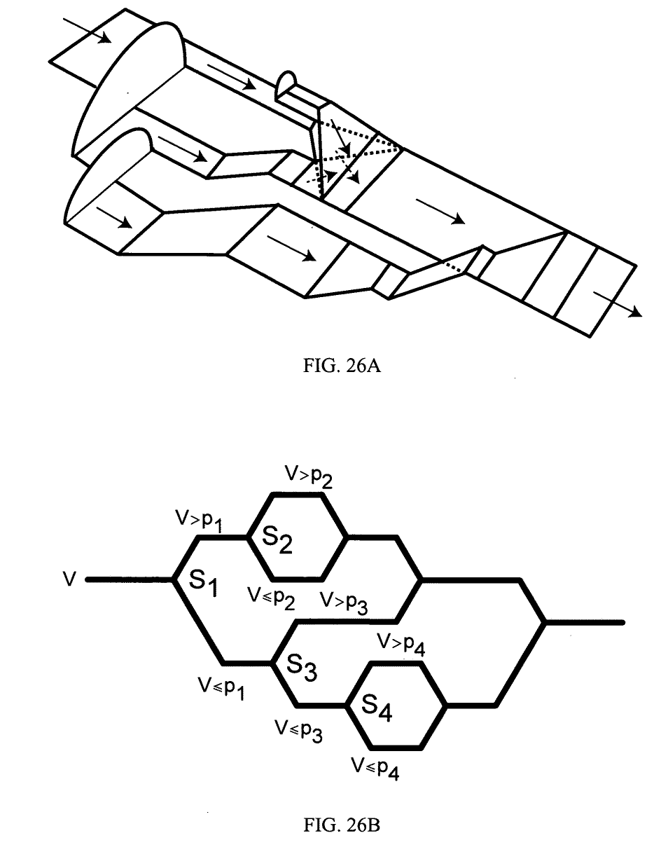

FIG. 25 shows how flowgraphs are defined from circuit manifolds, and indicates that they are useful topological objects.

FIG. 25A shows a typical circuit manifold, containing 13 modules plus 2 splits and 2 merges. Between the split and merge, the circuit has 5 links, and encloses 2 islands. The connections between modules are, in principle, 3-wires, but if we are dealing with linear chains of these manifolds, we need only 1 wire to represent the independent variable (V₁ only).

FIG. 25B shows the topological structure of this circuit manifold. Here, all the modules have been stripped away—only the connections are left, except that the direction of signal flow is indicated by the arrows.

FIG. 25C is the same as the previous diagram, but without the arrows, under the convention that the signal flow is always left-to-right. This form of diagram, with implied left-to-right direction, is what we call a flowgraph.

FIG. 25D shows two flowgraphs that are superficially similar, but are in fact not topologically equivalent.

Flowgraphs are useful for classifying circuit manifolds according to their topology. Indeed, they comprise a set of independent, irreducible graphs with which to construct larger graphs, thereby providing arbitrary scaling of circuit manifolds. However, it is important to note that a flowgraph does not uniquely specify a model branched manifold, because it contains no information about branch twists. In general, each link can have either an even number of half-twists, or an odd number of half-twists (inversion). Thus, a flowgraph with M links represents 2^{M} possible different branch manifolds. Flowgraphs have various statistical properties, described below.

### Example

### A 4-Split 3-Twist Manifold

The flowgraph for any model branched manifold can be drawn easily by inspection. The links represent the various branches of the manifold, and splits/merges are shown as vertices.

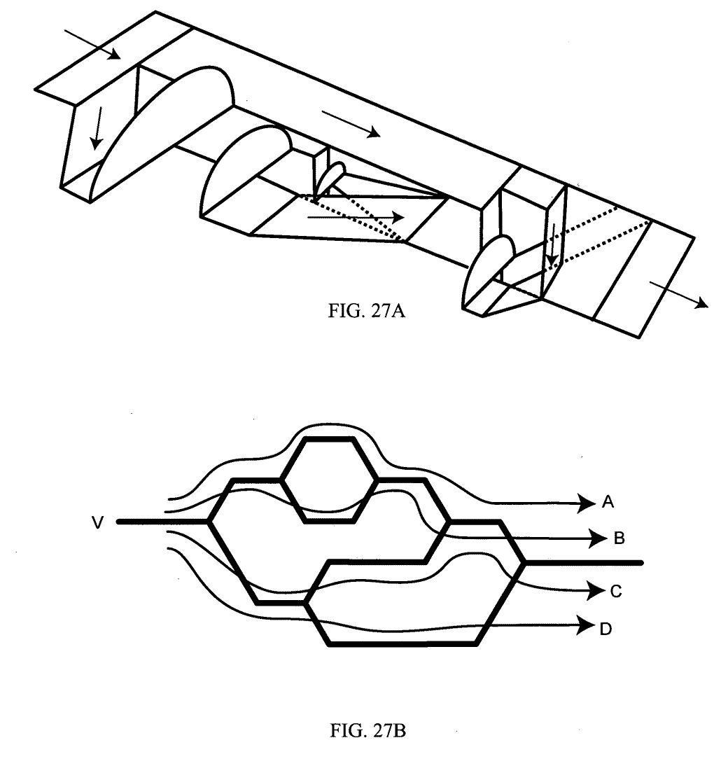

FIG. 26 shows a 4-split 3-twist manifold fragment and its associated flowgraph.

FIG. 26A shows the model branched manifold fragment; the arrows indicate the convention for direction of the signal flow.

FIG. 26B shows the flowgraph corresponding to the circuit manifold. The flowgraph contains 4 arbitrary control parameters p₁, P₂, P₃, and p₄. At the leftmost split S₁, the value of V₁ is tested against p₁. If V₁>p₁, V₁ is presented to the split S₂, where it is tested against p₂. If V₁>p₂, V₁ is processed on the p₂ branch; if V₁<p₂, V₁ is processed on the 1−p₂ branch. When V₁<p₁, it is presented to the split S₃, where it is tested against p₃. If V₁>p₃, V₁ is passed through the central link, merged twice and presented to the output. If V₁<p₃, V₁ is passed to split S₄, where it is tested against p₄. If V₁>p₄, V₁ is processed along the upper link and merged into the output. If V₁<p₄, V₁ is processed along the lower link, merged, and passed to output.

We emphasize again that the signal in a flowgraph is present in only one branch; which branch is determined by the value of the incoming signal. Connecting multiples of identical flowgraphs in series corresponds to the system executing multiple cycles around the attractor. Periodicity can be imposed by closing a linear chain of such flowgraphs into a ring. The advantage of this procedure is that the normally iterative computation is fully cast into hardware.

### Paths

A path through a flowgraph is a sequence of links. All paths are unique: the sequence constitutes a word or name for the path. We will also use a simple letter symbol (e.g., A,B, . . . ) for paths.

FIG. 27 shows typical paths through flowgraphs.

FIG. 27A shows a typical model branched manifold fragment, consisting of 3 splits and 8 links.

FIG. 27B shows the flowgraph corresponding to FIG. 27A. Like the manifold, it has 3 splits and 8 links. There are 4 paths: A, B, C, D. Given the constraint that the signal always passes from left-to-right, these are the only possible paths, and they are unique.

FIG. 27C shows a more complicated flowgraph. It has 7 splits, 20 links (identified with numbers), and 10 paths (identified as link sequences).

An interesting and useful fact about flowgraphs is that usually there are fewer paths through them than there are links. Because the paths are unique, the flowgraph can be replaced by an equivalent flowgraph with only parallel paths, which we now show.

FIG. 27D shows a flowgraph with 4 splits, 10 links, and 6 paths: A B, C, D, E, F.

FIG. 27E shows a fully parallel flowgraph containing the same 6 paths. Each path in this flowgraph is implemented by assembling the appropriate sequence of modules (the links). Note that although it is convenient to represent such fully-parallel flowgraphs as having a single (multi-branch) split, there are in fact N−1 splits for N branches.

The last example illustrates an important point about replacing flowgraphs with their parallel equivalents, namely the individual parallel paths must be constructed to have the same functional effect of the original paths, and this comes at the expense of redundancy. For instance, in FIG. 27C the paths E=1-5-8-10-14-17-20 and F=1-3-7-10-14-17-20 have nearly the same inventory of modules. The total number of modules required for the fully-parallel form is 60, considerably more than the 20 required for the original flowgraph. Turning this around, we could say that the networked flowgraph optimally connects the modules to eliminate redundancy, reducing their number from 60 to 20.

If, however, we are able to combine the modules and replace them with equivalent modules, the fully-parallel flowgraph would be optimal. Thus, FIG. 27D uses 10 modules to produce 6 paths. This could be reduced to 6 (equivalent) modules to produce the 6 paths. In FIG. 27C, the 20 modules could be reduce to 10, again one for each path.

If we find that some paths actually differ little from others, we might be able to reduce the number of required paths. For instance, we might be able to replace the E and F paths with a single (approximately) equivalent one. Furthermore, in designing monolithic VLSI circuits, particularly using nanoelectronics, we might be able to generate the complex functionality of the independent paths with individually designed modules, rather than assembling the parallel branches from the original modules.

To reiterate: the real advantage of casting the flowgraph into its fully parallel form is realized by replacing the original modules with path-specific modules.

It is assumed that all links of flowgraphs can be reached by scanning the range of input values. The fractional use of the various links depends on the parameters of the splits.

A useful convention for numbering the links in a flowgraph is to assign numbers in the following order: (1) Leftmost split; (2) Leftmost merge; (3) Top-to-bottom. Of course, any numbering of links will suffice.

### Paths and Maps

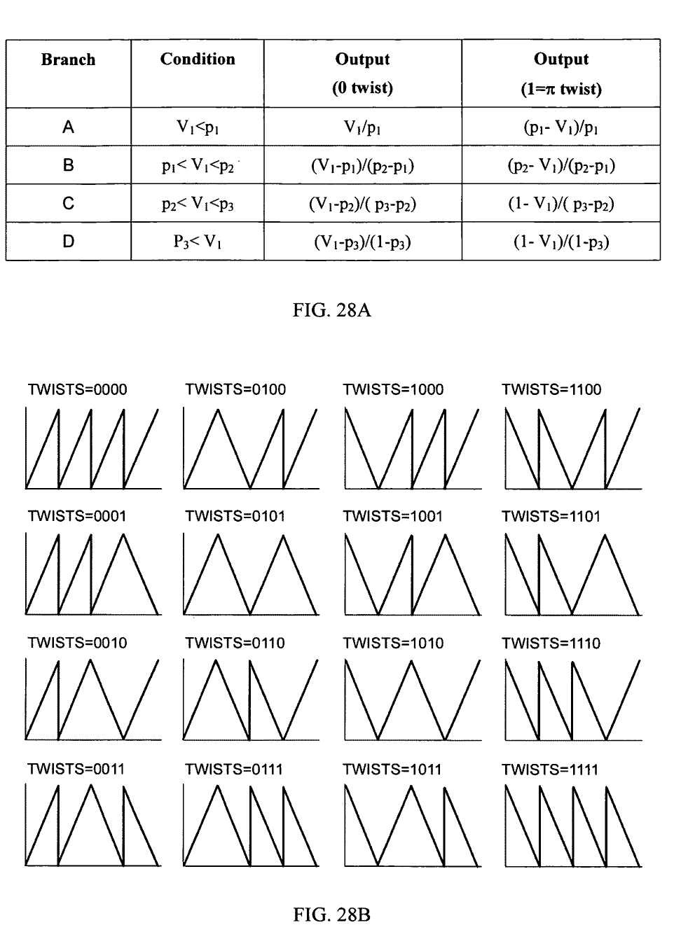

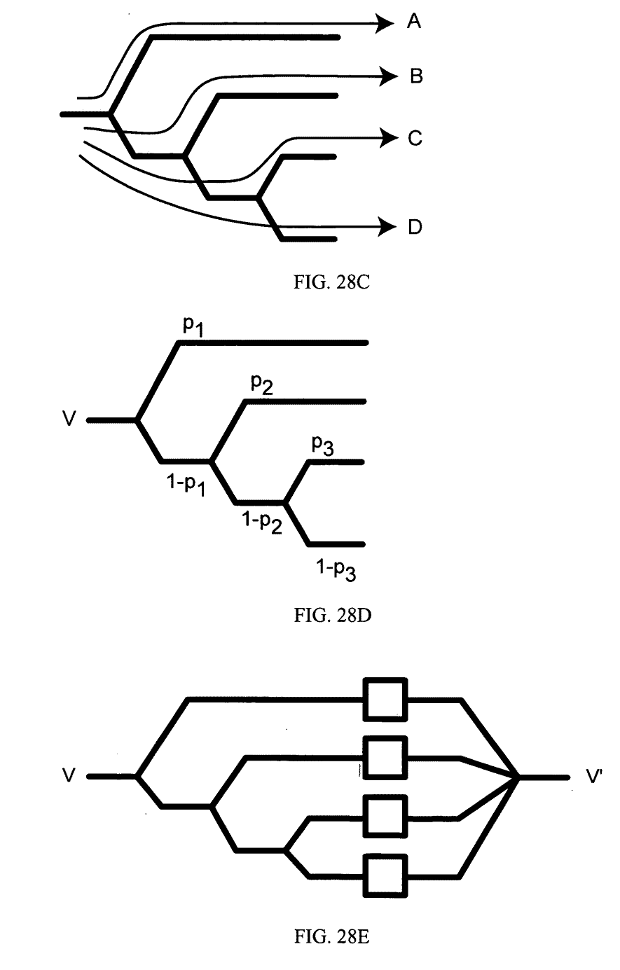

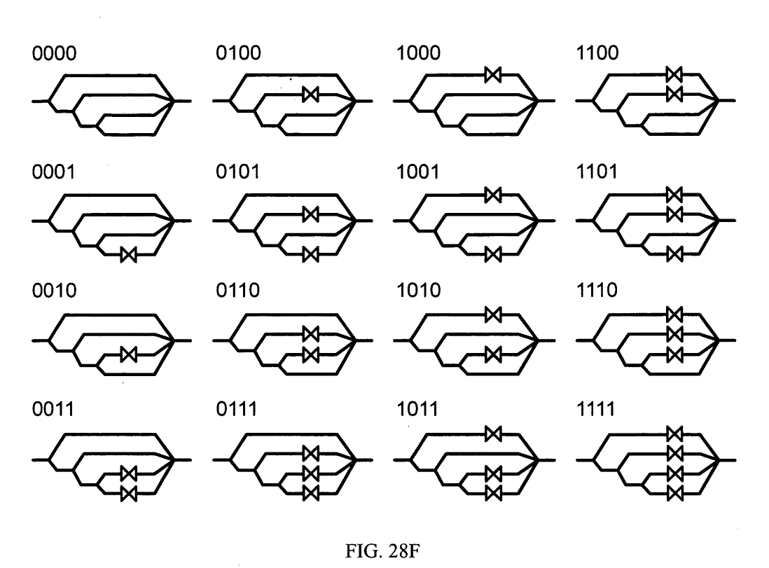

FIG. 28 shows the close relationship between paths and maps.

FIG. 28A shows a 4-segment linear map, implemented by 3 parameters: p₁, p₂, p₃

FIG. 28B shows the maps for the values p₁=¼, p₂=½, p₃=¾. The 16 maps correspond to the 2⁴ combinations of twists in the model branched manifold.

FIG. 28B shows the flowgraph corresponding to these maps. It contains 3 splits and 6 links. It has 4 paths (A, B, C, D) that traverse 1, 2, 3, 4 links.

FIG. 28D shows the usual assignment of the parameters to the flowgraph. By convention, we specify that if the input signal is great than p₁, it proceeds on branch (path) A, otherwise it is passed down and presented to the next split, where it is routed according to whether it is greater or less than p₂, and so on.

FIG. 28E shows that we can simply connect the ends of the paths together. Again, this is because only one path can have a signal at any time. The square blocks in this figure indicate that the modules can be arbitrary. However, we have classified the possible maps for this flowgraph according to the twists, so we can explicitly display this using the inverter to implement the twists.

FIG. 28F shows the 16 possible circuit manifolds (displaying only the inverters) corresponding to the 16 possible twist combinations.

This example emphasizes that the flowgraph does not uniquely specify a circuit manifold; rather, it specifies a set of such manifolds. Thus, corresponding to the single flowgraph FIG. 28E there are 16 unique circuit manifolds FIG. 28F.

### Paths and Islands

Flowgraphs can contain islands, which are closed areas bounded by links. We do not call these features loops, because the flow does not circulate around the islands, but to the sides of the islands. For flowgraphs with a single input and a single output, the number of islands is exactly the same as the number of splits (which is also the same as the number of merges).

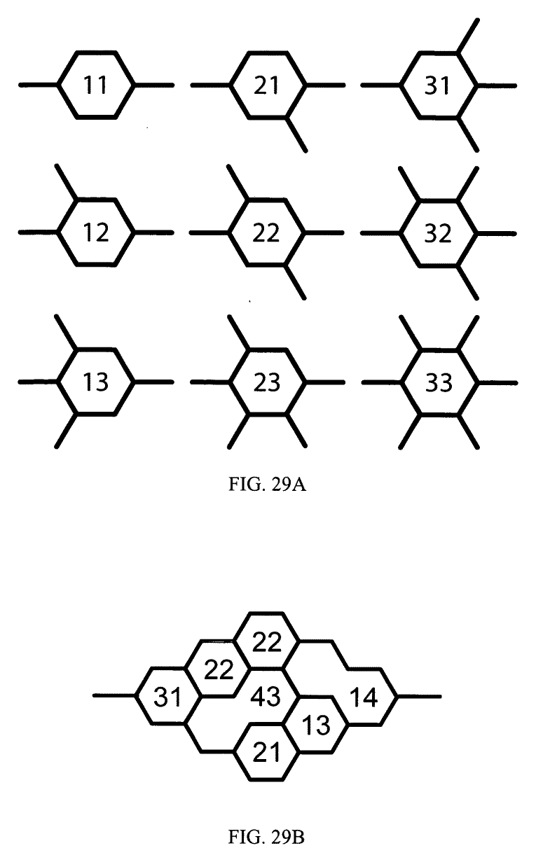

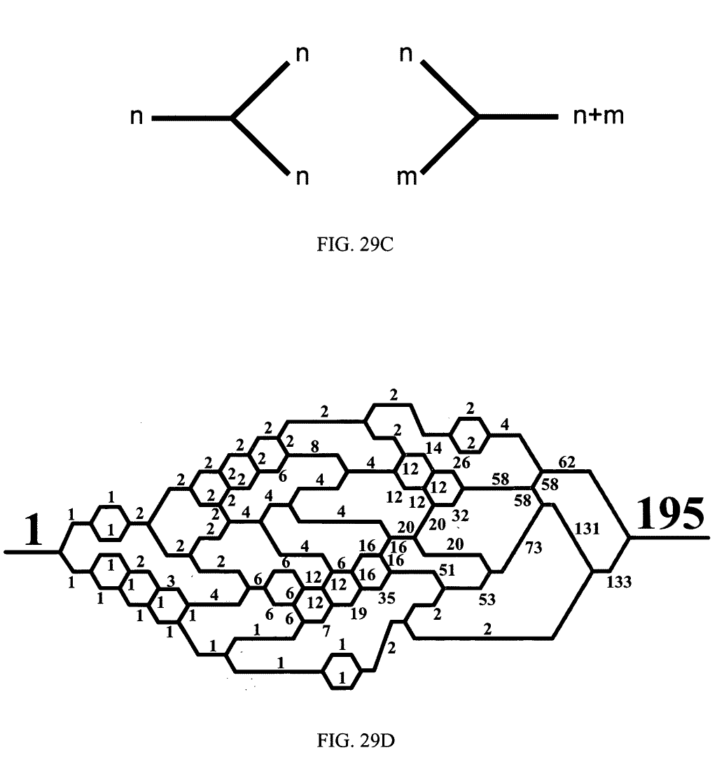

FIG. 29 defines notation for labeling islands by counting paths around them.

FIG. 29A provides a convention for labeling islands. The label is the binomial SM, where S is the number of split nodes and M is the number of merge nodes around the island.

FIG. 29B shows an example of labeling islands of a typical flowgraph.

FIG. 29C shows a very easy way to count the number of paths in a flowgraph. Each split and merge node is labeled with its multiplicity according to the following convention: (1) both output paths of a split have the same multiplicity as the input: n→n,n; (2) the output path of the merge has multiplicity that is the sum of the two input path multiplicities: n,m→n+m. The simple procedure is as follows: First, label the input path with multiplicity 1. Now, starting from the left, successively label each node using the convention just given. The output multiplicity is the number of paths through the flowgraph.

FIG. 29D shows a relatively complicated example of a flowgraph, with 29 splits and 86 links. Using the given procedure, we easily find that this flowgraph has 195 paths.

### Examples of Planar Flowgraphs

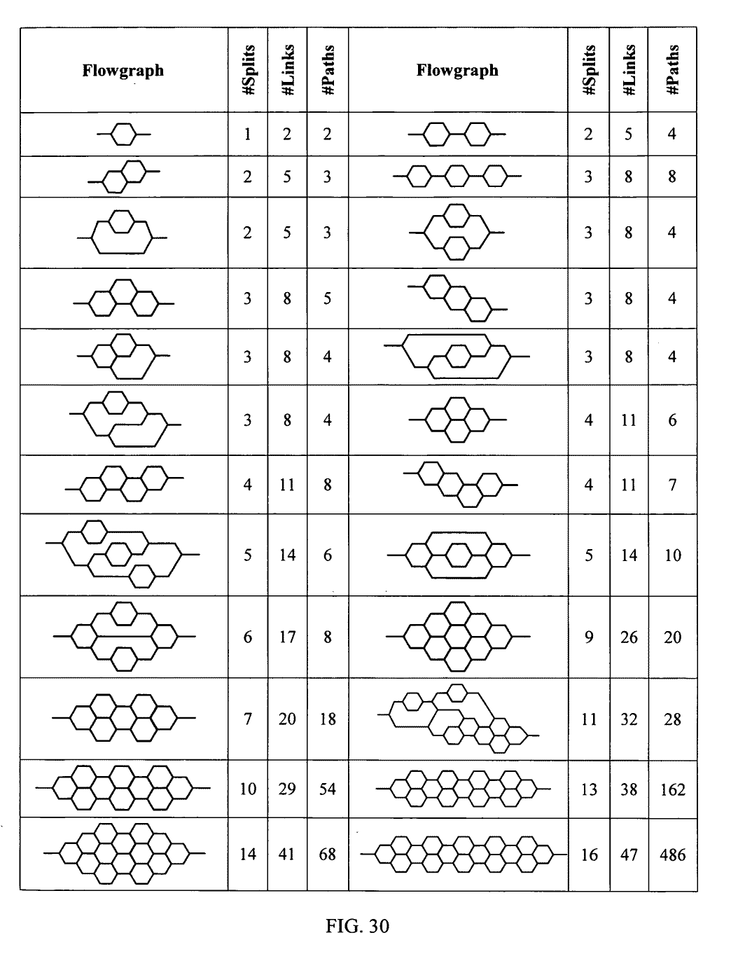

FIG. 30 shows examples of relatively simple planar flowgraphs, and some of their properties that serve to classify them. Most of the examples in the table are symmetric, or nearly so. However, extreme asymmetry does not seem to produce extreme statistics. In fact, the most extreme group is the linear worm-like structures at the bottom of the table, which have more (sometimes many more) paths than splits or links.

Flowgraphs have some simple and useful topological and statistical properties. For instance, the number of splits exactly equals the number of merges (for equal input/output branch multiplicity). More significantly, the number of links is directly related to the number of splits: if N=#splits and L=#links, then L=3N−1. Furthermore, the number islands is exactly the same as the number of splits: #islands=N.

### Numbers of Paths

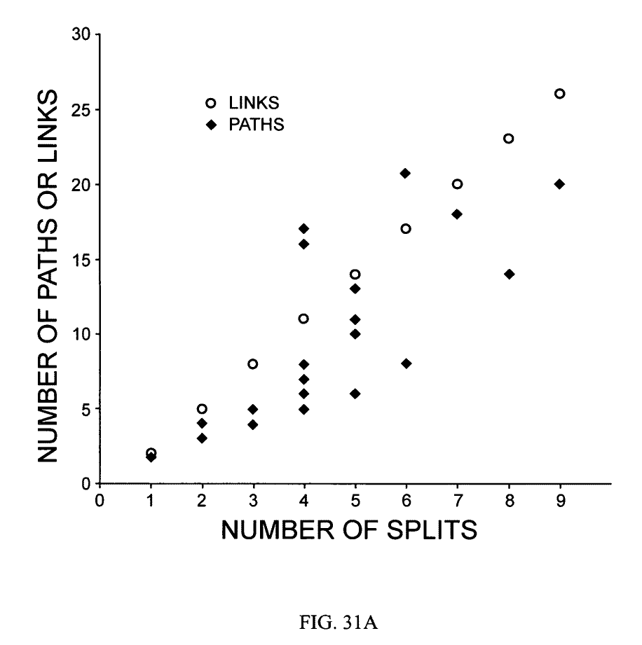

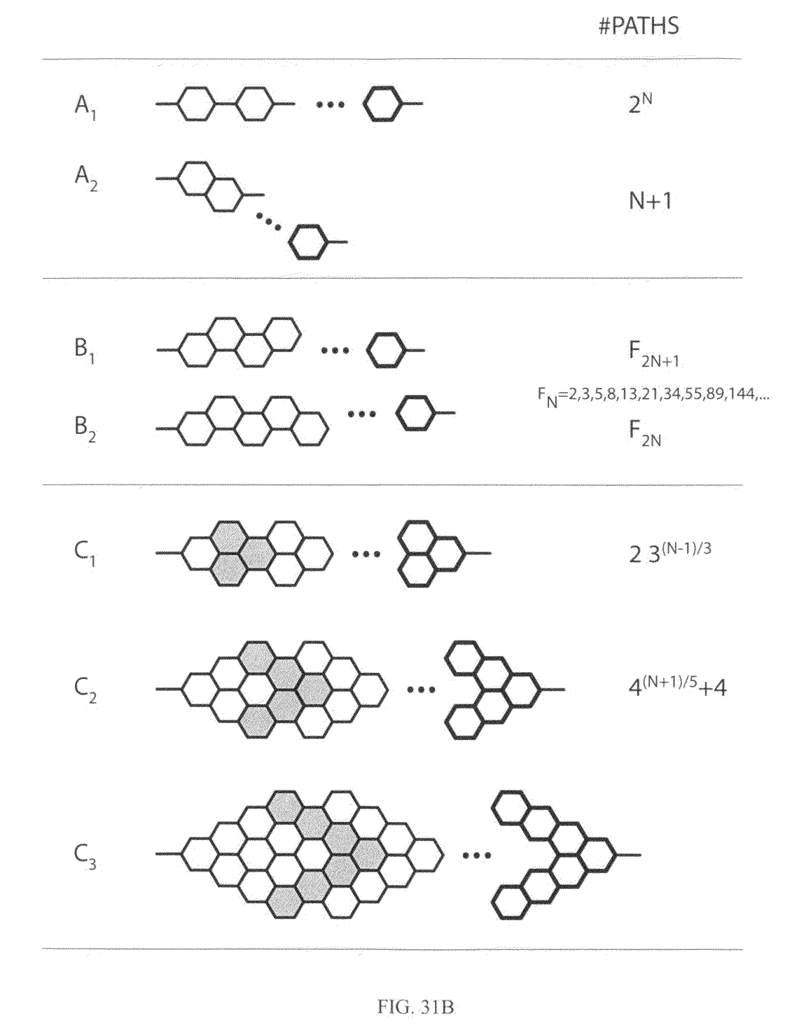

FIG. 31 shows the number of paths of selected flowgraphs.

FIG. 31A shows the number of paths and links as a function of the number of splits, for a selection of fairly small flowgraphs. While the number of links increase linearly with the number of splits (L=3N−1), the number of paths is (almost) always less than the number of links. When this is the case, it will usually be advantageous to transform the flowgraph to the form with fully parallel links.

For certain flowgraphs, the number of paths grows much faster than linear, hence will far exceed the number of splits. Furthermore, some of the flowgraphs fall into natural sequences, for which we can easily determine the number of paths for any member of the sequence.

FIG. 31B gives examples of relatively symmetric chainlike flowgraphs, together with the number of paths through them. For some of these, closed-form expressions for the number of paths are available. We indicate the sub-assembly of islands added to extend these chains by heavy lines and shading. We will discuss these flowgraphs in three groups, separated by the horizontal lines. We reiterate that for all of these flowgraphs, the #splits=#islands=N, and the # links=3N−1.

The first flowgraph A₁ is a simple linear chain of isolated islands, for which the number of paths increases as 2^{N} for N islands (#splits=#islands=N, and #links=3N−1). This is visually obvious, since each island provides 2 paths for its input, and one output.

The second flowgraph A₂ is a series of steps. Perhaps surprisingly, the number of paths is only N+1. We might think that this results from joining the islands along an edge rather than at a vertex. However, as we will now see, this is not the case.

The next two flowgraphs B₁, B₂ result from adding a single island on the end of the chain, joining at the edge and forming a zig-zag chain. Thus, there will be chains with odd numbers of islands and chains with even numbers of islands. Direct examination shows that the number of paths corresponding to 1, 2, 3, 4, 5, 6, 7 . . . islands is 2, 3, 5, 8, 13, 21, 34 . . . which we recognize as the Fibonacci numbers. It should not be surprising to find such a sequence, because graphs are almost universally described by integer sequences describing paths such as these. For convenience, we summarize here a few of the features of these numbers.

The Fibonacci numbers are defined by the recurrence relation F_{N+1}=F_{N}+F_{N-2}.

The Fibonacci numbers beyond the 3^{rd} are 2, 3, 5, 8, 13, 21, 34, 55, 89, 144, 233, 377, 610, 987, 597, 2584, 4181, 6765, 10946, 17711, 28657, 46368, 75025 . . . which will be the number of paths through the respective chain flowgraphs.

There are a large number of formulas involving the Fibonacci numbers, such as the generating function: x/(1−x−x²)=Σ(N=0,∞) F_{N}x^{N}. Some (but not all) the Fibonacci numbers are prime. They are related to the Lucas numbers L_{N}=F_{N-1}+F_{N-1}=2, 1, 3, 4, 7, 11, 18, 29, 47, 76 . . . , and to the trigonometric and hyperbolic functions.

It is very satisfying to find the Fibonacci numbers in our flowgraphs and therefore in our circuit manifolds. It is well-known that the Fibonacci numbers are encountered in a wide range of mathematical, economic, and natural phenomena—there is a large literature on them, and there are many applications of them.

The Fibonacci numbers are closely related to the Golden Ratio (\sqrt{5}+1)/2=1.6180339 . . . , which is widespread throughout the arts and sciences, music, painting, architecture, mathematics, and Nature. The Golden Ratio and Fibonacci numbers are encountered in biological populations, spiral shells, flowers, telephone trees, reflection in glass panes, family trees, phyllotaxis, partitioning and triangles, trading algorithms, pseudorandom number generation, optimization, audio compression, and many similar subjects.

The last three flowgraphs C₁, C₂, C₃ are wider chains, formed by starting with a diamond-shaped core and adding arrow-shaped ends to extend the chain.

The first flowgraph in this set C₁ has 2 3^{(N-1)/3} paths for N islands (note N=4, 7, 10, 13, 16, 19, 22 . . . ). This sequence is 2(3, 9, 27, 81, 243, 729, 2187 . . . )=6, 18, 54, 162, 1458, 4374, 13122 . . . . Its recurrence relation is R_{N+1}=3R_{N}. It is found in tiling, chemistry, and function partitioning.

The second flowgraph in this set C₂ has 4^{(N+1)/5}+4 paths for N islands (note N=9, 14, 19, 24, 29, 34, 39 . . . ). This sequence is 4(5, 17, 65, 257, 1025, 4097, 16385 . . . )=20, 68, 260, 1028, 4100, 16388, 65540 . . . . Its recurrence relation is S_{N+1}=4S_{N-1}−3. It is found in combinatorics, finance, and other applications.

The third flowgraph in this set C₃ has 10(7, 25, 90, 325, 1175, 4250 . . . )=70, 250, 900, 3250, 11750, 42500, 148500 . . . paths for N islands (note N=16, 23, 30, 37, 44, 51, 58 . . . ). The recurrence relation for 7, 25, 90, 325 . . . is T_{N+1}=5(T_{N}−T_{N-1}). We have not been able to find a simple closed formula for T_{N}. However, the sequence 2, 7, 25, 90, 325 . . . is the binomial transform of F_{2N+3}, indicating its close relation to the Fibonacci numbers.

The close relationship between flowgraphs and well-known integer sequences strongly implies that the circuit manifolds based on flowgraphs, as described in this invention, will have many diverse practical applications.

For large numbers of paths, flowgraphs provide the most efficient “packing” of modules; the number of links always increases only linearly (L=3N−1). Thus, for a flowgraph of the kind C₂, with N=39 islands, there are 3(39)−1=116 links requiring 116 modules, but implementing 65540 paths. Each path implements a different function, which can simulate 65540 different dynamical systems having 39-cycle periodic functions. This illustrates the significant advantage of using modules coupled into flowgraphs—the connections provide the versatility for complex computations.

### Multivariable Circuit Manifolds

It is easy to generate flowgraphs for which the Poincare section is disjoint. We are free to assemble a Poincare section from fragments, so long as the union of all fragments intercepts all possible orbits.

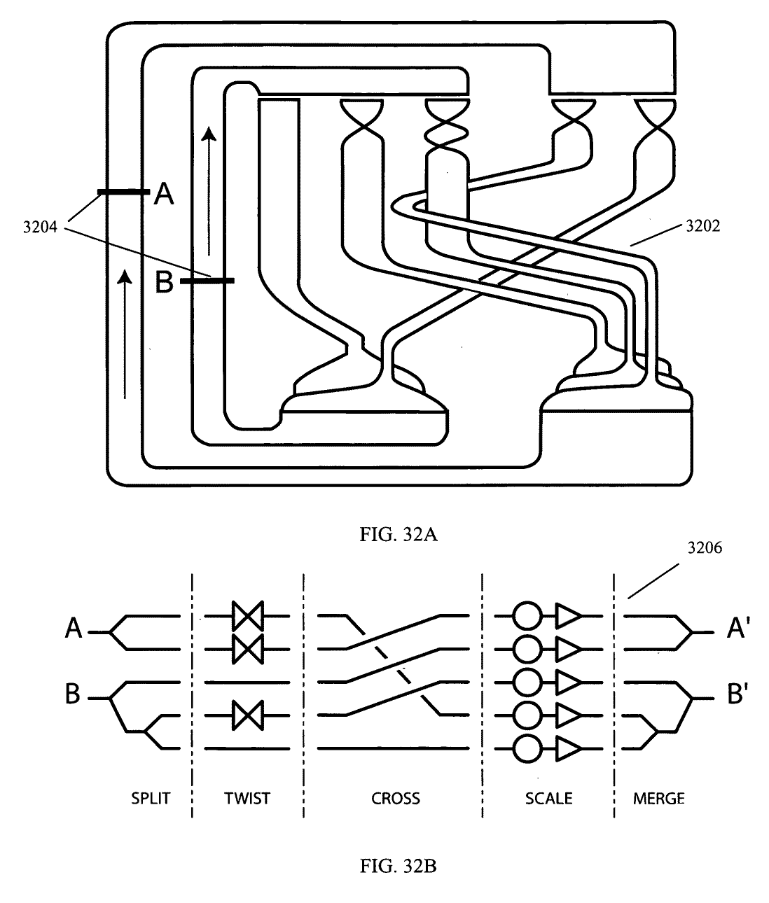

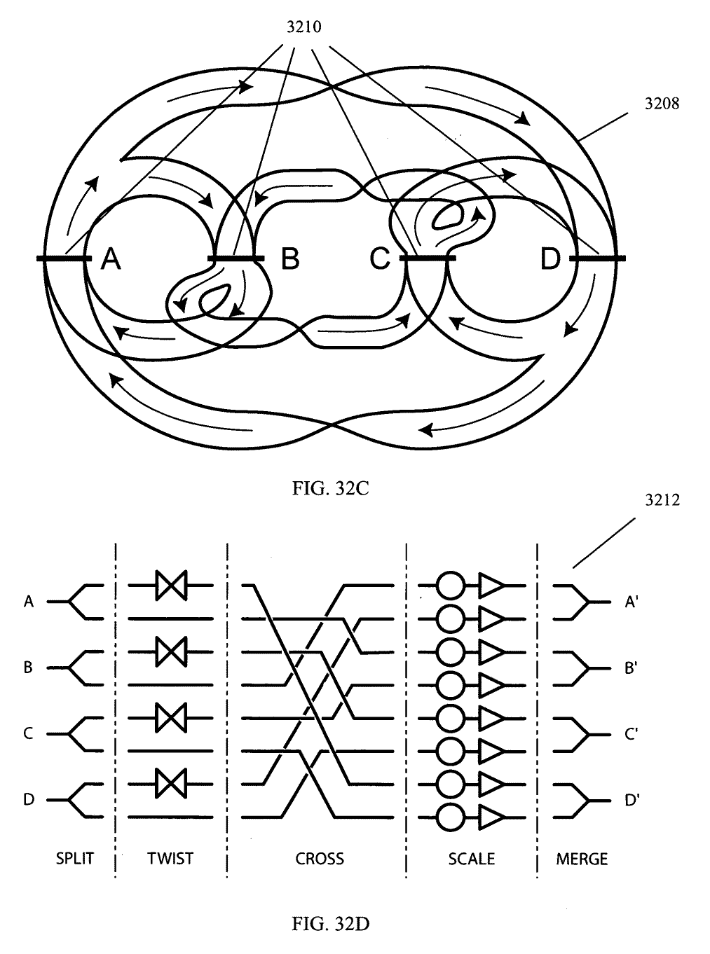

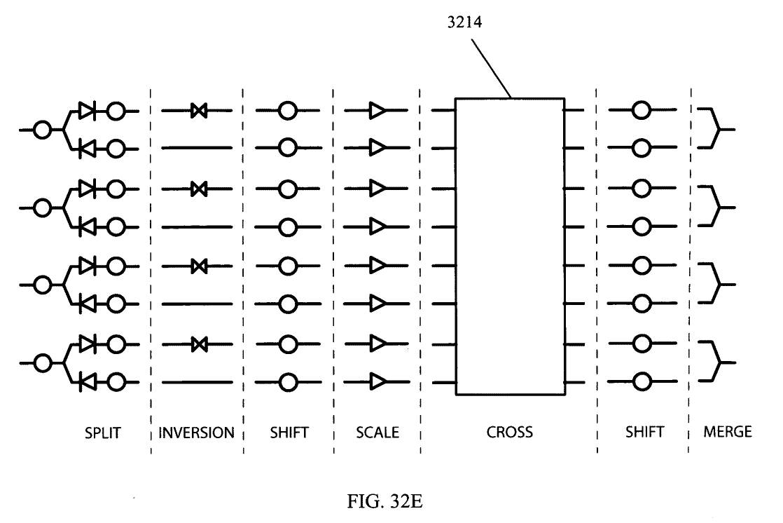

FIG. 32 shows three examples of branched manifolds with disjoint Poincare sections, together with the circuit manifolds obtained when the branched manifolds are cut and unrolled.

FIG. 32A shows a branched manifold 3202 shown by Gilmore which requires two cuts 3204 to intercept all orbits.

FIG. 32B shows how this branched manifold unrolls into a circuit manifold 3206 with two inputs and two outputs.

FIG. 32C shows the (by now familiar) example of the branched manifold 3208 for the current-carrying wire loop shown in FIG. 7, including four cuts 3210 that intercept all orbits.

FIG. 32D shows how the four cuts in this manifold enable us to unroll it and associate it with a circuit manifold 3212 with 4 inputs A, B, C, D and 4 outputs A′, B′, C′, D′. These examples have been deliberately arranged to group the circuit devices into the sequence SPLIT, TWIST, CROSS, SCALE, MERGE. It is likely that all such manifolds can be so arranged. In fact, it appears possible to sort all the functional modules according to type.

FIG. 32C shows a hypothetical 4-input/output circuit manifold sorted as SPLIT, INVERSION, SHIFT, SCALE, CROSS, SHIFT, MERGE. The CROSS region 3214 is where nonlinear computation occurs—all the rest is separation and conditioning. This region enables widely different values to interact and exchange, which provides magnitude mixing.

### Nonplanar Flowgraphs

So far we have tacitly assumed that the flowgraphs are planar. However, global torsion will introduce twists in the branches, as elaborated in detail by Gilmore, Tufillaro, and others. This problem is a bit subtle when we are using flowgraphs, since the flowgraphs have no indication of twist.

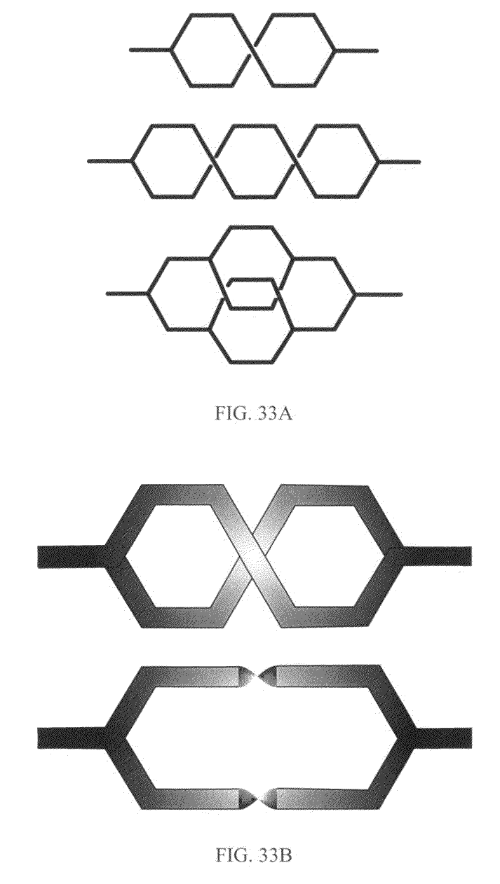

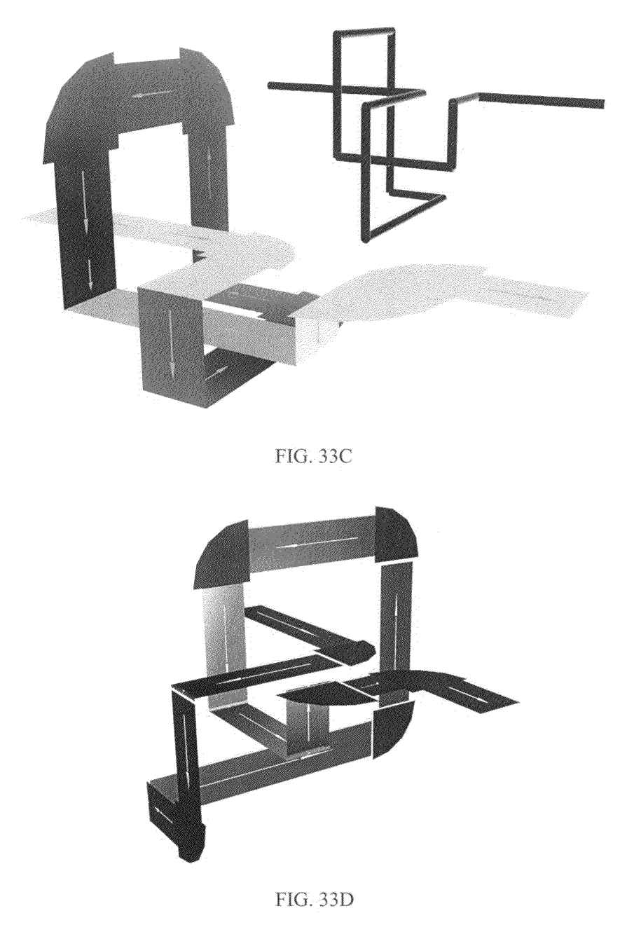

FIG. 33 shows examples of nonplanar flowgraphs.

FIG. 33A shows three simple flowgraphs with global torsion and/or internal linking. These diagrams do not show any twists, but that is only because we deliberately designed the flowgraphs to be free of such details.

Twist generates a problem in flowgraphs because the flowgraph branches are not lines, as we typically represent them, but ribbons. Thus, if we were to simply untwist the first diagram, the branches would themselves become twisted, hence we would have to introduce inversions into the maps.

FIG. 33B shows how global torsion is introduced by untwisting an otherwise planar appearing flowgraph. In this case, the flowgraph is indeed planar, but we must introduce twist pieces and their corresponding circuit manifolds.

FIG. 33C shows a branched manifold in the form of a simple (overhand) knot. This produces a circumstance in which the 3D nature of the branched manifold cannot be ignored. As discussed above, we must implement the circuit analogue for this branched manifold with a 3-wire circuit manifold; a 1-wire circuit manifold will not work. This happens because the finite width of the ribbon prevents the knot from being shrunk to zero.

FIG. 33D shows another form of the overhand knot branched manifold. While this one is very similar to the previous one, it differs in some details, and these details will appear in slightly different circuit manifolds. However, since the input and output ribbons of the two knots are the same, we know that the signals propagated through both knots must undergo the same total transform, hence it is immaterial which branched manifold we use. We will, in fact, obtain the same electrical circuit for both cases.

### Topological Properties of Flowgraphs

By design, the flowgraph does so much violence to the details of the model branched manifold that details about twists are irretrievably lost. Flowgraphs are similar to Feynman diagrams used in quantum electrodynamics, namely they are a means for topologically classifying classes of processes and organizing computations. Feynman diagrams use directed links; the links in flowgraphs are also directed, but by the convention that the flow is always left-to-right, we do not need to display these directions. A particular computation with such diagrams may require including several topologically identical, but geometrically distinct, diagrams.

Flowgraphs are graphs, and therefore the considerable body of knowledge about graphs, collectively designated graph theory, will be applicable to flowgraphs. For instance, splits and merges in a flowgraph are called vertices in graph theory, and links in flowgraphs are called edges in graphs. The adjacency matrix (#vertices×#vertices), whose elements are 1 if the vertices are connected and 0 if not, provides a Boolean matrix specification of the flowgraph. For instance, the adjacency matrix for the flowgraph shown in FIG. 26B is:

$$[ \begin{matrix}0 & 1 & 1 & 0 & 0 & 0 & 0 & 0 \\ 1 & 0 & 0 & 1 & 0 & 0 & 0 & 0 \\ 1 & 0 & 0 & 0 & 1 & 1 & 0 & 0 \\ 0 & 1 & 0 & 0 & 0 & 1 & 0 & 0 \\ 0 & 0 & 1 & 0 & 0 & 0 & 1 & 0 \\ 0 & 0 & 0 & 1 & 0 & 0 & 0 & 1 \\ 0 & 0 & 0 & 0 & 1 & 0 & 0 & 0 \\ 0 & 0 & 0 & 0 & 0 & 1 & 0 & 0\end{matrix} ]$$

### Chain Circuit Manifolds

Unrolling the Branched Manifold Several times we have referred to unrolling (also called suspension) the model branched manifold to obtain a linear chain or a ring with a series of modules connected in series. A quasi-periodic system is visualized as having trajectories in its phase space that return to the vicinity of a previous visit; periodic systems return exactly to a previous point. In this picture the attractor is like a coil of rope.

Now, if we visualize holding the ends but dropping the coils, we unroll the attractor into a linear chain with modules between node points. Each module in the chain represents a quasi-period of the dynamical system; each module maps the node voltage into the next node voltage. In this picture, the attractor is like a string of beads, or a chain.

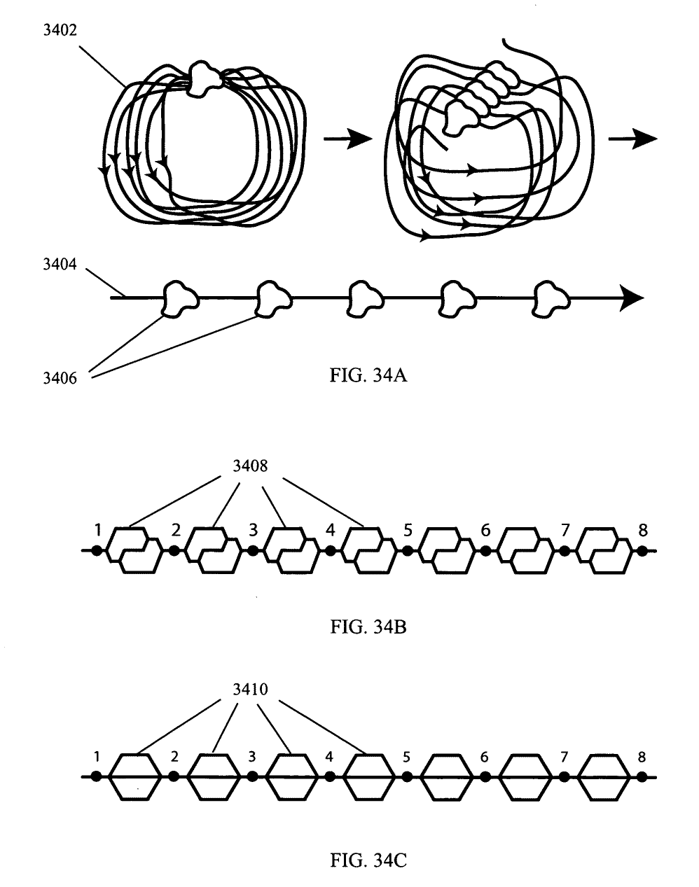

FIG. 34 shows unrolling of quasi-periodic attractors to form linear chains.

FIG. 34A shows the process of unrolling a quasi-periodic attractor 3402 into a chain 3404. According to the principle of assembling the circuit manifold with the same topology as the model branched manifold, the circuit analogues will be linear chains of modules 3406 connected together at their ends.

Chain manifolds will be valuable for two purposes:

(1) A linear chain provides a means of computing nested or iterated functions;

(2) A chain closed into a ring provides a means of forcing periodicity.

Two aspects of chain manifolds are quite significant for computing:

(1) Setting the voltage of any node automatically and uniquely sets the voltages of all other nodes. This happens because all modules are directly connected through their nodes; there is no iteration or switching in the completely analog circuit. This will enable extremely fast computation of all values at the Poincare section, corresponding to multiple cycles around the branched manifold.

(2) Normally we expect to make all modules in a chain identical, although they can have arbitrary complexity. This will enable us to mass-produce large numbers of modules, each implementing a nonlinear and/or discontinuous function corresponding to a very complex flowgraph. All the node voltages are “saved” in a computation, in contrast to digital computations in which intermediate values are discarded. We can use a matrix array to sort the (possibly) large number of node voltages into a smaller set of human-meaningful values. Thus, a chain circuit manifold contains its own (analog) memory, and operates with 100% parallelism.

### Linear Chain Manifolds

Chain manifolds can be constructed by connecting (nominally identical) flowgraphs in series. Between each pair of flowgraphs is a node; we assume we have access to some, or all, of the voltages on these nodes.

FIG. 34B shows a segment of a linear chain circuit manifold, in which the modules are identical 5-link, 3-path flowgraphs 3408.

Because most small flowgraphs have fewer paths than links, replacing the modules by their path-equivalent fully-parallel versions is useful, as we now discuss.

FIG. 34C shows the linear chain circuit manifold of FIG. 34B after replacing the flowgraphs by their 3-link, 3-path fully parallel equivalents 3410.

The path taken by the signal through a flowgraph depends on the incoming value of the signal, but it is a unique path, determined by the parameters defining the split pieces. If there are N splits in a flowgraph, and there are M flowgraph modules in series, there are NM unique paths available to the signal. The signal takes one, and only one, of these paths; which path depends on the value of the input voltage.

Given a path, all other paths are irrelevant: non-path parts of the chain are not used (for a particular input). Of course, if the input value is changed (perhaps by even a tiny amount), the path can be radically changed, so we cannot simply discard any parts of the chain.

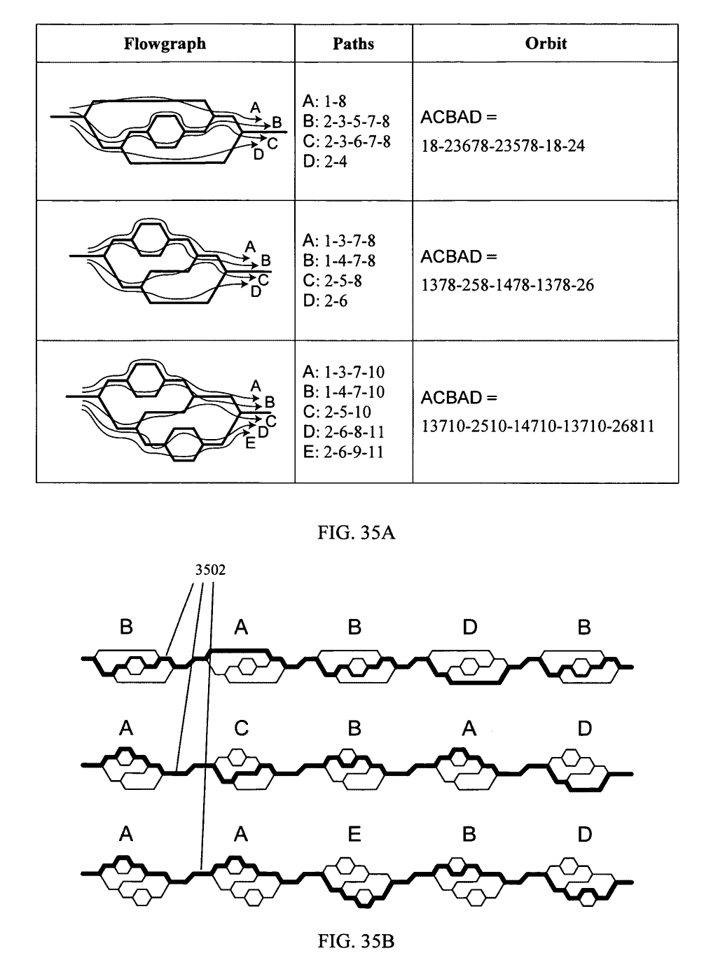

FIG. 35 shows three examples of flowgraphs used in linear chain circuit manifolds.

FIG. 35A defines the three flowgraphs used in the chain circuit manifolds. These flowgraphs are different in their details, yet have many features in common: all have 3 splits, 8 links, and either 4 or 5 paths. The paths define the sequence of circuit modules encountered by the signal as it traverses the flowgraph. An orbit is defined as a sequence of paths. Orbits can therefore be specified by the sequence of letters designating the successive paths. For example, one orbit (ACBAD, selected arbitrarily) is shown in the right-most column, for each flowgraph.

FIG. 35B shows the graphical representation of the ACBAD orbits for a 5-flowgraph chain. In spite of the similarity of the flowgraphs and the global topology of the circuit manifold, these orbits 3502 are completely different, as expected.

It should be obvious that these considerations present us with the flexibility to mix and match flowgraphs. To the extent that the circuit functional blocks in these flowgraphs can be set at run-time, as discussed above, these chain manifolds can provide considerable configurability. This will be valuable for developing applications that are useful for a range of problems, broad enough to be useful to a range of users, but narrow enough to be application-class specific.

### Linear Chain Manifolds

FIG. 36 shows data of relevance to linear chain circuit manifolds and issues of analog precision.

FIG. 36A shows how a linear chain of functional modules 3602 computes nested functions (which is synonymous with iterated functions, i.e., computing the function of the function, repeatedly).

The general effect of nesting functions is to enhance fine structural details. Any ripples, peaks, and other sharp features will be propagated into otherwise smooth parts of the initial function. Even starting with a very smooth initial function and using low-order functions, repeated mappings can rapidly generate an effectively chaotic function.

FIG. 36B shows the process of generating chaotic data from smooth data in repeated mappings. The first of the 8 frames shows the initial smooth function 3604. Successive frames show the function of the previous frame. With only a very small number of iterations, the function becomes hopelessly chaotic 3606. This explosion of detail is exactly what would occur if we combined two numbers, but did not discard digits after combination. Combining two 64-bit numbers would result in a 128-bit number, and combing these would result in 256-bit numbers. Digital computers maintain a limit on this by discarding bit beyond a fixed limit (say, 64-bits), for every data object, and this is done in hardware.

In fact, it is also easy to set a machine precision in analog circuits: we simply add low-pass filters in the circuit manifold, which maintains data complexity at a fixed level.

FIG. 36C shows such precision-limited analog data in a set of successive maps. These data were computed as previously-finding the function of the previous function, but now, in addition, we sort the functions into a fixed number of bins (“resolution” or “complexity”). All of these curves 3608 have about the same “roughness.” Such data will be characteristic of the computations done with circuit manifolds built according to this invention.

### Ring Manifolds

Given that we have unrolled a model branched manifold into a linear chain, it is a trivial, but highly significant, step to connect its ends to form a ring. The result of this step is that the chain is truncated and forced to be periodic, with period equal to the number of modules.

As for linear chains, setting the voltage of any node in a ring manifold immediately (within the analog settling time) sets the voltages of all other nodes. Furthermore, all node voltages remain (are “stored”) until modified, and are available in parallel to outside sampling. Essentially, the ring manifold computes the histogram representing the Poincare density, and stores it.

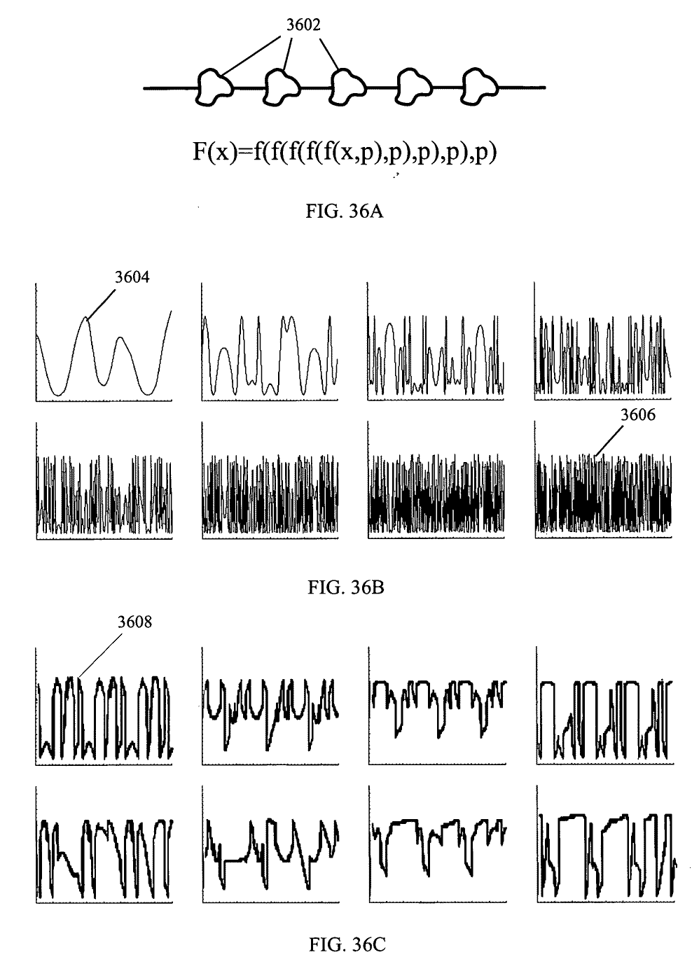

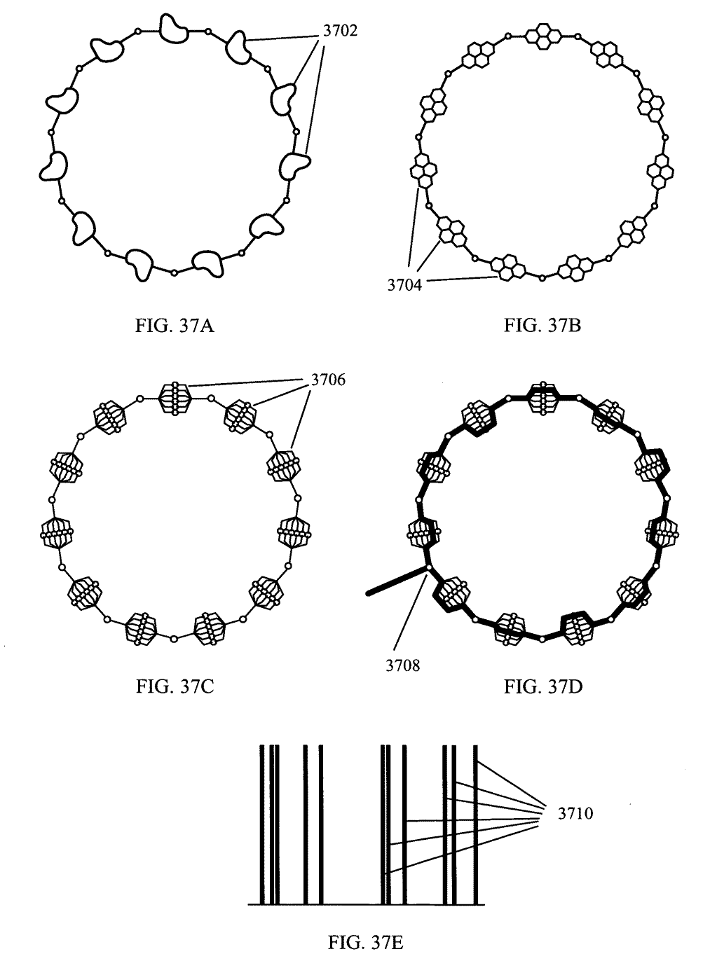

FIG. 37 shows examples of ring manifolds. The same issues of analog precision discussed above for linear chains are relevant for ring manifolds.

FIG. 37A shows a generic 11-node ring manifold. The functional modules 3702 in this diagram are unspecified, but generally are assumed that they are all identical.

FIG. 37B shows an 11-node ring manifold in which the modules are identical 4-split, 1′-link, 6-path flowgraphs 3704.

FIG. 37C shows the same flowgraph in which the modules are replaced with their fully-parallel equivalents 3706 with 6 parallel paths (cf., FIG. 27B).

FIG. 37D shows the use of the ring manifold to perform a computation. The voltage at one node 3708, which can be chosen arbitrarily since the ring has 11-fold rotational symmetry, is set to a desired value. Immediately, all other nodes are reset to voltages determined by the functional modules. The path of the signal, i.e., the branches that process the voltage and pass it to the next module, are shown as a heavy curve. This diagram emphasizes that only one path in the ring is active-all others are effectively uncoupled. Which path is active can be very sensitive to the voltage on the node 3708, and the more modules there are in the ring, the more sensitive it will be.

FIG. 37E shows a typical result of a calculation using this circuit. The nodes acquire 11 (different) voltages 3710 (plotted on the abscissa), determined by the circuit modules. These voltages can be extraordinarily sensitive to the value of the single set voltage. Imagine carefully adjusting a “knob” controlling the input voltage. Even very tiny changes will cause the values shown in FIG. 37E to jump around, although there must always be exactly 11 different voltages. Such a knob adjusting the value of any single node will be an efficient and convenient means to explore the transition from simple periodic motion to complex quasi-periodic motion to full chaotic motion.

### Analog Iteration

In digital system, iteration is used to perform repeated transformations on data using the same hardware. In this invention, we have emphasized the value of replacing a digital iteration with analog circuit manifolds, in which the sequential iterative steps are replaced by dedicated circuit modules suitably connected together in chains or rings. The computation performed by such analog analogues can be called analog iteration.

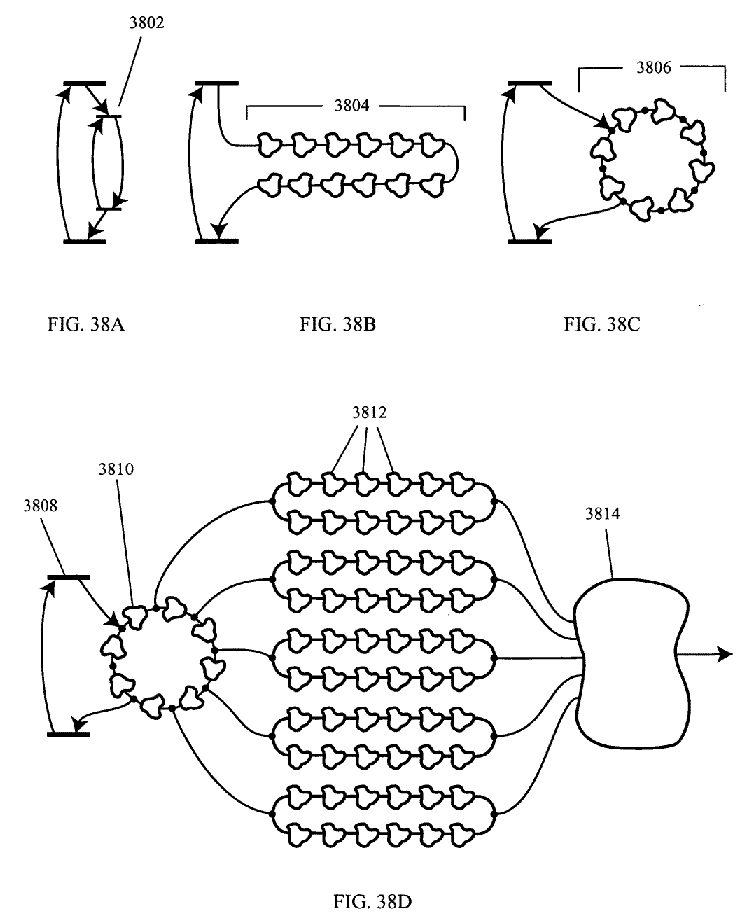

FIG. 38 shows circuit manifolds that implement analog iteration.

FIG. 38A shows a nested pair of iteration loops 3802, normally done with a digital network. Usually the most time is spent on the innermost iterative loop, so we seek to replace it with an analog chain.

FIG. 38B shows a linear analog chain 3804 performing 12 iterations and delivering the result to the digital circuit. The digital part of the circuit sets the voltage of the first node in the chain, and the analog chain immediately sets all other node voltages, including the last voltage, which is sensed by the digital circuit. We are justified in calling this analog iteration, because the result delivered to the enclosing digital circuit is the last value in the chain, which is the value of the nested function.

FIG. 38C shows the linear analog circuit manifold closed into a ring 3806. The input voltage from the digital circuit is applied to one node, and the voltage on another node is read out into the digital circuit. This arrangement forces the iteration to be periodic; the output is determined by the position of the output node relative to the input node.

FIG. 38D shows a more complicated example of nested analog iterations. In this example, a digital iterator 3808 is coupled to a 6-node ring analog circuit manifold 3810, and four steps in the analog iteration are coupled to four additional 12-node ring analog circuit manifolds 3812. Eight of the steps in the second-level iterators are sampled and passed to a decoder 3814, providing data that can be processed for presentation. For each value set at the input by the digital iterator, the 2-stage analog iterator generates data with completely parallel analog circuits.

We note that the number of steps in analog iteration is set by the number of modules, but we can change it dynamically (cf., changing topology, below).

### Computational Example

### A Small Ring Manifold

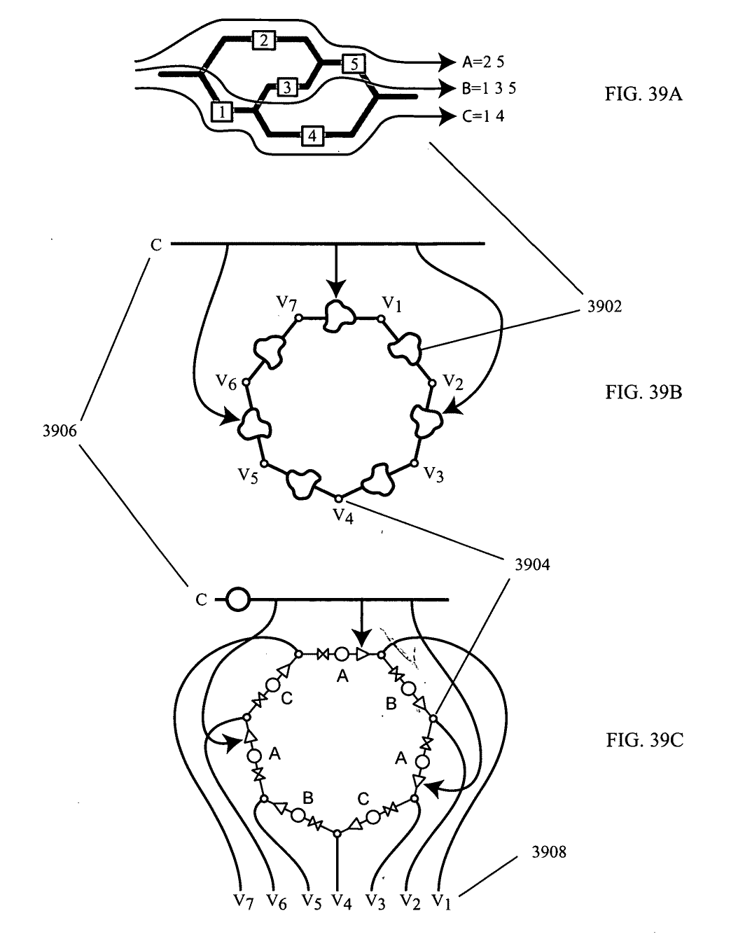

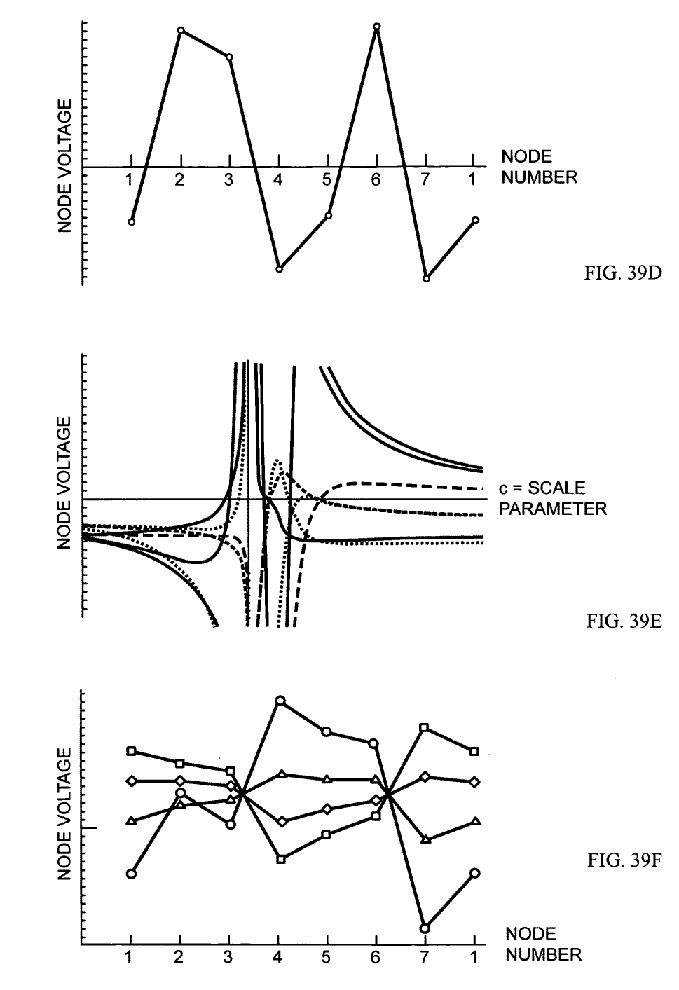

FIG. 39 presents a case study for a relatively simple computation done with a small ring circuit manifold.

FIG. 39A shows a simple flowgraph with 2 splits, 5 links, and 3 paths.

FIG. 39B shows a ring manifold consisting of 7 modules 3902, each module as shown in FIG. 27A. We number the nodes clockwise V₁,V₂,V₃,V₄,V₅,V₆,V₇. The modules are connected between the nodes 3904. A control signal c 3906 from an external source is applied to three modules (selected arbitrarily for this example).

Since there are only 3 paths A, B, C through the flowgraph, we can replace each flowgraph with an equivalent single-path module. There will be 3 kinds of these modules, corresponding to the 3 paths.

The modules for paths A, B, C each consist of 3 functional units connected in series: an inverter (x→±x), a shifter (x→x+p), and a scaler (x→cx). With this simplification, the circuit manifold becomes a purely series-connected ring of 7×3=21 simple functional modules. We select values (arbitrarily) for the parameters as shown in the following table:

| Module | Inverter | Shifter p | Scaler c | Path |
|---|---|---|---|---|
| 1 | −1 | ⅕ | c | A |
| 2 | −1 | 1 | −7 | B |
| 3 | −1 | ⅕ | c | A |
| 4 | −1 | 2 | 5 | C |
| 5 | −1 | 1 | −7 | B |
| 6 | −1 | ⅕ | c | A |
| 7 | −1 | 2 | 5 | C |

While we can easily reconfigure the modules at run time to implement any desired sequence of paths, to simplify this demonstration we (arbitrarily) select one orbit: ABACBAC.

FIG. 39C shows the equivalent ring manifold for the selected orbit ABACBAC. The parameter c is applied to the scaler in the three A modules. The 7 voltages V₁,V₂,V₃,V₄,V₅,V₆,V₇ 3908 constitute both the input and output: we can set any of them and measure the others.

A computation with this circuit is done by setting the voltage on one node and reading the voltages at the other nodes. We can then observe the node voltages are observed as a function of the control parameter c. The relation between the set and measured voltages constitutes simulation.

Commercial software (Analog Insydes™) was used to simulate this circuit by representing the 21 functional devices (we omit the detailed values here).

FIG. 39D shows the 7 node voltages when one of the node voltages is set (the first and last points both refer to the same node). For this plot, the voltage on node 2 was set; all the other nodes immediately responded by adjusting themselves to be consistent with the models in the functional modules.

FIG. 39E shows the node voltages as a function of the control parameter c. This plot shows that the node voltages vary smoothly with the control parameter c. Except for one particular value, the voltages remain finite and low. However, at one particular value of c the voltages become very large, probably infinite. This phenomenon was encountered regularly in these simulations. At most values of c, the positive amplification in some modules is cancelled by negative amplification in the others. At one particular value of c (for this circuit manifold), however, the values do not cancel, and unlimited positive (or negative) amplification occurs.

FIG. 39F shows the node voltages for four particular values of c, spaced by δc=0.03. As c moves across the anomaly, the central nodes form a peak that “flops” from negative to positive.

In this example, we used arbitrary values for the circuit parameters. By calibrating the circuit parameters against a physical system of interest, we could adjust these circuits to be faithful simulators of an actual physical system.

### Computational Example

### A Small Tree Circuit Manifold

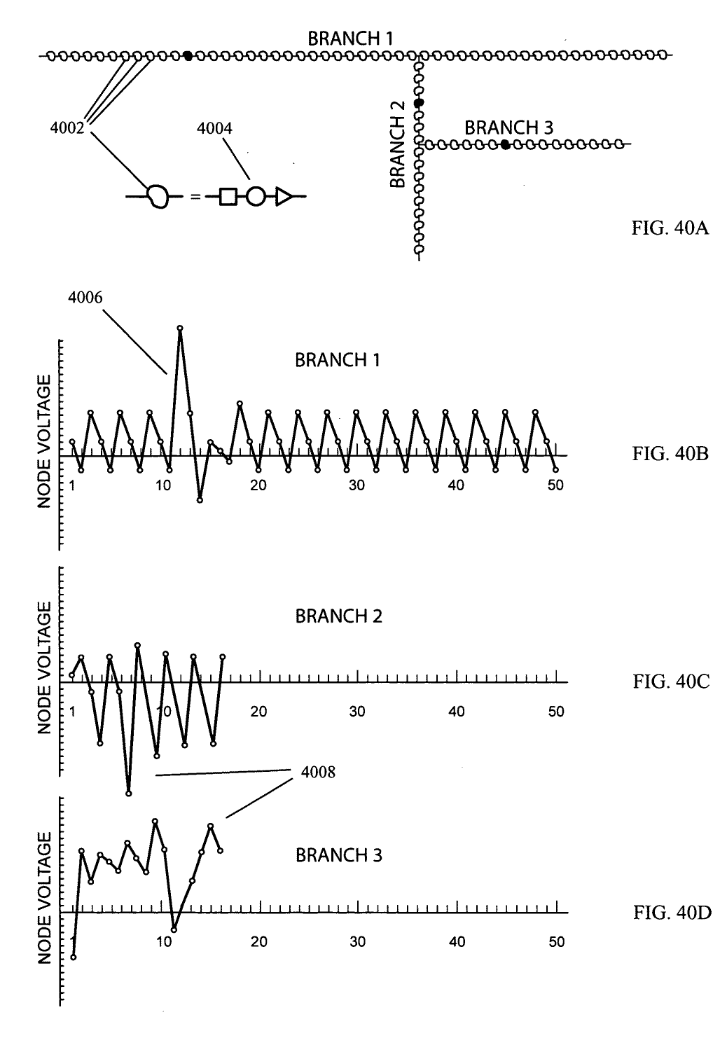

FIG. 40 presents a case study for a relatively simple computation done with a circuit manifold in the form of a multiply-branched tree.

FIG. 40A shows the tree manifold 4002 assembled as linear chains of similar modules 4004. BRANCH 1 contains 51 functional units of 17 triplets. BRANCH 2 has 16 units of 5 triplets and is connected to BRANCH 1 at node 30. BRANCH 3 also has 16 units of 5 triplets and is connected to BRANCH 2 at node 7. All triplets are the same kind as in the previous example, namely an inverter (x→±x), a shifter (x→x+a), and a scaler (x→cx). These triplets are identical, except that BRANCH 1, position 12 has 2.5a instead of a, BRANCH 2, position 4 has 2a instead of a, and BRANCH 3, position 7 has 2a instead of a. These modules are marked with solid symbols. All these values were arbitrarily selected to be purely illustrative.

As described previously, computation with circuit manifolds such as these involves setting some voltages and observing others. We now show examples of these for the tree branches.

FIG. 40B shows a typical state of BRANCH 1. The node voltages are essentially periodic. However, the anomalous a values produce a “shock” 4006 in the otherwise periodic node voltages. The shock perturbs nearby nodes, but the perturbation has a limited range.

FIG. 40C shows the voltages on BRANCH 2, which exhibit a weak perturbation due to the attachment of BRANCH 3.

FIG. 40D shows the voltages on BRANCH 3, which also shows a perturbation 4008 that is more violent.

### Computational Example

### Routes to Chaos

Linear circuit manifolds such as those we have described above can be used to generate analog representations of time-dependent functions. We might expect, and we will find, that they can be used to simulate phenomena such as oscillation, intermittency, and chaos.

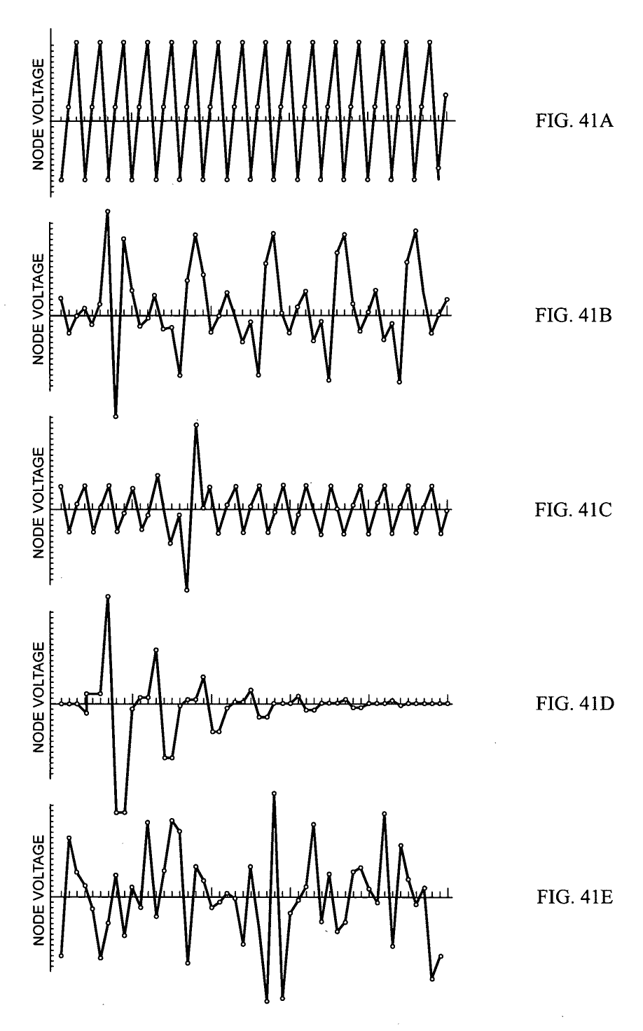

FIG. 41 shows examples of computations made with linear circuit manifolds. These plots show the node voltages of a linear chain circuit manifold, obtained by adjusting the parameters of the individual modules. We reiterate that these are not plots of the value of a variable in time, but rather the static values of node voltages. All these plots should be considered one period in a repeating sequence; these plots could be repeated back-to-back forever.

FIG. 41A shows periodicity. In the first case, the period is two nodes, while in the second case the period is 7 nodes. The latter case is adjusted to simulate an initial transient.

FIG. 41B shows period tripling. In this calculation, the period-3 oscillations are locally converted to period-9 oscillations.

FIG. 41C shows intermittency. The generally periodic behavior of the chain is interrupted locally with several very large voltage swings. Intermittency is obtained if we assume the pattern repeats.

FIG. 41D shows a transient. This could also be regarded as intermittency if we assume the pattern repeats.

FIG. 41E shows chaotic behavior: wildly oscillating values that do not have much coherent structure.

It is reassuring that the node voltages in these circuit manifolds exhibit various phenomena well-known in nonlinear dynamics. The advantage of using analog iteration is that when any one value is set, all values are generated simultaneously. We reiterate that these are plots of node voltages, which are obtained simultaneously with the analog circuit manifolds. Their resemblance to time-domain transient phenomena is purely structural. However, this is precisely what we set out to do, namely represent temporal dynamics in parallel, using arrays of analog circuits to produce all values simultaneously.

### Changing the Circuit Manifold Topology

So far the tacit assumption has been that the topology of the circuit manifold is fixed throughout a computation. However, there is considerable advantage in being able to alter the topology in response to a result. This is generally referred to as adaptive computing; changing the topology of the circuit manifold is only one way to be adaptive, but it is a very powerful one.

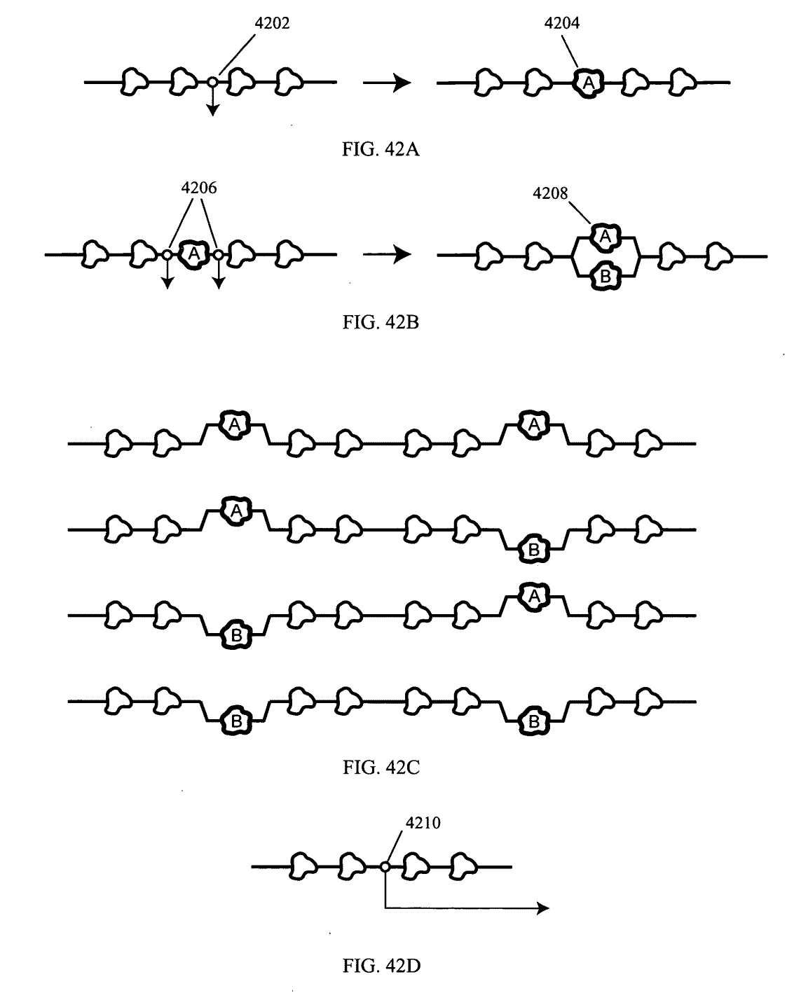

FIG. 42 shows some simple options for adaptively changing the topology.

FIG. 42A shows one method for inserting a module in a circuit manifold. Here we monitor a single node voltage 4202. If this voltage falls outside a defined interval (or set of values), we insert a new module 4204 at that node. The idea is to keep all node voltages confined within defined limits; insertion of additional modules can effect this.

Note, however, that this scheme changes the number of processing steps; in a periodic system it doubles the period. We can think of this mechanism as follows: the nearly periodic system detects when it returns too far from its “home,” and it goes around another time in an attempt to confine the orbit to a desired interval. Airplane pilots do this: when they miss the proper landing insertion vector, they go around again.

FIG. 42B shows another method for inserting a module in a circuit manifold. Here we monitor the voltage difference between two nodes 4206. When the difference exceeds the allowable range, we add a module 4208 in parallel. This has the effect of providing a new path, which enables the system to take one path, then the other on a subsequent pass. Clearly, this is equivalent to period doubling.

FIG. 42C shows the possible paths in the previous circuit manifold. There are four possibilities, corresponding to the signal passing through the two paths: A-A, B-B (period-1), and A-B, B-A (period-2).

In fact, there are many more possibilities than these two, such as AAB, ABB, etc. (period-3), AAAB, AABB, etc. (period-4), etc. If the two branches A, B are equally likely, all possible sequences, like coin flips, are equally likely. Thus, this adaptive mechanism generates perhaps too much richness in its period multiplication.

FIG. 42D shows a simple method of period halving. In this case we monitor a single node 4210. If the voltage on that node exceeds the allowable range, the signal is diverted directly to the output, shunting the second half of the modules.

### Architectures for Computation

We view computation as a series of aggregation/evaluation cycles. This is easy to see for digital computation. For example, we first aggregate integers 1, 3, 4, 7 into the assembly (3+7)/(1+4), then we evaluate that assembly to obtain 2. But what is the corresponding process for analog computation? We answer this question as follows:

(1) Assembling the circuit manifold and setting its voltages constitutes the aggregation part of the computation.

(2) Reading the data, sorting it, decoding it, generating statistical measures, and similar processes constitutes the evaluation part of the computation.

Thus, to do the computation we will need a general architecture that includes both aggregation of circuit manifolds and evaluation of the data represented and produced by them.

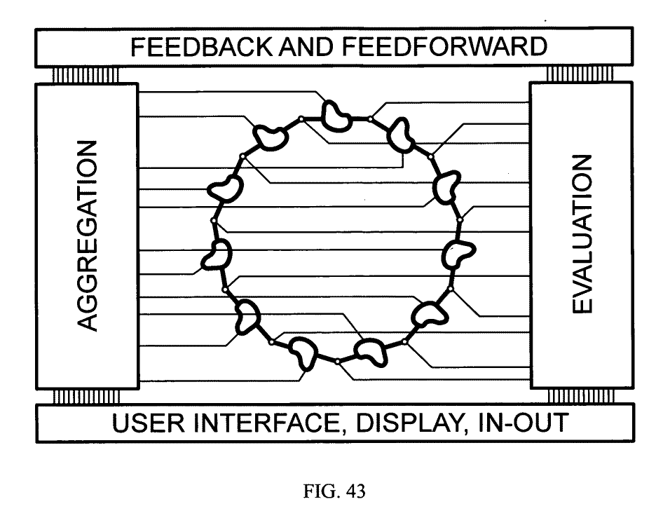

FIG. 43 shows our conceptual architecture for computing with analog circuit manifolds. The AGGREGATION section is used to assemble the circuit manifolds (an 1′-module ring circuit manifold is shown for example). As shown previously, we can do this by configuring the modules and by altering the topology, by plan or adaptively. The EVALUATION section reads, sorts, and generally processes the data from the circuit manifold. The USER INTERFACE sits between these two blocks, implementing both aggregation (setting up new problems, extending the current problem, etc.), and evaluation (interpreting output data, sorting and discarding data, declaring the problem solved, etc). The FEEDBACK AND FEEDFORWARD section provides for adaptive computation by reconfiguring the system. The difference between the FEED and USER sections is that the former is considered automatic and run-time, while the latter is considered manual and operator-time.

### Circuit Manifolds as a Vector Computers

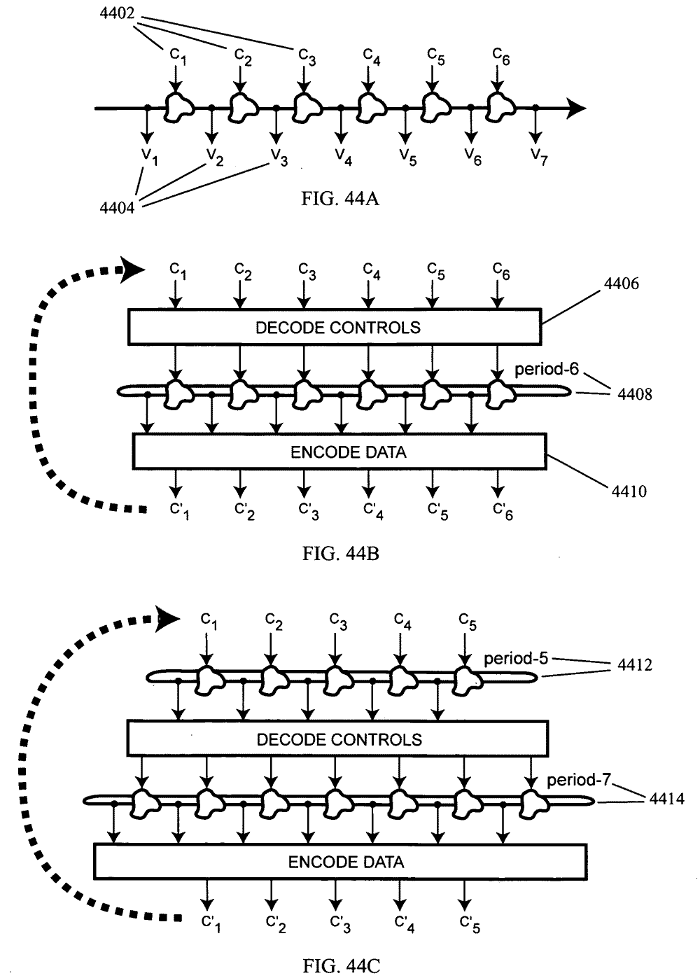

FIG. 44 shows examples of architectures based on the aggregation/evaluation model just described. Linear chain circuit manifolds convert an input set of values V to an output set V′. Conceptually, this can be described as a vector computer, although here we relax the usual condition that the input and output vectors have the same dimension.

FIG. 44A shows a circuit manifold that converts a set of control voltages C 4402 into node (data) voltages V 4404. Thus, the circuit performs a vector transformation C→V, or equivalently, the vector function V=M(C).

### Data/Control Fusion

It is obvious that both the control voltages (“control”) and the node voltages (“data”) are voltages. We see this as an opportunity to actually use control voltages as data and vice-versa. This interchangeability of control and data presents a very high potential value for adaptive computing. In this sense, the control voltages and the node voltages share equal importance and should be considered the same kind of variable in the realm of computation. Data/control fusion has been exploited in many areas, e.g., genetic programming, systolic arrays, etc., and we see many applications of this concept in this invention.

FIG. 44B shows an architecture in which the data and controls are coupled in a feedback arrangement. At the top, a set of parameters C is sent through a matrix decoder 4406 and passed to the functional modules of a period-6 ring circuit manifold 4408. The ring generates a corresponding set of node voltages V, which are passed through a matrix encoder 4410, thereby generating a new set of controls C′. These new controls can be fed back as inputs to the first decoder, thus providing a new set of control parameters for the circuit manifold.

FIG. 44C shows another way to mix data and control. Here, the node voltages of a period-5 circuit manifold 4412 are converted to control voltages for a period-7 manifold 4414, and the node voltages of the latter are converted to control voltages for possible feedback to the period-5 manifold. This circuit enables the period-5 and period-7 manifolds to interact through the mediation of the control voltages.

### Ladder Arrays

Given that control and data signals are interchangeable, we can easily imagine a variety of topologies for circuit manifolds. Simple linear and circular chains are appropriate for computing nested and periodic functions, respectively. Combinations of linear and circular chains are appropriate for problems with more complicated constraints. Elaborations of these topologies is likely to bring advantages in specific applications. Possible uses include structural (topological) stability, mode-locking, higher-order complexity in functional modules, non-local models, feed-forward functions, analog averaging, etc.

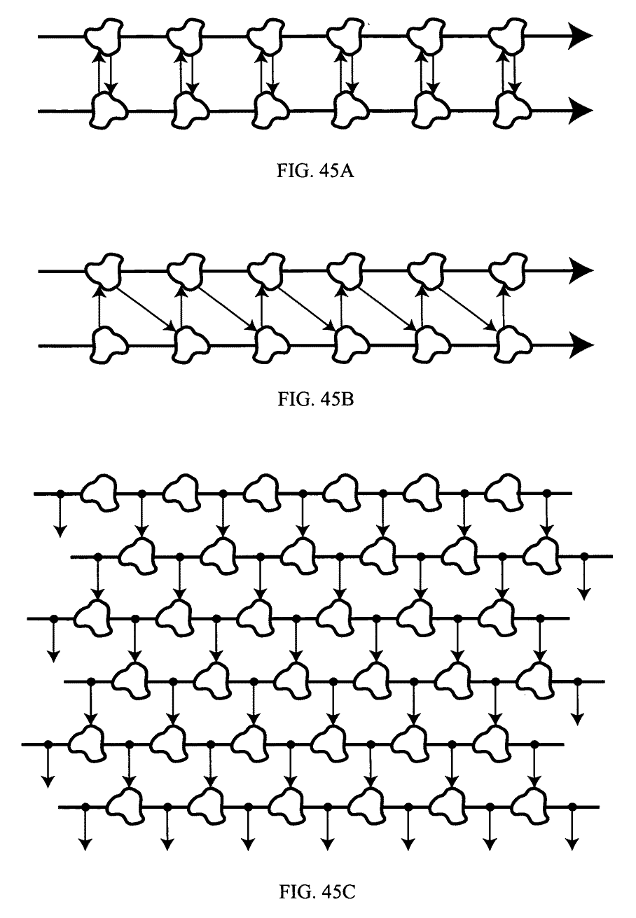

FIG. 45 shows several architectures for circuit manifolds that mix data and control.

FIG. 45A shows a feed-transverse ladder array. In this case, part of the output of each module is used as the control input for the neighboring module. This architecture is appropriate for imposing stability and consistency.

FIG. 45B shows a typical feed-forward ladder circuit manifold. In this case, the output from each module is used as control input to the next module. This architecture is appropriate for guiding the signal by altering the modules directly ahead of the local signal.

### 2D Arrays

The logical extension of ladder arrays is to full 2D arrays of processing modules. One way is to have node voltages act as control voltages for nearest neighbors. Such arrays are well-known in the literature (e.g., systolic arrays), and 2D analog arrays have been investigated. Together with existing technology for implementing analog nanoelectronic VLSI, we find it quite reasonable to imagine arrays of 1000×1000 modules. The association of 2D with images is obvious and very suggestive.

FIG. 45C shows a 2D half-offset array circuit manifold. In this case, the node voltages constitute the 2D “image,” and they are used as control inputs to the neighboring ladder. This circuit manifold thus implements a line-oriented adaptive image processor. Additional control inputs to the modules (not shown in the figure) can provide for global control over the image.

### Sensor Arrays

Because circuits can easily incorporate analog devices acting as sensors and transducers, it is quite reasonable to expect 2D arrays will be useful for image analysis, lattice computations, simulating diffusive processes, and similar applications. Such arrays could have the capability to detect chemicals, including DNA and other proteins, and to perform analysis on the signals for fast detection and interpretation. Such capability would find application in medicine, chemistry, security, and many other areas.

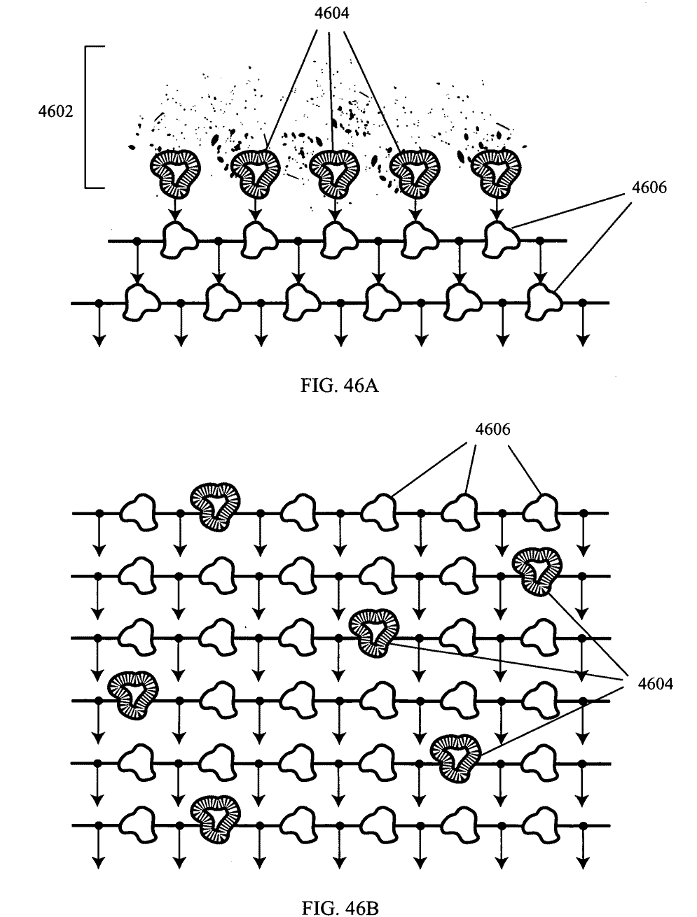

FIG. 46 shows two concepts of sensor arrays built into analog circuit manifolds.

FIG. 46A shows a surface layer 4602 of sensors 4604 integral with the edge of the processor containing modules 4606. This is the usual structure of an artificial retina, in which the imaging plane is processed with a backplane.

FIG. 46B shows a 2D array circuit manifold with sensors 4608 embedded within the array of processing modules 4606. This form of processor begins to resemble biological systems, and that is intentional here. The idea of distributed nanoscale sensors integral with the circuitry able to interpret their readings in real-time is a very powerful one. While the primary purpose of this invention is simulation, the ability to receive micro-detailed input data in real-time broadens considerably the meaning of the term.

### Discussion

### Nanoelectronics

The preferred means for realizing the circuits described in this invention is analog nanoelectronics. The large number of devices implied by casting algorithms into hardware demands the smallest, lowest power devices possible. More importantly, nanoelectronic devices can have transfer functions that are complex, in particular non-monotonic. Such functions present the opportunity to fabricate complex functional modules as single nanoscale devices. Nanoelectronics also offers advantages in lower power, higher speed, fewer devices, and simpler architectures.

Both individual nanoelectronic devices and VLSI analog electronics have been developed to engineering subjects. However, as of this writing technology for fabricating nanoelectronic analog VLSI circuits is not widely available. We emphasize that this invention in no way depends on the availability of such technology (it can be fabricated using any electronic technology). Conversely, we believe that the advantages of this invention provide incentive for developing such technology.

### Programming

For analog circuits, programming implies the process of physically assembling the circuits and setting parameter values. This is essentially what we have called aggregation. The process of measuring the values of circuit variables and interpreting them is referred to as evaluation. The aggregation/evaluation computational paradigm we adopt here is valid for the analog circuit manifolds we have described in this invention.

However, this invention blurs the distinction between data and control, hence blurs the distinction between data and programming. It is simply not meaningful to separate data and programming, either logically or physically. Problem solving should be thought of as a single process of specification and solution: the solution emerges simultaneously with the specification of the problem. In this sense, even the aggregation/evaluation paradigm is inadequate to describe the operation of the analog circuit manifolds described in this invention. To a great extent, programming per se is inherently meaningless in the present invention.

Advantages of this Invention Over Conventional Computers

It is natural to ask about the performance of the circuit manifolds described in this invention as computers, and whether they could compete favorably with conventional computers. While it is perhaps dangerous to compare the mature digital technology with the incipient nanoelectronic analog array circuit manifold technology described in this invention, we can offer a rough basis for such a comparison.

First, for VLSI technology, nanoelectronics offers advantages of reduced device size and power, and increased device density, speed, and complexity; these factors should provide an advantage to nanoelectronic circuit manifolds of 10-10³. Second, for Logic, analog arrays can have throughput 102-105 times digital arrays, as shown by Hasler and others. Third, for Architecture, assembling the circuit manifolds as topological analogues of the system attractor should bring advantages in throughput of 10²-10⁴.

The following table brings these advantages together. On the bottom line, we make a rough estimate of what we might expect in combining these technologies. The smallest figure (10³) refers to a period of research, technology demonstration, and verification. The intermediate figure (10⁶) refers to a period of product development. The highest figure (10⁹) refers to projected optimized products.

It should be noted in this table that neither nanoelectronics nor analog arrays is an intrinsic part of this invention. The core idea here is topological analogues. However, we have noted that both nanoelectronics and analog arrays are important to realizing the maximum advantages enabled by topological analogues.

| | Conventional | This invention | Advantage |
|---|---|---|---|
| VLSI technology | Microelectronics | Nanoelectronics | 10-10³ |
| Logic | Digital arrays | Analog arrays | 10²-10⁵ |
| Architecture | Bit storage/registers | Topological | 10²-10⁴ |
| | | analogues | |
| | | TOTAL | 10³-10⁶-10⁹ |

### Appropriate Applications

Most human-important problems are qualitative: we neither have complete and precise input, nor do we want precise output of instances of solutions. Rather, we need qualitative information about the system, its general dependence on controls, and discovery of unexpected features. Problems in the following areas are often of this kind: artistic expression, climate and weather, control, engineering, image processing, pattern recognition, language, medicine, physics, politics, and psychology.

As an example, consider the challenge of planning for global climate change. This system has many aspects that would make it a good candidate for the kind of approach we describe here:

(1) It has both local and global character;

(2) It involves numerous dynamic processes;

(3) The dynamics ranges from periodicity to chaos;

(4) We do not have comprehensive or precise data for input;

(5) We do not need or want detailed precise data as output. What we need is relatively coarse simulations that generate scenarios, together with indicators of their dependence on controls (e.g., petroleum exhaustion, introduction of nuclear energy, deforestation, land use changes, etc.). Clearly, this problem has the following characteristics:

(6) The problem is important;

(7) We can't solve it with conventional computers;

(8) We don't care about the details.

Thus, we see that appropriate problems typically will have some or all of the following characteristics:

(9) Input data is qualitative, incomplete, ambiguous, etc.;

(10) Physical models probably do not exist;

(11) The system behavior is complex (“too complicated for analysis”);

(12) The system behavior contains structure and recognizable patterns;

(13) The system may exhibit catastrophes or other discontinuities;

(14) We are interested in understanding the system prerequisite to controlling it;

(15) We would like to have real-time interactivity with the simulation.

Appropriate applications for the present invention will have some, or all, of the characteristics (1-15) listed above. Probably the more of these characteristics it has, the greater will be the advantage of this invention over conventional digital computers.

It may be asked how we can specify circuits and problems in this seemingly vague, nonspecific domain. The answer is inherent in the topological foundation of this approach: we are not demanding numerical agreement of a simulation with a real physical system, but the qualitative behavior of a set of systems connected by control parameters. Thus, we can be rather cavalier in the details—we can miss the behavior quantitatively by a lot—but we look for qualitative aspects of the behavior, in the hope and expectation that the simulation will give us some insight into the behavior of the system and how to control it. We need not be concerned with whether the fragments agree in detail with a real physical system. Although this may sound hopelessly sloppy, it is not—it is in fact the central motive for attacking intractable simulations, namely to find out (roughly) “what's happening.”

Chaotic dynamical systems is exemplary of the large class of problems that cannot be solved with conventional digital computers but can be successfully attacked with the present approach. Many diverse systems can be cast into the form of a chaotic dynamical system, to which this invention is directed.

This invention derives its exceptional advantages from the casting of the computational algorithm into an electronic analog circuit that is a physical analogue of the system being simulated. The two systems are, by design, topological equivalents. It is the topological match between human-important problems and the electronic circuits that enables this invention to be realized and to have practical advantages over conventional computers.

What is claimed is:

1. Circuits for simulating dynamical systems comprising:
(a) a set of individual electronic circuit modules, each with a plurality of inputs and a plurality of outputs, together with a plurality of control inputs and monitoring outputs, said modules providing transfer functions between inputs and outputs, said inputs and outputs comprising corresponding sets of circuit variables, said circuit variables being experimentally accessible electronic quantities such as voltages and/or currents, said modules being electronic analogues of pieces of a model branched manifold, said model branched manifold being an idealized geometric model of a branched manifold, said branched manifold being the topological equivalent of an attractor, said attractor describing the dynamics in phase space of a dynamical system, and in which one or more circuit variables are analogues of dynamical variables of the system, and wherein other circuit variables can be the analogues of the density of trajectories at local transverse sections across the model branched manifold, and still other variables can be the analogues of the system time generating the dynamics, said circuit modules being connected end-to-end by joining the outputs of each module to the corresponding inputs of the next module, said modules being chosen and said connections being made such that the fully-connected circuit is the topological equivalent of part or all of the model branched manifold; and
(b) means for establishing values of a subset of the circuit variables thereby defining said subset as independent variables, and means for measuring values of the complementary subset of circuit variables thereby defining said complementary subset as dependent variables, and means for determining functional relationships between said independent variables and said dependent variables;
whereby said simulation of said dynamical system is accomplished.

2. Circuits for simulating dynamical systems recited in claim 1 wherein said modules are comprised of other modules.

3. Circuits for simulating dynamical systems recited in claim 2 wherein a subset of said modules is selected from a group of modules that are the analogues of connecting pieces of the model branched manifold, said group having in common that the inputs are connected coherently to corresponding outputs, said modules also providing arbitrary transfer functions for all variables.

4. Circuits for simulating dynamical systems recited in claim 2 wherein a subset of said modules is selected from a group of modules that are the analogues of rotational pieces of the model branched manifold, said group having in common that two or more inputs are exchanged among themselves before being connected to the outputs, said modules also providing arbitrary transfer functions for all variables.

5. Circuits for simulating dynamical systems recited in claim 2 wherein a subset of said modules is selected from a group of modules that are analogues of the split piece of the model branched manifold, said group having in common that the input variables can be connected to any of a plurality of output channels having corresponding variables, said output channel being selected from said plurality by means to examine said input variables, said modules also providing arbitrary transfer functions for all variables.

6. Circuits for simulating dynamical systems recited in claim 2 wherein a subset of said modules is selected from a group of modules that are analogues of the merge piece of the model branched manifold, said group having in common that corresponding variables in a plurality of input channels can be combined and connected to corresponding variables in the output, said modules also providing arbitrary transfer functions for all variables.

7. Circuits for simulating dynamical systems recited in claim 2 wherein the circuit is in the form of a plurality of modules connected in series, whereby a linear chain circuit is obtained.

8. Circuits for simulating dynamical systems recited in claim 7 wherein the output of the last module in said linear modular circuit is connected to the input of the first module, whereby a ring chain circuit is obtained.

9. Circuits for simulating dynamical systems recited in claim 7 wherein a plurality of such linear modular circuits are connected together by connecting the output of any module to the input of the first module in a different linear chain circuit, whereby a tree chain circuit is obtained.

10. Circuits for simulating dynamical systems recited in claim 2 wherein the circuit is in the form of a plurality of modules connected in parallel, whereby a parallel chain circuit is obtained.

11. Circuits for simulating dynamical systems recited in claim 2 wherein the outputs of a subset of the modules in said circuit are used as control inputs to different subset of modules in said circuit, in such a manner as to effect a change in the operation of said modules, whereby a feedback or feed forward circuit is obtained.

12. Circuits for simulating dynamical systems recited in claim 2 wherein the outputs of a subset of the modules in said circuit are used to control changes in the connections of the modules of said circuit, including but not limited to the insertion or removal of one or more modules, whereby a change in the topography of the circuit is obtained.

13. Circuits for simulating dynamical systems recited in claim 2 wherein the modules have exactly one (1) circuit variable, said variable being the analogue of the independent variable in the dynamical system.

14. Circuits for simulating dynamical systems recited in claim 2 wherein the modules have exactly three (3) circuit variables, one variable being the analogue of the independent variable of the dynamical system, another variable being the analogue of the density of trajectories at local transverse sections of the model branched manifold, and the third variable being the analogue of the system time generating the dynamics.

15. Circuits for simulating dynamical systems recited in claim 2 wherein the modules have a plurality of variables, said variables being the analogues of a plurality of mutually exclusive intervals of values of the independent variable of the dynamical system.

16. Circuits for simulating dynamical systems recited in claim 2 wherein the transfer functions of the variables are effected with circuits that are primarily analog rather than digital.

17. Circuits for simulating dynamical systems recited in claim 2 wherein some or all of the transfer functions of the variables are effected with circuits incorporating nanoelectronics to an extent that significantly improves their performance over microelectronics.
